(19) United States
(12) Patent Application Publication
(10) Pub. No.: US 2019/0172848 A1
(43) Pub. Date: Jun. 6, 2019

(54) THIN-FILM TRANSISTOR SUBSTRATE

(71) Applicant: Mitsubishi Electric Corporation, Tokyo (JP)

(72) Inventors: Kazunori INOUE, Kumamoto (JP); Takeshi KUBOTA, Tokyo (JP)

(73) Assignee: Mitsubishi Electric Corporation, Tokyo (JP)

(21) Appl. No.: 16/201,318

(22) Filed: Nov. 27, 2018

(30) Foreign Application Priority Data
Dec. 4, 2017 (JP) 2017-232395

(51) Int. Cl. H01L 27/12; H01L 29/786

(52) U.S. Cl. CPC H01L 27/1225; H01L 27/1218; H01L 27/124; G02F 1/1368; H01L 29/7869; H01L 27/1296; H01L 27/1248

(57) ABSTRACT

A first gate insulating layer and a protective insulating layer are made of silicon nitride. A second gate insulating layer is provided on gate electrodes via a first gate insulating layer. A first intersecting layer is provided on gate lines via a first gate insulating layer. A channel layer has the same shape as the second gate insulating layer. A second intersecting layer is provided on and has the same shape as the first intersecting layer. Source lines intersect with the gate lines on the second intersecting layer. The first gate insulating layer and the protective insulating layer have gate contact holes. The protective insulating layer has source contact holes. The second gate insulating layer, the channel layer, and the first and second intersecting layers are made of oxide and have a common species of elements and a common crystal structure.

### BACKGROUND OF THE INVENTION

### Field of the Invention

The present invention relates to a thin-film transistor substrate and a method of manufacturing a thin-film transistor substrate, and in particular to a thin-film transistor substrate using oxide semiconductors and a method of manufacturing such a thin-film transistor substrate.

### Description of the Background Art

TFT active matrix substrates using thin-film transistors (TFTs) as switching devices (hereinafter, referred to as “thin-film transistor substrates” or “TFT substrates”) are used in electrooptical devices such as displays using, for example, liquid crystals or organic electroluminescence (organic EL). Semiconductor devices such as TFTs are characterized by its low power consumption and low profile and are being actively applied to flat panel displays. Electrooptical elements for liquid crystal displays (LCDs) include passive matrix LCDs, and TFT-LCDs using TFTs as switching devices. Among them, TFT-LCDs are superior to passive matrix LCDs in display quality and widely used for display produces such as mobile computers, notebook computers, and televisions. In general, TFT-LCDs include a liquid crystal display panel having a structure in which a liquid crystal layer is sandwiched between a TFT substrate that includes a plurality of TFTs arranged in an array and a counter substrate that includes, for example, a color filter. A polarizing plate is provided on each of the front and back sides of the liquid crystal display panel, and a backlight is further provided on one of the front and back sides. This structure gives an excellent color display.

Liquid crystal driving modes adopted in LCDs include longitudinal electric field modes such as the twisted nematic (TN) mode and the vertical alignment (VA) mode, and transverse electric field modes such as the in-plane switching (IPS) mode (“IPS” is a registered trademark of Japan Display Inc.) and the fringe field switching (FFS) mode. In general, LCDs employing the transverse electric field modes are more advantageous in increasing viewing angles than LCDs employing the longitudinal electric field modes and are becoming the mainstream of display products such as personal computers and on-vehicle display devices.

In the LCDs employing the longitudinal electric field modes typified by the TN mode, pixel electrodes to which voltages based on image signals are applied are provided on a TFT substrate, and common electrodes fixed to a constant potential (common potential) is provided on a counter substrate. Thus, the liquid crystal of a liquid crystal layer is driven by an electric field that is approximately perpendicular to the surface of the liquid crystal display panel. In liquid crystal display panels employing the transverse electric field modes, on the other hand, both the pixel electrodes and the common electrodes are provided on the TFT substrate, and the liquid crystal of the liquid crystal layer is driven by an electric field that is approximately horizontal to the surface of the liquid crystal display panel. In particular, on an FFS-mode TFT substrate, the pixel electrodes and the common electrodes are provided so as to vertically oppose each other via an insulation film. Either the pixel electrodes or the common electrodes may be disposed on the lower side, and the ones disposed on the lower side are formed in a planar shape and the others disposed on the upper side (on the side closer to the liquid crystal layer) are formed in a grid shape having slits or in a comb tooth shape.

The switching devices of TFT substrates for LCDs have conventionally mainly used amorphous silicon (a-Si) as semiconductor films that configure active layers (channel layers) of the TFTs.

For example, typical TN-mode TFT substrates that include TFTs using a-Si semiconductor films as channel layers (hereinafter, referred to as “a-Si-TFTs) as illustrated in FIGS. 1 and 2 of Publication of Japanese Unexamined Patent Application No. 10-268353 can generally be manufactured through a total of five photolithographic processes that correspond to (1) a step of forming gate electrodes, (2) a step of forming a gate insulating layer and a channel layer, (3) a step of forming source electrodes and drain electrodes, (4) a step of forming contact holes in a protective insulation film, and (5) a step of forming pixel electrodes.

Moreover, FFS-mode TFT substrates with a general structure including a-Si-TFTs as disclosed in, for example, Publication of Japanese Unexamined Patent Application No. 2009-151285 can be manufactured through a total of seven photolithographic processes that correspond to (1) a step of forming gate electrodes, (2) a step of forming a gate insulating layer and a channel layer, (3) a step of forming source electrodes and drain electrodes, (4) a step of forming contact holes in a protective insulation film, (5) a step of forming pixel electrodes, (6) a step of forming contact holes in an interlayer insulation layer, and (7) a step of forming common electrodes.

The TFTs disclosed in the above publications can use a silicon nitride (SiN) film or a silicon oxide (SiO) film as the gate insulating layer and the protective insulation film. In particular, a-Si-TFTs generally favorably use an SiN film in consideration of, for example, excellence in barrier ability (interrupting ability) against impurity elements that can affect the properties and reliability of the channel layer due to the substrate or external environments, and easiness of the machining process (formation of the contact holes). As the method of depositing an SiN-film, plasma enhanced chemical vapor deposition (PECVD) is common because of high productivity achieved by high deposition speed. The SiN film deposited by PECVD contains a large number of hydrogen (H) atoms. Thus, combining this SiN insulation film with an a-Si film that has defects caused by uncombined hands (dangling bonds) between Si atoms achieves the effect of recovering the properties of the a-Si film by repairing dangling bonds with the hydrogen atoms in the SiN film.

Incidentally, in recent years, TFTs using oxide semiconductor films as channel layers (hereinafter, referred to as “oxide TFTs”) have been newly developed. Oxide semiconductors have higher mobility than a-Si and can achieve higher-performance TFTs. Thus, oxide semiconductors are advantageous in increasing panel resolution and reducing power consumption, and are increasingly applied to portable devices such as smartphones and mobile computers, personal computers, and other devices. Zinc-oxide-based (ZnO) materials, and amorphous InGaZnO-based materials made by adding gallium oxide (Ga₂O₃) and indium oxide (In₂O₃) to zinc oxide are mainly used as oxide semiconductors. Techniques for these oxide TFTs are disclosed in, for example, Publication of Japanese Unexamined Patent Application Nos. 2000-150900 and 2007-281409 and Kenji Nomura, et al., “Room-temperature fabrication of transparent flexible thin-film transistors using amorphous oxide semiconductors,” Nature 2004, vol. 432, pp. 488 to 492.

However, it is known that the characteristics and reliability of the oxide TFTs using oxide semiconductor films as channel layers will deteriorate if an SiN film that is widely used in a-Si-TFTs is used as, for example, a gate insulating layer. This is because a reduction in resistance and structural defects occur at the interface layer as a result of the channel layer of an oxide semiconductor film being reduced. In addition, the aforementioned reduction caused by the hydrogen atoms in the SiN film is known to have an adverse effect of deteriorating characteristics on the oxide semiconductor film, although having a good effect of repairing defects on the a-Si film.

As measures for avoiding these problems, for example, Publication of Japanese Unexamined Patent Application Nos. 2003-86808 and 2009-141002 disclose techniques using a two-layer configuration that combines an SiN film, which has excellent barrier ability, and an SiO film, which is an oxide insulating film with a low hydrogen concentration and containing oxygen (O), so that an oxide semiconductor film is disposed in contact with an SiO film. The SiO film, like the SiN film, can be deposited by PECVD, and these films can both be deposited by simply changing a source gas. Thus, these techniques can be applied without causing a considerable increase in the cost of the film deposition process.

The SiO film is, however problematic in that it makes the machining process difficult in the manufacture of a TFT substrate. For example, in the case of the insulation layer of an SiN film used in a-Si-TFTs, efficient machining is possible by dry etching using a fluorine-based (F) gas in the process of forming contact holes in the insulation layer. With this etching technique, however, an SiO film is etched at an extremely low rate (at a rate less than or equal to one-half of the etch rate of the SiN film). For this reason, using the two-layer configuration of an SiO film and an SiN film poses a problem in that productivity will drop due to an increase in the processing time for forming contact holes. Even if countermeasures to reduce the ratio of the film thickness of the SiO film in the two-layer configuration and thereby shorten the processing time are taken, a surface of discontinuity in shape such as recessed dents, notches, or eaves can be generated at the interface between the SiN film and the SiO film on the side faces of the contact holes. Consequently, another problem arises in that a coverage failure (disconnection) occurs in, for example, an electrode film that is provided on the contact holes in a subsequent step.

In the case of using a metal oxide insulating film such as tantalum oxide (TaO), aluminum oxide (AlO), or titanium oxide (TiO) instead of the SiO film, there is a problem that the introduction of, for example, an insulator material, a sputtering deposition device, and an etching process (gas for dry etching or a chemical solution for wet etching) is newly required and accordingly the manufacturing cost increases, in addition to the problem that a surface of discontinuity is formed on the side faces of the contact holes.

In addition, the aforementioned coverage failure (disconnection) problem can occur not only on the contact holes but also on step heights caused by electrodes or a wiring pattern. Preventing such a coverage failure (disconnection) caused by step heights is also important in order to reduce the percent defective and thereby reduce the product cost.

### SUMMARY

The present invention has been achieved in order to solve problems as described above, and it is an object of the present invention to provide a thin-film transistor substrate that can be manufactured with high yield and high productivity while ensuring high performance and high reliability, and to provide a method of manufacturing a thin-film transistor substrate having high performance and high reliability with high yield and high productivity.

A thin-film transistor substrate according to one aspect of the present invention is a thin-film transistor substrate having a plurality of pixel regions arranged in a matrix, and including a plurality of thin-film transistors that correspond respectively to the plurality of pixel regions. The thin-film transistor substrate includes a support substrate, a gate line, a gate terminal, a first gate insulating layer, a second gate insulating layer, a first intersecting layer, a channel layer, a second intersecting layer, a source electrode, a drain electrode, a source line, a source terminal, and a protecting insulating layer. The gate line is provided on the support substrate and includes a gate electrode disposed in each of the plurality of pixel regions. The gate terminal is provided on the support substrate and connected to the gate line. The first gate insulating layer is made of silicon nitride and covers the gate line and the gate terminal, a second gate insulating layer provided on the gate electrode via the first gate insulating layer in each of the plurality of pixel regions. The first intersecting layer is provided on the gate line via the first gate insulating layer and intersects with the gate line. The channel layer is provided on the second gate insulating layer and has the same shape as the second gate insulating layer. The second intersecting layer is provided on the first intersecting layer and has the same shape as the first intersecting layer. The source electrode and the drain electrode are spaced from and oppose each other on the channel layer. The source line is connected to the source electrode and intersects with the gate line via the second intersecting layer. The source terminal is connected to the source line. The protective insulating layer is made of silicon nitride and covers the channel layer, the gate line, the gate terminal, the source line, and the source terminal. The first gate insulating layer and the protective insulating layer has a gate contact hole that reaches the gate terminal. The protective insulating layer has a source contact hole that reaches the source terminal. The second gate insulating layer, the channel layer, the first intersecting layer, and the second intersecting layer are made of oxide and have a common species of elements and a common crystal structure.

A thin-film transistor substrate according to another aspect of the present invention is a thin-film transistor substrate having a plurality of pixel regions arranged in a matrix, and including a plurality of thin-film transistors that correspond respectively to the plurality of pixel regions. The thin-film transistor substrate includes a support substrate, a gate line, a gate terminal, a first gate insulating layer, a second gate insulating layer, a first intersecting layer, a channel layer, a second intersecting layer, a local insulating layer, a third intersecting layer, a source electrode, a drain electrode, a source line, a source terminal, and a protective insulating layer. The gate line is provided on the support substrate and includes a gate electrode disposed in each of the plurality of pixel regions. The gate terminal is provided on the support substrate and connected to the gate line. The first gate insulating layer is made of silicon nitride and covers the gate line and the gate terminal. The second gate insulating layer is provided on the gate electrode via the first gate insulating layer in each of the plurality of pixel regions. The first intersecting layer is provided on the gate line via the first gate insulating layer and intersects with the gate line. The channel layer is provided on the second gate insulating layer and has the same shape as the second gate insulating layer. The second intersecting layer is provided on the first intersecting layer and has the same shape as the first intersecting layer. The local insulating layer is provided on the channel layer and has the same shape as the channel layer. The third intersecting layer is provided on the second intersecting layer and has the same shape as the second intersecting layer. The source electrode and the drain electrode are respectively in contact with first and second ends of the channel layer and are spaced from and oppose each other on the local insulating layer. The source line is connected to the source electrode and intersects with the gate line on the third intersecting layer. The source terminal is connected to the source line. The protective insulating layer is made of silicon nitride and covers the local insulating layer, the gate line, the gate terminal, the source line, and the source terminal. The first gate insulating layer and the protective insulating layer has a gate contact hole that reaches the gate terminal. The protective insulating layer has a source contact hole that reaches the source terminal. The second gate insulating layer, the channel layer, the local insulating layer, the first intersecting layer, the second intersecting layer, and the third intersecting layer are made of oxide and have a common species of elements and a common crystal structure. The first intersecting layer, the second intersecting layer, and the third intersecting layer have portions that extend off the gate line in plan view. The portions have conductivity.

A thin-film transistor substrate according to yet another aspect of the present invention is a thin-film transistor substrate having a plurality of pixel regions arranged in a matrix, and including a plurality of thin-film transistors that correspond respectively to the plurality of pixel regions. The thin-film transistor substrate includes a support substrate, a gate line, a gate terminal, a common electrode, a first gate insulating layer, a second gate insulating layer, a first intersecting layer, a channel layer, a second intersecting layer, a source electrode, a drain electrode, a source line, a source terminal, a pixel electrode, an interlayer insulation layer, a counter electrode, and a local insulating layer. The gate line is provided on the support substrate and includes a gate electrode disposed in each of the plurality of pixel regions. The gate terminal is provided on the support substrate and connected to the gate line. The common electrode is provided apart from the gate line on the support substrate. The first gate insulating layer is made of silicon nitride and covers the gate line and the gate terminal. The second gate insulating layer is provided on the gate electrode via the first gate insulating layer in each of the plurality of pixel regions. The first intersecting layer is provided on the gate line via the first gate insulating layer and intersects with the gate line. The channel layer is provided on the second gate insulating layer and has the same shape as the second gate insulating layer. The second intersecting layer is provided on the first intersecting layer and has the same shape as the first intersecting layer. The source electrode and the drain electrode are spaced from and oppose each other on the channel layer. The source line is connected to the source electrode and intersects with the gate line on the second intersecting layer. The source terminal is connected to the source line. The pixel electrode is provided in contact with the drain electrode on the first gate insulating layer in each of the plurality of pixel regions. The interlayer insulation layer is made of silicon nitride and covers the channel layer, the gate line, the gate terminal, the source line, the source terminal, and the pixel electrode. The counter electrode is provided on the interlayer insulation layer and opposes the pixel electrode via the interlayer insulation layer. The local insulating layer is provided between the channel layer and the interlayer insulation layer and directly covers the channel layer. The interlayer insulation layer has a source contact hole that reaches the source terminal. The first gate insulating layer and the interlayer insulation layer have a gate contact hole that reaches the gate terminal and a common electrode contact hole that reaches the common electrode. The counter electrode is connected to the common electrode through the common electrode contact hole. The second gate insulating layer, the channel layer, the first intersecting layer, the second intersecting layer, and the local insulating layer are made of oxide and have a common species of elements and a common crystal structure.

A thin-film transistor substrate according to yet another aspect of the present invention is a thin-film transistor substrate having a plurality of pixel regions arranged in a matrix, and including a plurality of thin-film transistors that correspond respectively to the plurality of pixel regions. The thin-film transistor substrate includes a support substrate, a gate line, a gate terminal, a common electrode, a first gate insulating layer, a second gate insulating layer, a first intersecting layer, a channel layer, a second intersecting layer, a local insulating layer, a third intersecting layer, a source electrode, a drain electrode, a source line, a source terminal, a pixel electrode, an interlayer insulation layer, and a counter electrode. The gate line is provided on the support substrate and includes a gate electrode disposed in each of the plurality of pixel regions. The gate terminal is provided on the support substrate and connected to the gate line. The common electrode is provided apart from the gate line on the support substrate. The first gate insulating layer is made of silicon nitride and covers the gate line and the gate terminal. The second gate insulating layer is provided on the gate electrode via the first gate insulating layer in each of the plurality of pixel regions. The first intersecting layer is provided on the gate line via the first gate insulating layer and intersecting with the gate line. The channel layer is provided on the second gate insulating layer and has the same shape as the second gate insulating layer. The second intersecting layer is provided on the first intersecting layer and has the same shape as the first intersecting layer. The local insulating layer is provided on the channel layer and has the same shape as the channel layer. The third intersecting layer is provided on the second intersecting layer and has the same shape as the second intersecting layer. The source electrode and the drain electrode are respectively in contact with first and second ends of the channel layer and are spaced from and oppose each other on the local insulating layer. The source line is connected to the source electrode and intersects with the gate line on the third intersecting layer. The source terminal is connected to the source line. The pixel electrode is provided in contact with the drain electrode on the first gate insulating layer in each of the plurality of pixel regions. The interlayer insulation layer is made of silicon nitride and covers the channel layer, the gate line, the gate terminal, the source line, the source terminal, and the pixel electrode. The counter electrode is provided on the interlayer insulation layer and opposing the pixel electrode via the interlayer insulation layer. The pixel electrode includes a first pixel electrode layer provided on the first gate insulating layer, a second pixel electrode layer provided on the first pixel electrode layer and having the same shape as the first pixel electrode layer, and a third pixel electrode layer provided on the second pixel electrode layer and having the same shape as the second pixel electrode layer. The interlayer insulation layer has a source contact hole that reaches the source terminal. The first gate insulating layer and the interlayer insulation layer have a gate contact hole that reaches the gate terminal and a common electrode contact hole that reaches the common electrode. The counter electrode is connected to the common electrode through the common electrode contact hole. The second gate insulating layer, the channel layer, the local insulating layer, the first intersecting layer, the second intersecting layer, the third intersecting layer, the first pixel electrode layer, the second pixel electrode layer, and the third pixel electrode layer are made of oxide and have a common species of elements and a common crystal structure.

A method of manufacturing a thin-film transistor according to one aspect of the present invention is a method of manufacturing a thin-film transistor substrate having a plurality of pixel regions arranged in a matrix, and including a plurality of thin-film transistors that correspond respectively to the plurality of pixel regions. The manufacturing method includes the following steps. A gate line that including a gate electrode disposed in each of the plurality of pixel regions, and a gate terminal connected to the gate line are formed on a support substrate. A first gate insulating layer that is made of silicon nitride and covers the gate line and the gate terminal is formed. A laminated film is formed on the first gate insulating layer. The step of forming the laminated film includes a step of depositing a first oxide insulating layer on the first gate insulating layer by sputtering and a step of depositing an oxide semiconductor layer on the first oxide insulating layer by sputtering. A sputtering material that is used in the step of depositing the first oxide insulating layer and a sputtering material that is used in the step of depositing the oxide semiconductor layer are made of oxide and have a common species of elements and a common crystal structure. By patterning the laminated film, a second gate insulating layer provided on the gate electrode via the first gate insulating layer in each of the plurality of pixel regions and a first intersecting layer provided on the gate line via the first gate insulating layer and intersecting with the gate line is formed from the first oxide insulating layer, and a channel layer provided on the second gate insulating layer and having the same shape as the second gate insulating layer, and a second intersecting layer provided on the first intersecting layer and having the same shape as the first intersecting layer are formed from the oxide semiconductor layer. A source electrode and a drain electrode that are spaced from and oppose each other on the channel layer, a source line connected to the source electrode and intersecting with the gate line on the second intersecting layer, and a source terminal connected to the source line are formed. A protective insulating layer that covers the channel layer, the gate line, the gate terminal, the source line, and the source terminal is made of silicon nitride. A gate contact hole that reaches the gate terminal is formed in the first gate insulating layer and the protective insulating layer, and a source contact hole that reaches the source terminal is formed in the protective insulating layer.

A method of manufacturing a thin-film transistor according to another aspect of the present invention is a method of manufacturing a thin-film transistor substrate having a plurality of pixel regions arranged in a matrix, and including a plurality of thin-film transistors that correspond respectively to the plurality of pixel regions. The manufacturing method includes the following steps. A gate line that includes a gate electrode disposed in each of the plurality of pixel regions, and a gate terminal connected to the gate line are formed on a support substrate. A first gate insulating layer that covers the gate line and the gate terminal is made of silicon nitride. A laminated film is formed on the first gate insulating layer. The step of forming the laminated film includes a step of depositing a first oxide insulating layer on the first gate insulating layer by sputtering, a step of depositing an oxide semiconductor layer on the first oxide insulating layer by sputtering, and a step of depositing a second oxide insulating layer on the oxide semiconductor layer by sputtering. A sputtering material that is used in the step of depositing the first oxide insulating layer, a sputtering material that is used in the step of depositing the oxide semiconductor layer, and a sputtering material that is used in the step of depositing the second oxide insulating layer are made of oxide and have a common species of elements and a common crystal structure. By patterning the laminated film, a second gate intersecting layer provided on the gate electrode via the first gate insulating layer in each of the plurality of pixel regions, and a first intersecting layer provided on the gate line via the first gate insulating layer and intersecting with the gate line are formed from the first oxide insulating layer, a channel layer provided on the second gate insulating layer and having the same shape as the second gate insulating layer, and a second intersecting layer provided on the first intersecting layer and having the same shape as the first intersecting layer are formed from the oxide semiconductor layer, and a local intersecting layer provided on the channel layer and having the same shape as the channel layer, and a third intersecting layer provided on the second intersecting layer and having the same shape as the second intersecting layer are formed from the second oxide insulating layer. Ultraviolet light is applied via the gate line toward the laminated film to impart conductivity to a portion of the laminated film; the portion extends off the gate line in plan view. A source electrode and a drain electrode that are respectively in contact with first and second ends of the channel layer and are spaced from and oppose each other on the local insulating layer, a source line connected to the source electrode and intersecting with the gate line on the third intersecting layer, and a source terminal connected to the source line are formed. A protective insulating layer that covers the local insulating layer, the gate line, the gate terminal, the source line, and the source terminal is made of silicon nitride. A gate contact hole that reaches the gate terminal is formed in the first gate insulating layer and the protective insulating layer. A source contact hole that reaches the source terminal is formed in the protective insulating layer.

According to the present invention, a thin-film transistor substrate with high performance and high reliability can be manufactured with high yield and high productivity.

### BRIEF DESCRIPTION OF THE DRAWINGS

FIG. 1 is a partial sectional view schematically illustrating a configuration of a TFT substrate according to a first preferred embodiment of the present invention, and taken along lines G1-G2, S1-S2, and P1-P2 in FIG. 2;

FIG. 2 is a partial plan view schematically illustrating the configuration of the TFT substrate according to the first preferred embodiment of the present invention;

FIG. 3 is a partial sectional view schematically illustrating one step of a method of manufacturing the TFT substrate according to the first preferred embodiment of the present invention;

FIG. 4 is a partial plan view schematically illustrating one step of the method of manufacturing the TFT substrate according to the first preferred embodiment of the present invention;

FIGS. 5 to 7 are partial sectional views schematically illustrating one step of the method of manufacturing the TFT substrate according to the first preferred embodiment of the present invention;

FIG. 8 is a partial plan view schematically illustrating one step of the method of manufacturing the TFT substrate according to the first preferred embodiment of the present invention;

FIG. 9 is a partial sectional view schematically illustrating one step of the method of manufacturing the TFT substrate according to the first preferred embodiment of the present invention;

FIG. 10 is a partial plan view schematically illustrating one step of the method of manufacturing the TFT substrate according to the first preferred embodiment of the present invention;

FIGS. 11 and 12 are partial sectional views schematically illustrating one step of the method of manufacturing the TFT substrate according to the first preferred embodiment of the present invention;

FIG. 13 is a partial plan view schematically illustrating one step of the method of manufacturing the TFT substrate according to the first preferred embodiment of the present invention;

FIG. 14 is a partial sectional view schematically illustrating one step of the method of manufacturing the TFT substrate according to the first preferred embodiment of the present invention;

FIG. 15 is a partial plan view schematically illustrating one step of the method of manufacturing the TFT substrate according to the first preferred embodiment of the present invention;

FIG. 16 is a partial sectional view schematically illustrating a configuration of a TFT substrate according to a second preferred embodiment of the present invention, and taken along lines G1-G2, S1-S2, and P1-P2 in FIG. 17;

FIG. 17 is a partial plan view schematically illustrating the configuration of the TFT substrate according to the second preferred embodiment of the present invention;

FIG. 18 is a partial sectional view schematically illustrating one step of a method of manufacturing the TFT substrate according to the second preferred embodiment of the present invention;

FIG. 19 is a partial plan schematically illustrating one step of the method of manufacturing the TFT substrate according to the second preferred embodiment of the present invention;

FIG. 20 is a partial sectional view schematically illustrating one step of the method of manufacturing the TFT substrate according to the second preferred embodiment of the present invention;

FIG. 21 is a partial plan view schematically illustrating one step of the method of manufacturing the TFT substrate according to the second preferred embodiment of the present invention;

FIG. 22 is a partial sectional view schematically illustrating one step of the method of manufacturing the TFT substrate according to the second preferred embodiment of the present invention;

FIG. 23 is a partial plan view schematically illustrating one step of the method of manufacturing the TFT substrate according to the second preferred embodiment of the present invention;

FIG. 24 is a partial sectional view schematically illustrating one step of the method of manufacturing the TFT substrate according to the second preferred embodiment of the present invention;

FIG. 25 is a partial plan view schematically illustrating one step of the method of manufacturing the TFT substrate according to the second preferred embodiment of the present invention;

FIG. 26 is a partial sectional view schematically illustrating one step of the method of manufacturing the TFT substrate according to the second preferred embodiment of the present invention;

FIG. 27 is a partial plan view schematically illustrating one step of the method of manufacturing the TFT substrate according to the second preferred embodiment of the present invention;

FIG. 28 is a partial sectional view schematically illustrating a configuration of a TFT substrate according to a third preferred embodiment of the present invention, and taken along lines G1-G2, S1-S2, and P1-P2 in FIG. 29;

FIG. 29 is a partial plan view schematically illustrating the configuration of the TFT substrate according to the third preferred embodiment of the present invention;

FIGS. 30 to 35 are partial sectional views schematically illustrating one step of a method of manufacturing the TFT substrate according to the third preferred embodiment of the present invention;

FIG. 36 is a partial plan view schematically illustrating one step of the method of manufacturing the TFT substrate according to the third preferred embodiment of the present invention;

FIG. 37 is a partial sectional view schematically illustrating one step of the method of manufacturing the TFT substrate according to the third preferred embodiment of the present invention;

FIG. 38 is a partial plan view schematically illustrating one step of the method of manufacturing the TFT substrate according to the third preferred embodiment of the present invention;

FIG. 39 is a partial sectional view schematically illustrating one step of the method of manufacturing the TFT substrate according to the third preferred embodiment of the present invention;

FIG. 40 is a partial plan view schematically illustrating one step of the method of manufacturing the TFT substrate according to the third preferred embodiment of the present invention;

FIG. 41 is a partial sectional view schematically illustrating one step of the method of manufacturing the TFT substrate according to the third preferred embodiment of the present invention;

FIG. 42 is a partial plan view schematically illustrating one step of the method of manufacturing the TFT substrate according to the third preferred embodiment of the present invention;

FIG. 43 is a partial sectional view schematically illustrating a configuration of a TFT substrate according to a fourth preferred embodiment of the present invention, and taken along lines G1-G2, S1-S2, and P1-P2 in FIG. 44;

FIG. 44 is a partial plan view schematically illustrating the configuration of the TFT substrate according to the fourth preferred embodiment of the present invention;

FIG. 45 is a partial sectional view schematically illustrating one step of a method of manufacturing the TFT substrate according to the fourth preferred embodiment of the present invention;

FIG. 46 is a partial plan view schematically illustrating one step of the method of manufacturing the TFT substrate according to the fourth preferred embodiment of the present invention;

FIG. 47 is a partial sectional view schematically illustrating a configuration of a TFT substrate according to a fifth preferred embodiment of the present invention, and taken along lines G1-G2, S1-S2, and P1-P2 in FIG. 48;

FIG. 48 is a partial plan view schematically illustrating the configuration of the TFT substrate according to the fifth preferred embodiment of the present invention;

FIG. 49 is a partial sectional view schematically illustrating one step of a method of manufacturing the TFT substrate according to the fifth preferred embodiment of the present invention;

FIG. 50 is a partial plan view schematically illustrating one step of the method of manufacturing the TFT substrate according to the fifth preferred embodiment of the present invention;

FIG. 51 is a partial sectional view schematically illustrating one step of the method of manufacturing the TFT substrate according to the fifth preferred embodiment of the present invention;

FIG. 52 is a partial plan view schematically illustrating one step of the method of manufacturing the TFT substrate according to the fifth preferred embodiment of the present invention;

FIG. 53 is a partial sectional view schematically illustrating one step of the method of manufacturing the TFT substrate according to the fifth preferred embodiment of the present invention;

FIG. 54 is a partial plan view schematically illustrating one step of the method of manufacturing the TFT substrate according to the fifth preferred embodiment of the present invention;

FIG. 55 is a partial sectional view schematically illustrating a configuration of a TFT substrate according to a sixth preferred embodiment of the present invention, and taken along lines G1-G2, S1-S2, and P1-P2 in FIG. 56;

FIG. 56 is a partial plan view schematically illustrating the configuration of the TFT substrate according to the sixth preferred embodiment of the present invention;

FIG. 57 is a partial sectional view schematically illustrating one step of a method of manufacturing the TFT substrate according to the sixth preferred embodiment of the present invention;

FIG. 58 is a partial plan view schematically illustrating one step of the method of manufacturing the TFT substrate according to the sixth preferred embodiment of the present invention;

FIG. 59 is a partial sectional view schematically illustrating one step of the method of manufacturing the TFT substrate according to the sixth preferred embodiment of the present invention;

FIG. 60 is a partial plan view schematically illustrating one step of the method of manufacturing the TFT substrate according to the sixth preferred embodiment of the present invention;

FIG. 61 is a partial sectional view schematically illustrating one step of the method of manufacturing the TFT substrate according to the sixth preferred embodiment of the present invention;

FIG. 62 is a partial plan view schematically illustrating one step of the method of manufacturing the TFT substrate according to the sixth preferred embodiment of the present invention;

FIG. 63 is a partial sectional view schematically illustrating one step of the method of manufacturing the TFT substrate according to the sixth preferred embodiment of the present invention;

FIG. 64 is a partial plan view schematically illustrating one step of the method of manufacturing the TFT substrate according to the sixth preferred embodiment of the present invention;

FIG. 65 is a partial sectional view schematically illustrating one step of the method of manufacturing the TFT substrate according to the sixth preferred embodiment of the present invention;

FIG. 66 is a partial plan view schematically illustrating one step of the method of manufacturing the TFT substrate according to the sixth preferred embodiment of the present invention;

FIG. 67 is a partial sectional view schematically illustrating a configuration of a TFT substrate according to a seventh preferred embodiment of the present invention, and taken along lines G1-G2, S1-S2, and P1-P2 in FIG. 68;

FIG. 68 is a partial plan view schematically illustrating the configuration of the TFT substrate according to the seventh preferred embodiment of the present invention;

FIG. 69 is a partial sectional view schematically illustrating one step of a method of manufacturing the TFT substrate according to the seventh preferred embodiment of the present invention;

FIG. 70 is a partial plan view schematically illustrating one step of the method of manufacturing the TFT substrate according to the seventh preferred embodiment of the present invention;

FIG. 71 is a partial sectional view schematically illustrating one step of the method of manufacturing the TFT substrate according to the seventh preferred embodiment of the present invention;

FIG. 72 is a partial plan view schematically illustrating one step of the method of manufacturing the TFT substrate according to the seventh preferred embodiment of the present invention;

FIG. 73 is a partial sectional view schematically illustrating one step of the method of manufacturing the TFT substrate according to the seventh preferred embodiment of the present invention;

FIG. 74 is a partial plan view schematically illustrating one step of the method of manufacturing the TFT substrate according to the seventh preferred embodiment of the present invention;

FIG. 75 is a partial sectional view schematically illustrating one step of the method of manufacturing the TFT substrate according to the seventh preferred embodiment of the present invention; and

FIG. 76 is a partial plan view schematically illustrating one step of the method of manufacturing the TFT substrate according to the seventh preferred embodiment of the present invention.

### DESCRIPTION OF THE PREFERRED EMBODIMENTS

Preferred embodiments of the present invention are described hereinafter with reference to the drawings. Note that identical or corresponding parts in the following drawings are given the same reference numerals, and description thereof is not repeated. In order to facilitate viewing of the configuration related to the corresponding content in the specification, part of the configuration may not be shown in plan views. Preferable examples are also described, together with the description of preferred embodiments.

Note that in the specification of the present invention, the words “the same shape” as used in relation to layer patterns refer to the sameness of shape to an extent that can be implemented by common photolithographic processes. Thus, slight variations in shape caused by side etching of patterns or retraction of the outer edges of etching masks during the same photolithographic process are ignorable.

The words “common crystal structure” refer to structures that are classified into the same type (e.g., the same crystal system). Here, amorphous structures are assumed to be one type of crystal structures. The degree of lattice defects (typically, oxygen defects) and slight differences in lattice constant are not taken into consideration to distinguish among crystal structures.

When a plurality of members have a “common species of elements”, the material for each member contains the same combination of elements. For example, in the case where multiple layers are all configured by a combination of an In element, a Ti element, and an O element (i.e., they are all so-called ITO layers), these layers can be said to have a “common species of elements.” Differences in composition ratio are not taken into consideration to distinguish among the spices of elements. The same applies to a sputtering material that is used to deposit layers.

The word “conductivity” refers to the property of having a specific resistance value corresponding to those of conductors, and in other words, refers to the property of having a specific resistance value lower than the specific resistance values of semiconductors. Thus, a member having “conductivity” has a specific resistance value lower than the specific resistance value of a semiconducting material for the channel layer.

The transitive verb “cover” can mean “partially cover”. The transitive verb “cover” can also mean “cover via some member”.

### First Preferred Embodiment

Overview of Structure

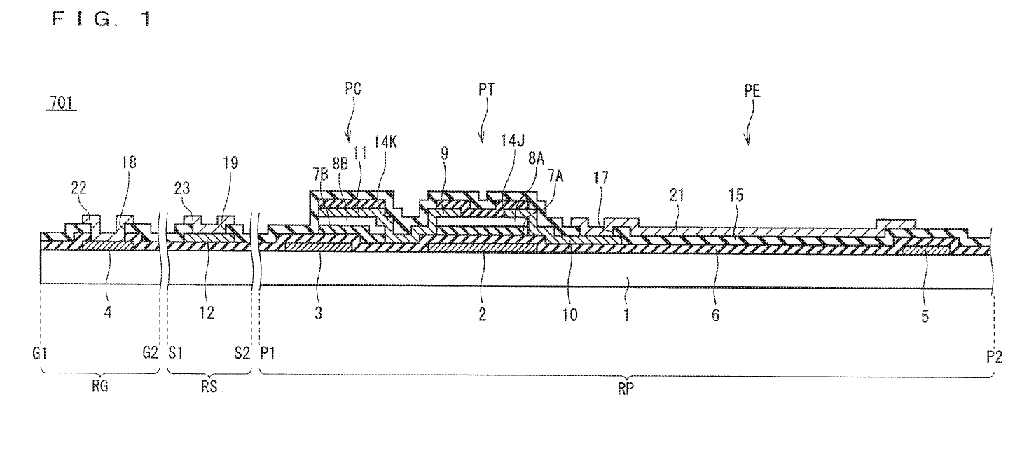

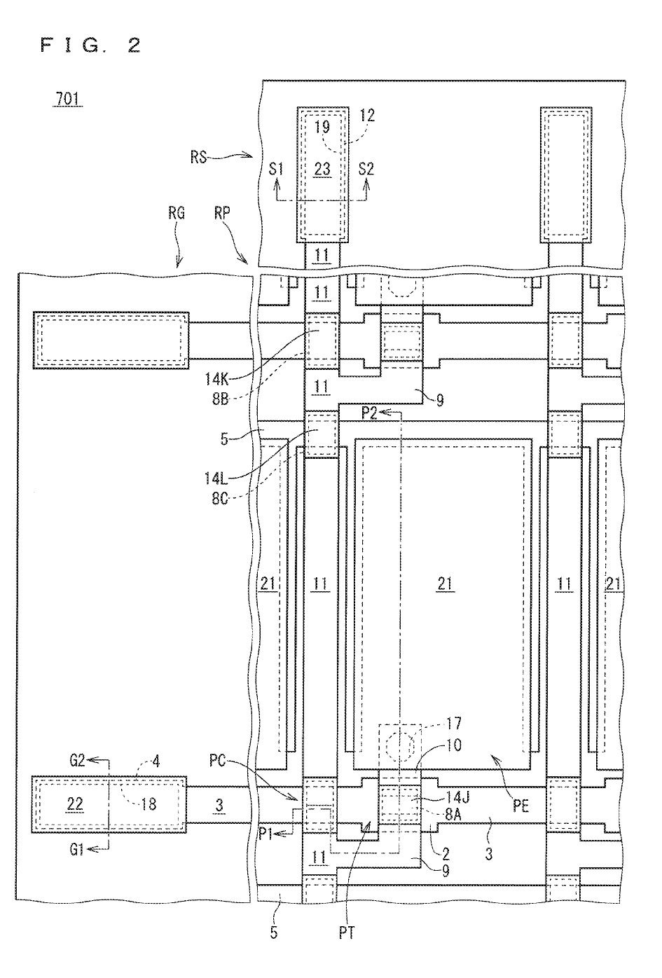

FIGS. 1 and 2 are respectively a partial sectional view and a partial plan view that schematically illustrate a configuration of a thin-film transistor substrate (TFT substrate) 701 according to a first preferred embodiment. The section illustrated in FIG. 1 is taken along line G1-G2 in a gate terminal portion RG, line S1-S2 in a source terminal portion RS, and line P1-P2 in a pixel portion RP in FIG. 2. Note that part of the configuration is not shown in FIG. 2 in order to facilitate viewing of the internal configuration of the TFT substrate 701.

The TFT substrate 701 includes the pixel portion RP. In the pixel portion RP, a plurality of pixel regions is arranged in a matrix, and a plurality of TFTs that correspond to the plurality of pixel regions is provided. Note that FIGS. 1 and 2 illustrate one of the pixel regions. Each of the pixel regions includes a line-intersecting portion PC, a TFT portion PT, and a pixel electrode portion PE. Although described in detail later, the line-intersecting portion PC is an area where a gate line 3 and a source line 11 intersect with each other in plan view (FIG. 2). The TFT portion PT is an area where the aforementioned TFT is provided. The pixel electrode portion PE is an area where a pixel electrode 21 is disposed.

The TFT substrate 701 is applicable to TN-mode optically transparent LCDs. The TFT substrate 701 includes a support substrate 1, gate lines 3, gate terminals 4, a first gate insulating layer 6, a second gate insulating layer 7A, a first intersecting layer 7B, a channel layer 8A, a second intersecting layer 8B, source electrodes 9, drain electrodes 10, source lines 11, source terminals 12, and a protective insulating layer 15.

The gate lines 3 are provided on the support substrate 1 and include gate electrodes 2 that are respectively disposed in each of the plurality of pixel regions. The gate terminals 4 are provided on the support substrate 1 and connected to the gate lines 3. The first gate insulating layer 6 covers the gate lines 3 and the gate terminals 4 and is made of silicon nitride.

The second gate insulating layer 7A in each of the plurality of pixel regions is provided on the gate electrode 2 via the first gate insulating layer 6. The first intersecting layer 7B is provided on the gate line 3 via the first gate insulating layer 6 and intersects with the gate line 3.

The channel layer 8A is provided on the second gate insulating layer 7A and has the same shape as the second gate insulating layer 7A. The second intersecting layer 8B is provided on the first intersecting layer 7B and has the same shape as the first intersecting layer 7B.

The source electrodes 9 and the drain electrodes 10 are spaced from and oppose each other on the channel layer 8A. The source lines 11 are connected to the source electrodes 9 and intersect with the gate lines 3 on the second intersecting layer 8B. The source terminals 12 are connected to the source lines 11.

The protective insulating layer 15 covers the channel layer 8A, the gate lines 3, the gate terminals 4, the source lines 11, and the source terminals 12 and is made of silicon nitride. The first gate insulating layer 6 and the protective insulating layer 15 have gate contact holes 18 that reach the gate terminals 4. The protective insulating layer 15 has source contact holes 19 that reach the source terminals 12. The second gate insulating layer 7A, the channel layer 8A, the first intersecting layer 7B, and the second intersecting layer 8B are made of oxide and have a common species of elements and a common crystal structure.

The TFT substrate 701 may further include a local insulating layer 14J. The local insulating layer 14J is provided between the channel layer 8A and the protective insulating layer 15 and directly covers the channel layer 8A. The local insulating layer 14J is made of oxide.

Details of Structure

The support substrate 1 is, for example, a transparent insulated substrate such as a glass substrate. Each pattern of the gate electrodes 2, the gate lines 3, the gate terminals 4, and common electrodes 5, which are formed from a first conductive film, is arranged on the support substrate 1. The gate terminals 4 and the source terminals 12 are respectively for applying scanning signals and display signals from the outside of the TFT substrate 701.

As illustrated in FIG. 2, the gate lines 3 and the common electrodes 5 extend in the lateral direction and are approximately parallel to each other. The gate electrodes 2 are for controlling an electric field applied to the channel of the TFT and form part of the gate lines 3. That is, the portion of each gate line 3 that is included in the TFT portion PT corresponds to the gate electrode 2. The gate terminals 4 are disposed on one ends (left ends in FIG. 2) of the gate lines 3. The common electrodes 5 are disposed so as to form a pi (II) shape in FIG. 2 and include portions that extend in the lateral direction and portions that branch off from the lateral portions and extend in the longitudinal direction. The latter portions extend in parallel with the source lines 11 on both sides of each pixel region in which the pixel electrode 21 is disposed.

In the first preferred embodiment, for example, a metal such as copper (Cu), molybdenum (Mo), chromium (Cr), and aluminum (Al) or an alloy of these metals with addition of trace amounts of other elements can be used as a material for the first conductive film. As a preferable example, Mo is used as the material for the first conductive film.

As illustrated in FIG. 1, the first gate insulating layer 6 formed from a first insulation film is disposed so as to cover the patterns of the gate electrodes 2, the gate lines 3, the gate terminals 4, and the common electrodes 5 on the upper main surface of the support substrate 1. In the first preferred embodiment, an SiN film that is generally used in conventional a-Si-TFTs is used as the first gate insulating layer 6.

In the TFT portion PT, the second gate insulating layer 7A, which is a pattern formed from a second insulation film (first oxide insulating layer), is disposed on the first gate insulating layer 6. Also, the channel layer 8A that is a pattern formed from an oxide semiconductor film (oxide semiconductor layer) is laminated on the upper surface of the second gate insulating layer 7A.

In plan view (FIG. 2), the second gate insulating layer 7A and the channel layer 8A are configured as an insular pattern of approximately the same shape in the region where they overlap with the gate electrode 2.

As illustrated in FIG. 1, in the line-intersecting portion PC, the first intersecting layer 7B, which is formed from the second insulation film, and the second intersecting layer 8B, which is formed from the oxide semiconductor film and laminated on the first intersecting layer 7B, are disposed on the first gate insulating layer 6 so as to overlap in part with the gate line 3 located thereunder.

In plan view (FIG. 2), a laminated film pattern configured by the first intersecting layer 7B and the second intersecting layer 8B has approximately the same pattern as the pattern of an insulating layer 14K, which will be described later. Specifically, this laminated film pattern has such an insular pattern that overlaps with the gate line 3 and extends off the pattern of the gate line 3 in the longitudinal direction (the direction in which the source line 11 extends). This portion that extends off in the longitudinal direction covers the edges of the gate line 3 located thereunder in sectional view (FIG. 1). This alleviates the shape of step heights caused by the edges of the gate line 3. Accordingly, the coverage of a film to be provided thereon can be improved.

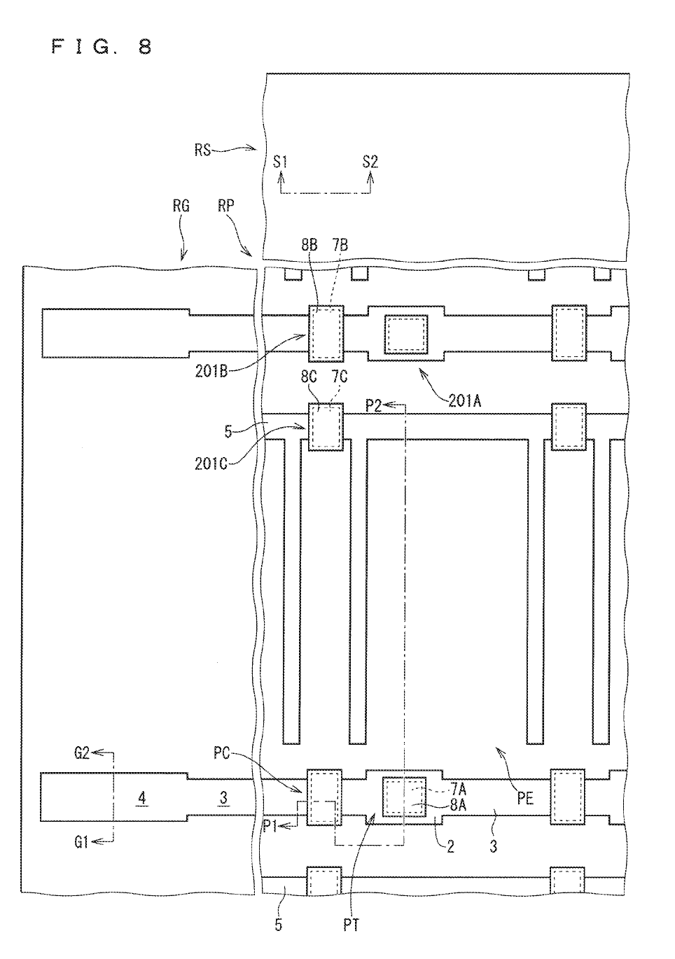

Moreover, another laminated film pattern configured by a second intersecting layer 8C and a first intersecting layer 7C (see FIG. 8) may be provided so as to have almost the same pattern as the pattern of an insulating layer 14L, which will be described later. Specifically, this laminated film pattern has such an insular pattern that overlaps with the common electrode 5 and extends off the pattern of the common electrode 5 in the longitudinal direction (the direction in which the source line 11 extends). This portion that extends off in the longitudinal direction covers the edges of the common electrode 5 located thereunder in sectional view (FIG. 1). This alleviates the shape of step heights caused by the edges of the common electrode 5. Accordingly, the coverage of a film to be provided thereon can be improved.

In the first preferred embodiment, for example, zinc oxide-based (ZnO) oxide semiconductors, InZnSnO-based oxide semiconductors made by adding indium oxide (In₂O₃) and tin oxide (SnO₂) to zinc oxide, and InGaZnO-based oxide semiconductors made by adding gallium oxide (Ga₂O₃) or indium oxide (In₂O₃) to zinc oxide can be used as a material for the oxide semiconductor film. Forming the channel layer 8A of an oxide semiconductor improves mobility, compared to the case of forming the channel layer 8A of amorphous silicon. As a preferable example, InGaZnO is used as the oxide semiconductor.

As a preferable example, InGaZnO, which is the same material as the material for the above-described oxide semiconductor film, is used as a material for the second insulation film after conductivity is imparted thereto. That is, an oxide insulating film made of InGaZnO is used. Such an oxide insulating film can be obtained by, for example, sputtering deposition using an InGaZnO target, in which a mixed gas made by adding an oxygen (O₂) gas to an inert gas (sputtering gas) in group 18 such as a neon (Ne) gas, an argon (Ar) gas, or a krypton (Kr) gas is used as a process gas. The deposited film is further subjected to oxidation treatment through oxygen plasma treatment (treatment for irradiating plasma containing oxygen), so that an insulation film with higher insulating properties can be obtained. In order for the film to be used as an insulation film, the electrical specific resistance value is preferably set to greater than or equal to 1×10⁶ Ωcm, and more preferably greater than or equal to 1×10⁷ Ωcm.

On the other hand, the electrical specific resistance value of the oxide semiconductor film that functions as the channel layer of the TFT is preferably greater than or equal to 0.1 Ωcm and less than 1×10⁶ Ωcm, and more preferably greater than or equal to 1 Ωcm and less than 1×10⁵ Ωcm. The specific resistance values of metal oxides such as InGaZnO can be changed widely by changing the ratio (e.g., pressure ratio) of the oxygen gas that is mixed in the inert gas in group 18 during sputtering deposition.

As described above, as a preferable example, the channel layer 8A made of an InGaZnO semiconductor, which overlaps with the gate electrode 2 in plan view, opposes the pattern of the gate electrode 2 located thereunder via the first gate insulating layer 6 made of SiN and the second gate insulating layer 7A made of an InGaZnO insulator. The channel layer 8A is in direct contact with the second gate insulating layer 7A (oxide insulating layer) disposed as a lower layer and is isolated from the first gate insulating layer 6 (silicon nitride layer) by the second gate insulating layer 7A.

As illustrated in FIG. 1, the source electrode 9, the drain electrode 10, the source line 11, and the source terminal 12 are disposed as patterns formed from a second conductive film. These patterns are disposed on the channel layer 8A, on the second intersecting layer 8B, and on the first gate insulating layer 6 between the channel layer 8A and the second intersecting layer 8B.

In plan view (FIG. 2), the channel layer 8A may have a pattern that corresponds roughly to the pattern of the local insulating layer 14J. The end face of the source electrode 9 and the end face of the drain electrode 10 oppose each other at a given distance in the region where they overlap with the pattern of the channel layer 8A. Of the channel layer 8A, a portion that corresponds to this given distance functions as a channel of the TFT. The source line 11 extends in the longitudinal direction so as to intersect with the gate lines 3 and the common electrode 5 that extend in the lateral direction. The source line 11 and the source electrode 9 are configured as continuous patterns, and the pattern of the source electrode 9 branch off from the pattern of the source line 11. The source terminal 12 is disposed at one end (upper end in FIG. 2) of the sources line 11. The drain electrode 10 is disposed so as to extend off the gate electrode 2 toward the pixel electrode portion PE.

As a preferable example, Mo, which is the same as the material for the aforementioned first conductive film, is used as a material for the second conductive film. A laminated body of the first intersecting layer 7B and the second intersecting layer 8B (FIG. 1) and a laminated body of the first intersecting layer 7C and the second intersecting layer 8C (FIG. 8) are respectively provided in the regions where the source line 11 intersects with the gate line 3 and where the source line 11 intersects with the common electrode 5 in plan view. This improves coverage at the intersections, thus preventing disconnection of the source lines 11 due to step height discontinuity (discontinuity or rupture of films at step heights).

While the laminated body of the second gate insulating layer 7A and the channel layer 8A is included inside the gate electrode 2 in plan view according to the first preferred embodiment, this laminated body, like the laminated body of the first intersecting layer 7B and the second intersecting layer 8B, may extend outward off the gate electrode 2 in the longitudinal direction in FIG. 2. In this case, it is possible to prevent disconnection of the source electrode 9 and the drain electrode 10 due to the influence of step heights caused by the gate electrode 2.

As illustrated in FIG. 1, the local insulating layer 14J formed from a third insulation film (second oxide insulating layer) is disposed on the source electrode 9, the drain electrode 10, and the portion of the channel layer 8A that is between the source electrode 9 and the drain electrode 10.

The local insulating layer 14J may have an insular pattern of approximately the same shape as the laminated film pattern of the second gate insulating layer 7A (not shown in FIG. 2) and the channel layer 8A in plan view (FIG. 2).

As illustrated in FIG. 1, in the line-intersecting portion PC, the first intersecting layer 7B and the second intersecting layer 8B are disposed under the source line 11, and the insulating layer 14K formed from the third insulation film is disposed above the source line 11.

The insulating layer 14K may have an insular pattern of approximately the same shape as the laminated film pattern of the first intersecting layer 7B (not shown in FIG. 2) and the second intersecting layer 8B in plan view (FIG. 2). The insulating layer 14L may have an insular pattern of approximately the same shape as the laminated film pattern of the first intersecting layer 7C (not shown in FIG. 2) and the second intersecting layer 8C in plan view (FIG. 2).

As a preferable example, InGaZnO, which is the same material as the material for the oxide semiconductor film, is used as a material for the third insulation film after conductivity is imparted thereto, as in the case of the second insulation film. The local insulating layer 14J directly covers the upper surface of the channel layer 8A made of an InGaZnO semiconductor and thereby protects the channel layer 8A.

As illustrated in FIG. 1, the protective insulating layer 15 formed from a fourth insulation film is disposed on the upper main surface of the support substrate 1. As a preferable example, silicon nitride, which is the same material as the material for the first insulation film, is used as a material for the fourth insulation film.

In the TFT portion PT (FIG. 1), the pixel drain contact hole 17 is provided so as to expose part of the surface of the drain electrode 10 in a region overlapping with the drain electrode 10 in plan view (FIG. 2). In the gate terminal portion RG (FIG. 1), the gate contact hole 18 is provided so as to expose part of the surface of the gate terminal 4 in a region overlapping with the gate terminal 4 in plan view (FIG. 2). In the source terminal portion RS (FIG. 1), the source contact hole 19 is provided so as to expose part of the surface of the source terminal 12 in a region overlapping with the source terminal 12 in plan view (FIG. 2).

In the first preferred embodiment, as illustrated in FIG. 1, the first insulation film and the fourth insulation film, which form a two-layer SiN film, are disposed above the gate terminal 4, and only the fourth insulation film is disposed above the drain electrode 10 and the source terminal 12, with no other insulating layers disposed thereon. Thus, the pixel drain contact hole 17, the gate contact hole 18, and the source contact hole 19 can be formed simply by etching SiN. Accordingly, these contact holes can be formed with high productivity.

In the TFT portion PT and the pixel electrode portion PE (FIG. 1), the pixel electrode 21 formed from a third conductive film is disposed on the protective insulating layer 15. The pixel electrode 21 has light transmission properties. In plan view (FIG. 2), the pixel electrode 21 is disposed in a region surrounded by the gate electrode 2, the common electrode 5, and the two source lines 11. The pixel electrode 21 overlaps with part of the common electrode 5. The pixel electrode 21 also overlaps with part of the drain electrode 10 in plan view and is electrically connected to the drain electrode 10 through the pixel drain contact hole 17.

In the gate terminal portion RG (FIG. 1), a gate pad 22 formed from the third conductive film is disposed on the protective insulating layer 15 in which the gate contact hole 18 is provided. The gate pad 22 overlaps with the gate contact hole 18 in plan view (FIG. 2) and is electrically connected to the gate terminal 4 through the gate contact hole 18.

In the source terminal portion RS (FIG. 1), a source pad 23 formed from the third conductive film is disposed on the protective insulating layer 15 in which the source contact hole 19 is provided. The source pad 23 overlaps with the source contact hole 19 in plan view (FIG. 2) and is electrically connected to the source terminal 12 through the source contact hole 19.

In the first preferred embodiment, a transparent conductive film (translucent conductive film) is used as the third conductive film. Examples of the transparent conductive film include ITO made by mixing indium oxide (In₂O₃) and tin oxide (SnO₂), and IZO made by mixing indium oxide and zinc oxide (ZnO). As a preferable example, ITO is used. Thus, in the pixel electrode portion PE, the pixel electrode 21 can serve as a transmission pixel electrode having optical transparency. In the gate terminal portion RG or the source terminal portion RS, excellent connection with less tendency to induce exfoliation can be established between the terminal of an integrated circuit (IC) for driving for use in signal input and the gate or source terminal. This enables packaging of a highly reliable IC (Integrated Circuit).

The TFT substrate 701 is configured as described above. According to this configuration, the gate insulating layer has a two-layer structure consisting of the first gate insulating layer 6 and the second gate insulating layer 7A. In the region that is in direct contact with the channel layer 8A, the second gate insulating layer 7A made of a material that is the same material as the material for the channel layer 8A (having the same species of elements and the same crystal structure) and that has given insulating properties is disposed. This configuration reduces defects (e.g., lattice defects derived from interdiffusion of different species of elements or a mismatched crystal structure) at the interface between the channel layer 8A and the gate insulating layer. Accordingly, the characteristics and reliability of the TFT can be improved.

Moreover, the second gate insulating layer 7A made of the oxide insulator is disposed apart from the aforementioned contact holes. Thus, the contact holes are provided in only the first gate insulating layer 6 made of SiN, out of the first gate insulating layer 6 and the second gate insulating layer 7A. This allows the end faces of the contact holes to have a uniform and smooth shape. Accordingly, the coverage of a film to be provided on the contact holes can be improved.

In addition, the local insulating layer 14J made of oxide insulator that is the same material as the material for the channel layer 8A and that is given insulating properties may be provided in the region that is in direct contact with the channel layer 8A, while an SiN film that is widely used as a protective insulating layer in a-Si-TFTs is provided as the protective insulating layer 15. Accordingly, the occurrence of interface defects on the channel layer 8 can be more reduced than in the case where the protective insulating layer 15 is in direct contact with the channel layer 8A. This further improves the characteristics and reliability of the TFT.

Also, the local insulating layer 14J is disposed apart from the contact holes. Thus, the contact holes are provided in only the protective insulating layer 15 made of SiN, out of the laminated film of the local insulating layer 14J and the protective insulating layer 15 that cover the channel layer 8A. This allows the end faces of the contact holes to have a uniform and smooth shape. Accordingly, the coverage of a film to be provided on the contact holes can be improved.

Also, the laminated film pattern of the first intersecting layer 7B and the second intersecting layer 8B is provided on the first gate insulating layer 6 at the intersection between the gate line 3 and the source line 11. This improves the coverage of the source line 11 at the step height of the gate line 3, thus preventing a disconnection failure of the source line 11 caused by step height discontinuity. Also, the dielectric voltage between the gate line 3 and the source line 11 can be improved.

Manufacturing Method

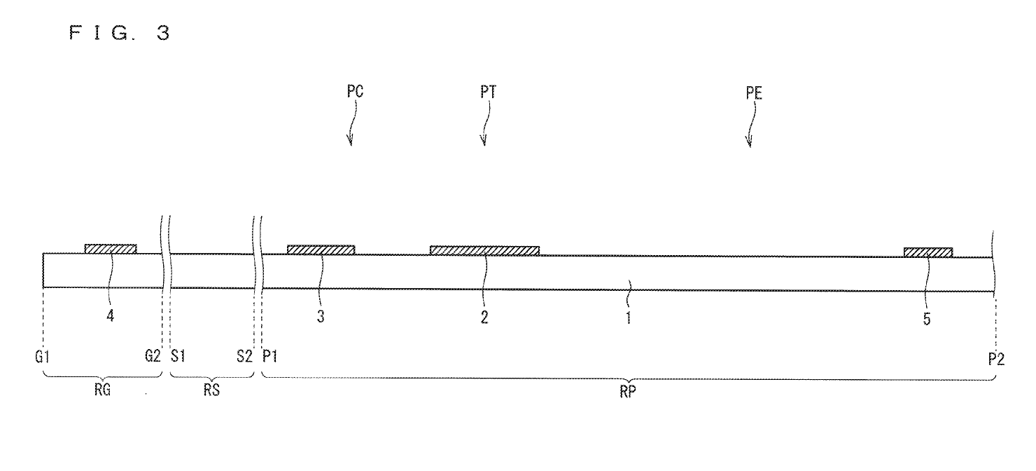

Next, a method of manufacturing the TFT substrate 701 according to the present preferred embodiment is described below with further reference to FIGS. 3 to 15. In these figures, the fields of view in figures that correspond to partial sectional views are the same as the field of view in FIG. 1, and the fields of view in figures that correspond to partial plan views are the same as the field of view in FIG. 2.

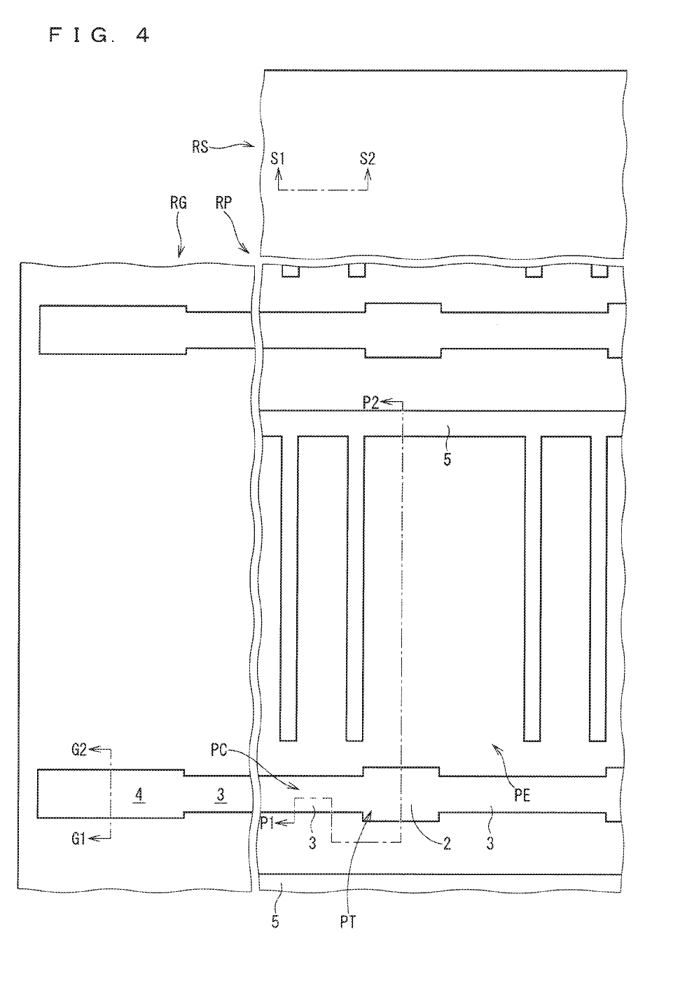

First Photolithographic Process (FIGS. 3 and 4)

First, the support substrate 1 is cleaned with a cleaning fluid or deionized water. As a preferable example, a glass substrate with a thickness of 0.5 mm is used as the support substrate 1. Then, the first conductive film that is to be patterned into the gate electrodes 2, the gate lines 3, and the common electrodes 5 is deposited on the upper main surface of the cleaned support substrate 1.

Examples of the material for the first conductive film include metals such as chromium (Cr), molybdenum (Mo), titanium (Ti), copper (Cu), tantalum (Ta), tungsten (W), and aluminum (Al), and alloys formed primarily of one of these metal elements and with one or more types of other additive elements. Here, the element serving as a principal component refers to an element with a highest content in an alloy of elements. Alternatively, a laminated structure that includes two or more layers made of these metals or alloys may be used. With the use of these metals or alloys, a conductive film with a low specific resistance value of less than or equal to 50 μΩcm can be obtained. As a preferable example, a molybdenum (Mo) film with a thickness of 200 nm is deposited as the first conductive film by sputtering using an argon (Ar) gas.

Thereafter, the first photolithographic process is performed. Specifically, a photoresist material is applied to the top of the first conductive film. The photoresist material is then subjected to pattern exposure and a development process. This produces a photoresist pattern. The development of the photoresist material uses, for example, an organic alkaline developer that contains 2.38 wt % of tetramethyl ammonium hydroxide (TMAH). Then, the first conductive film is patterned by etching using the photoresist pattern as a mask. As a preferable example, wet etching using a solution that contains phosphoric acid, acetic acid, and nitric acid (phosphoric-acetic-nitric acid: PAN). Thereafter, the photoresist pattern is removed. As a result, the patterns of the gate electrode 2, the gate line 3, the gate terminal 4, and the common electrode 5 are formed on the support substrate 1 as illustrated in FIGS. 3 and 4.

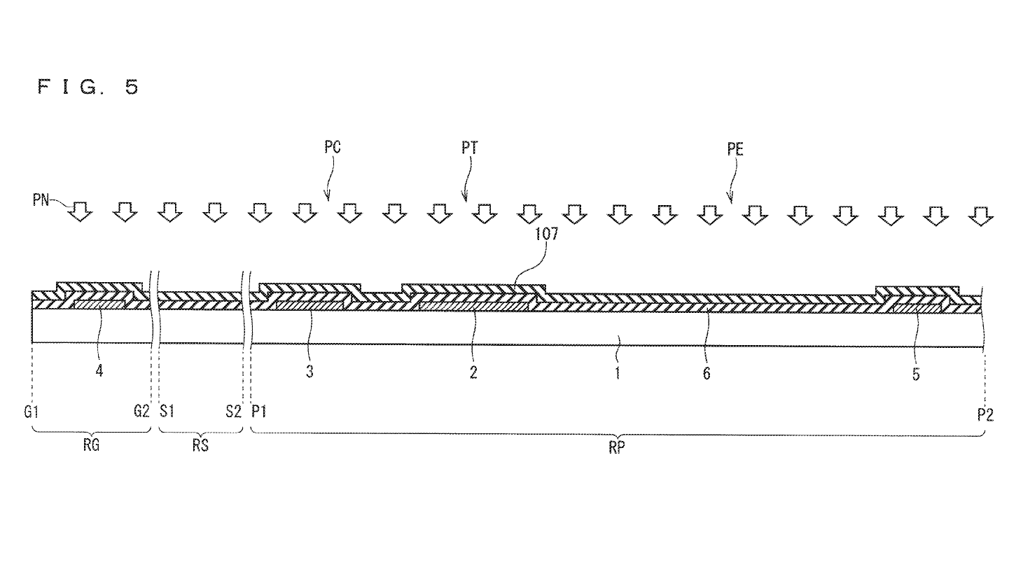

Second Photolithographic Process (FIGS. 5 to 8)

Referring to FIG. 5, the first insulation film that serves as the first gate insulating layer 6 is deposited. As a preferable example, an SiN film with a thickness of 400 nm is deposited by PECVD using a silane (SiH₄) gas, an ammonia (NH₃) gas, and a nitrogen (N₂) gas as source gases. Since the deposition of the SiN film by PECVD uses the source gases that contain a large volume of hydrogen (H), the deposited SiN film contains 20 to 25 at % of hydrogen. The SiN film has a high barrier ability (interrupting ability) against impurity elements that adversely affects TFT characteristics, such as moisture (H₂O), sodium (Na), or potassium (K), and therefore can prevent impurities contained in, for example, the support substrate 1 and the gate electrode 2 from being diffused into the channel layer 8A (FIG. 1).

Then, a second insulation film 107 (first oxide insulating layer) is deposited on the above-described first insulation film. As a preferable example, sputtering using a target made of oxide containing In, Ga, and Zn (e.g., InGaZnO) is used as a film deposition method. Specifically, an InGaZnO film with a thickness of 100 nm is deposited by sputtering using an In—Ga—Zn—O [In₂O₃.Ga₂O₃.2(ZnO)] target whose atomic composition ratio of In:Ga:Zn:O is 1:1:1:4 and a mixed gas made by adding an O₂ gas to an Ar gas. As a preferable example, the partial pressure ratio between the Ar gas and the O₂ gas is set to 1:1 (i.e., the partial pressure ratio between O₂ and A is 50%) so as to allow deposition of an oxide insulating film of InGaZnO having a specific resistance value of greater than or equal to 5×10⁶ Ωcm and insulating properties. This sputtering deposition does not use an H₂ gas, and therefore the resultant film does not contain a large number of H atoms.

Note that the gas used in the sputtering deposition of the second insulation film 107 may be an Ne gas or a Kr gas that is an inert gas in group 18, instead of an Ar gas. In particular, in the case of using Kr whose atomic weight is greater than the atomic weight of Ar, an InGaZnO insulation film with a higher density of film can be obtained. Increasing the density of film leads to an improvement in dielectric voltage (dielectric breakdown resistance). While the partial pressure ratio between 02 and Ar is set to 50% in the above-described preferable example, the partial pressure ratio is not limited to this, and may be appropriately adjusted depending on the sputtering device to be used so as to achieve a specific resistance value of greater than or equal to 1×10⁶ Ωcm.

As another preferable example, plasma using a dinitrogen monoxide (N₂O) gas is applied to the upper main surface of the support substrate 1 as indicated by arrows PN (FIG. 5) after the InGaZnO insulation film serving as the second insulation film 107 is deposited on the upper main surface of the support substrate 1. That is, the InGaZnO insulation film is subjected to N₂O plasma treatment. This accelerates oxidation of the InGaZnO insulation film (increases the oxygen concentration), thus making the specific resistance value thereof greater than or equal to 1×10⁷ Ωcm. Accordingly, insulation electrical performance can be further enhanced.

Note that, for example, wet treatment for immersing the support substrate 1 in a chemical solution that contains cerium ammonium nitrate (CAN), e.g., a chemical solution of 5 to 50 wt % of CAN and water (H₂O), may be performed instead of the N₂O plasma treatment. Alternatively, a chemical solution made by adding 2 to 10 wt % of perchloric acid or 5 to 40 wt % of nitric acid to the chemical solution of CAN may be used. As another alternative, both of the N₂O plasma treatment and the treatment using a chemical solution of CAN may be performed. This accelerates oxidation of the InGaZnO insulation film (increases the oxygen concentration), thus making the specific resistance value thereof greater than or equal to 1×10⁷ Ωcm. Accordingly, insulation electrical performance can be further enhanced.

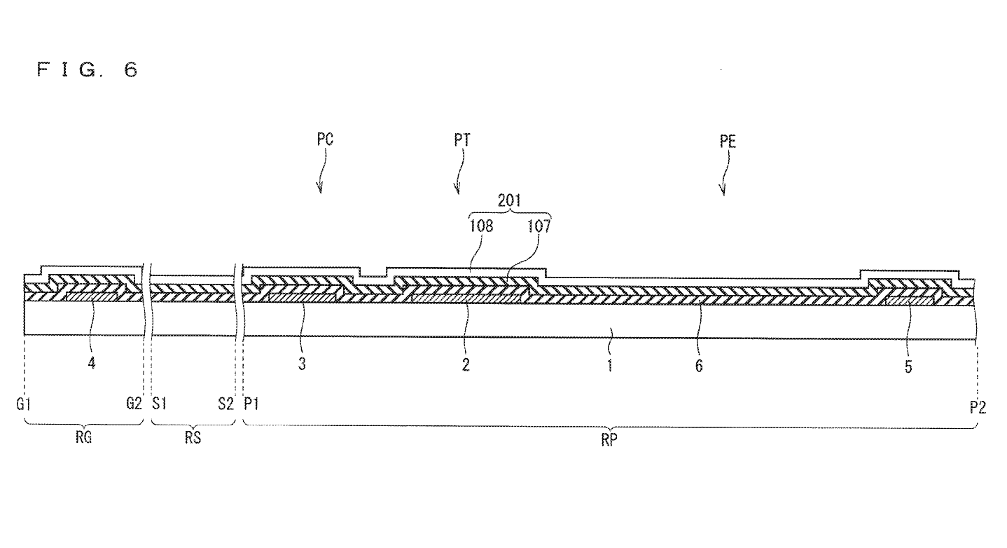

Referring to FIG. 6, next, an oxide semiconductor film 108 that serves as the channel layer 8A (FIG. 1) is deposited on the second insulation film 107. As a result, a laminated film 201 of the second insulation film 107 and the oxide semiconductor film 108 is formed. As a preferable example, sputtering using a target made of oxide containing In, Ga, and Zn (e.g., InGaZnO) is used as a film deposition method, as in the case of the second insulation film 107. Specifically, an InGaZnO film with a thickness of 50 nm is deposited by sputtering using an In—Ga—Zn—O [In₂O₃.Ga₂O₃.2(ZnO)] target whose atomic composition ratio of In:Ga:Zn:O is 1:1:1:4 and a mixed gas made by adding an O₂ gas to an Ar gas. As a preferable example, the partial pressure ratio between the O₂ gas and the Ar gas at this time is set to 10%. This enables deposition of an oxide semiconductor film made of InGaZnO and with a specific resistance value of 1×10⁴ Ωcm.

Note that the gas used in the sputtering deposition of the oxide semiconductor film 108 may be an Ne gas or a Kr gas that is an inert gas in group 18, instead of the Ar gas. In particular, in the case of using Kr whose atomic weight is greater than the atomic weight of Ar, an InGaZnO semiconductor film with a higher density of film can be obtained. Increasing the density of film can more stabilize the characteristics of the oxide semiconductor film 108 and improve the reliability thereof. While the partial pressure ratio between O₂ and Ar is set to 10% in the above-described preferable example, the partial pressure ratio is not limited to this, and may be appropriately adjusted depending on the sputtering device to be used so as to achieve a specific resistance value of greater than or equal to 0.1 Ωcm and less than 1×10⁶ Ωcm, more preferably greater than or equal to 1 Ωcm and less than 1×10⁵ Ωcm. In general, the specific resistance values of metal oxide films typified by InGaZnO-based films can be easily changed by changing the partial pressure ratio between the O₂ gas and the Ar (or Ne or Kr) gas during sputtering. Reducing the partial pressure ratio leads to a reduction in the specific resistance value, whereas increasing the partial pressure ratio leads to an increase in the specific resistance value.

Thereafter, the second photolithographic process is performed. Specifically, a photoresist material is applied to the top of the laminated film 201, and then a photoresist pattern is formed. The laminated film 201 is patterned by etching using the photoresist pattern as a mask. As a preferable example, wet etching using an oxalic acid-based chemical solution that contains 5 wt % of oxalic acid and water is performed. Since both of the oxide semiconductor film 108 and the second insulation film 107 are made of InGaZnO, they can be collectively etched. Thereafter, the photoresist pattern is removed.

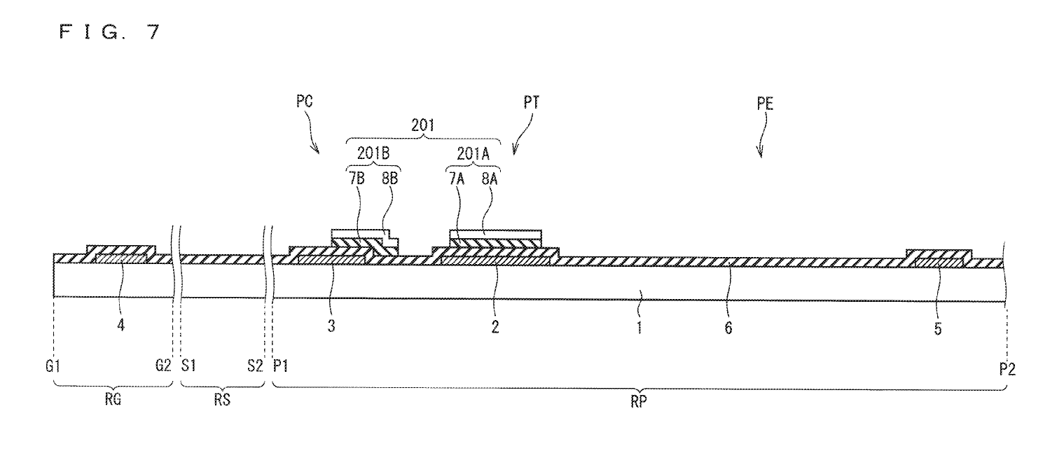

Referring to FIGS. 7 and 8, laminated film patterns 201A to 201C are thereby formed. The laminated film pattern 201A is formed as an insular pattern in a region that overlaps with the gate electrode 2 in plan view. In plan view, the laminated film pattern 201B overlaps with the gate line 3 and is formed as an insular pattern in a region that extends off the gate line 3 in the direction in which the source line 11 (FIG. 2) extends (in the longitudinal direction in FIG. 8). In plan view, the laminated film pattern 201C overlaps with the common electrode 5 and is formed as an insular pattern in a region that extends off the common electrode 5 in the direction in which the source line 11 (FIG. 2) extends (in the longitudinal direction in FIG. 8). The laminated film pattern 201A includes the second gate insulating layer 7A and the channel layer 8A that have approximately the same shape. The laminated film pattern 201B includes the first intersecting layer 7B and the second intersecting layer 8B that have approximately the same shape. The laminated film pattern 201C includes the first intersecting layer 7C and the second intersecting layer 8C that have approximately the same shape.

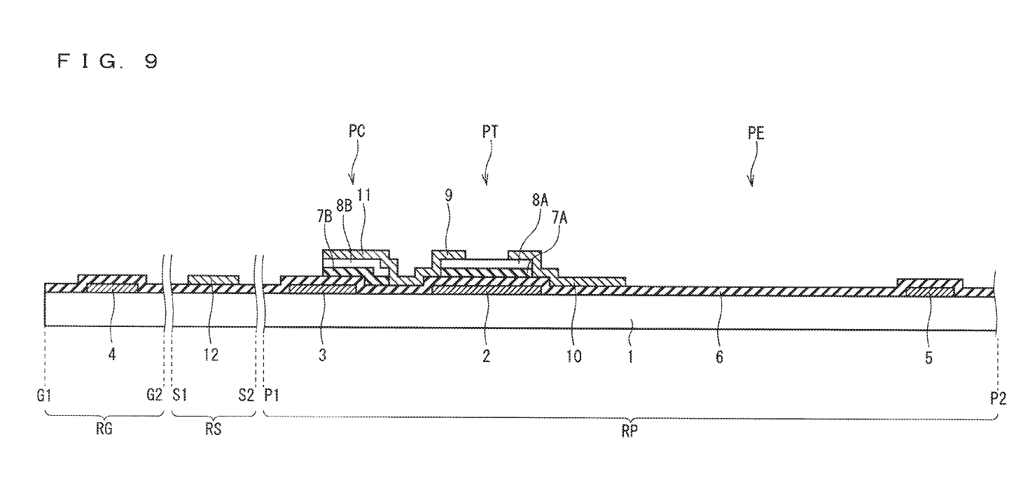

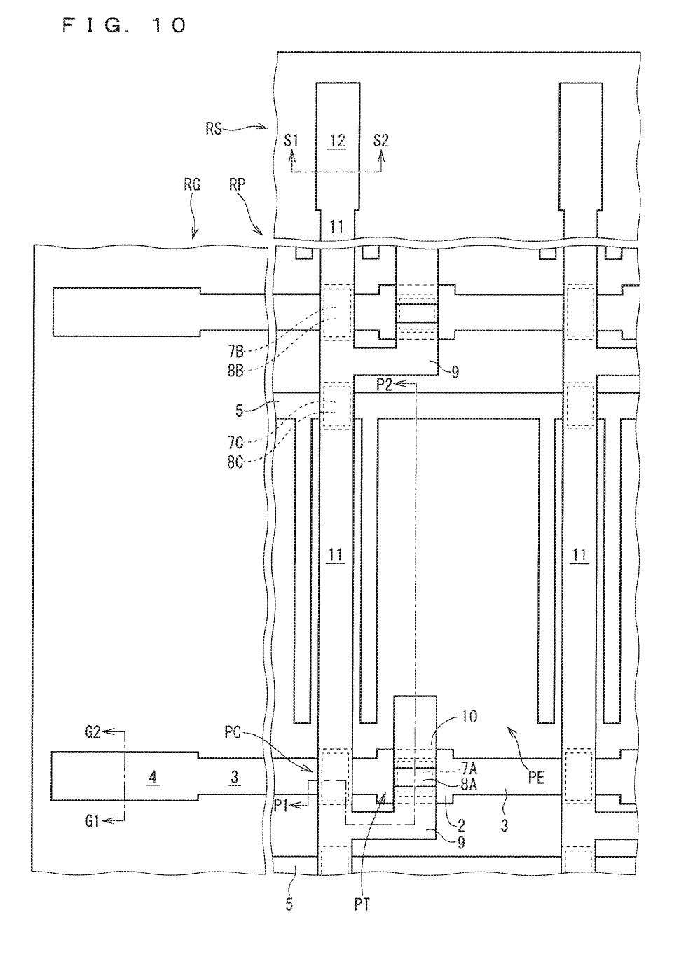

Third Photolithographic Process (FIGS. 9 and 10)

Referring to FIGS. 9 and 10, next, the second conductive film that is to be patterned into, for example, the source electrode 9, the drain electrode 10, and the source line 11 is deposited. As a preferable example, a molybdenum (Mo) film with a thickness of 200 nm is deposited by sputtering using an argon (Ar) gas in a similar manner to the first conductive film.

Thereafter, the third photolithographic process is performed. Specifically, a photoresist pattern is formed on the second conductive film. The second conductive film is patterned by etching using the photoresist pattern as a mask. As a preferable example, wet etching using a chemical solution of PAN is performed in a similar manner to the patterning of the first conductive film.

Thereafter, the photoresist pattern is removed. As a result, as illustrated in FIGS. 9 and 10, the source electrode 9 and the drain electrode 10 are formed on the channel layer 8A and the first gate insulating layer 6 in the TFT portion PT, the source line 11 is formed on the second intersecting layer 8B and the first gate insulating layer 6 in the line-intersecting portion PC, and the source terminal 12 is formed on the first gate insulating layer 6 in the source terminal portion RS.

The laminated body (FIG. 8) of the first intersecting layer 7B and the second intersecting layer 8B and the laminated body of the first intersecting layer 7C and the second intersecting layer 8C (FIG. 8) are provided respectively in the regions in plan view (FIG. 10) where the source line 11 intersects with the gate line 3 and where the source line 11 intersects with the common electrode 5. This improves coverage at the intersections. Thus, it is possible to prevent disconnection of the source line 11 due to step height discontinuity (discontinuity or rupture of films at step heights).

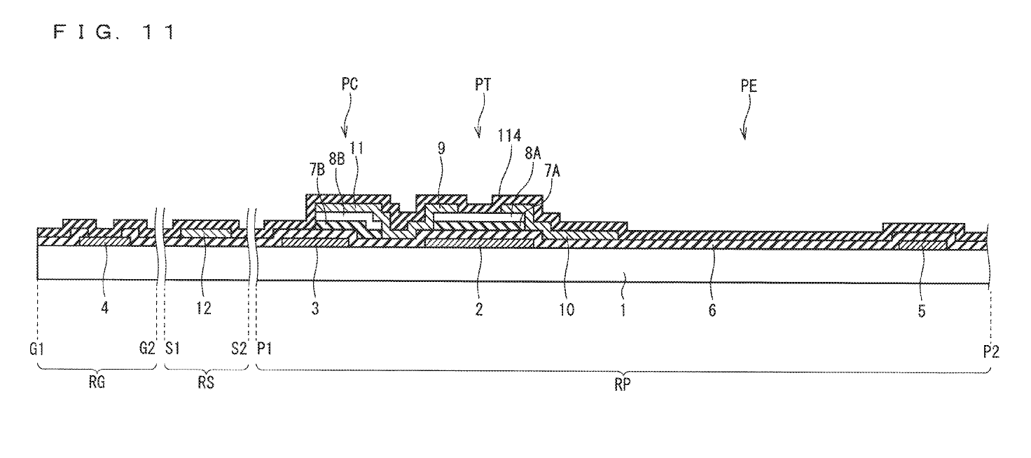

Fourth Photolithographic Process (FIGS. 11 to 13)

Referring to FIG. 11, next, a third insulation film 114 (second oxide insulating layer) is deposited. A film deposition method to be used may be similar to that used for the second insulation film 107. As a preferable example, an InGaZnO film having insulating properties is deposited to a thickness of 100 nm by a similar method to that used for the aforementioned second insulation film 107.

Thereafter, the fourth photolithographic process is performed. Specifically, a photoresist material is applied to the top of the third insulation film 114 and used to form a photoresist pattern. In the first preferred embodiment, the same photoresist pattern as the photoresist pattern used in the aforementioned second photolithographic process is used. Thereafter, the third insulation film 114 is patterned by etching using the photoresist pattern as a mask. As a preferable example, wet etching using an oxalic acid-based chemical solution that contains 5 wt % of oxalic acid and water is performed in a similar manner to the etching of the second insulation film. Thereafter, the photoresist pattern is removed.

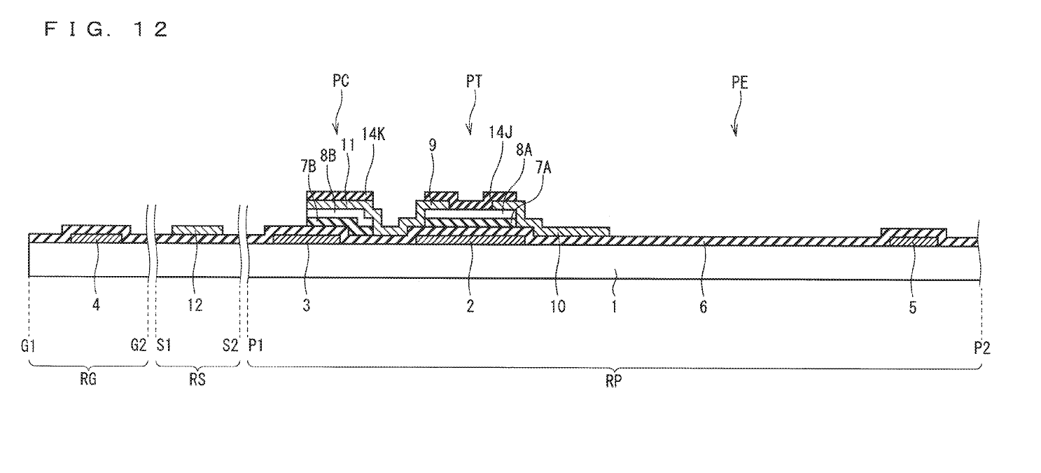

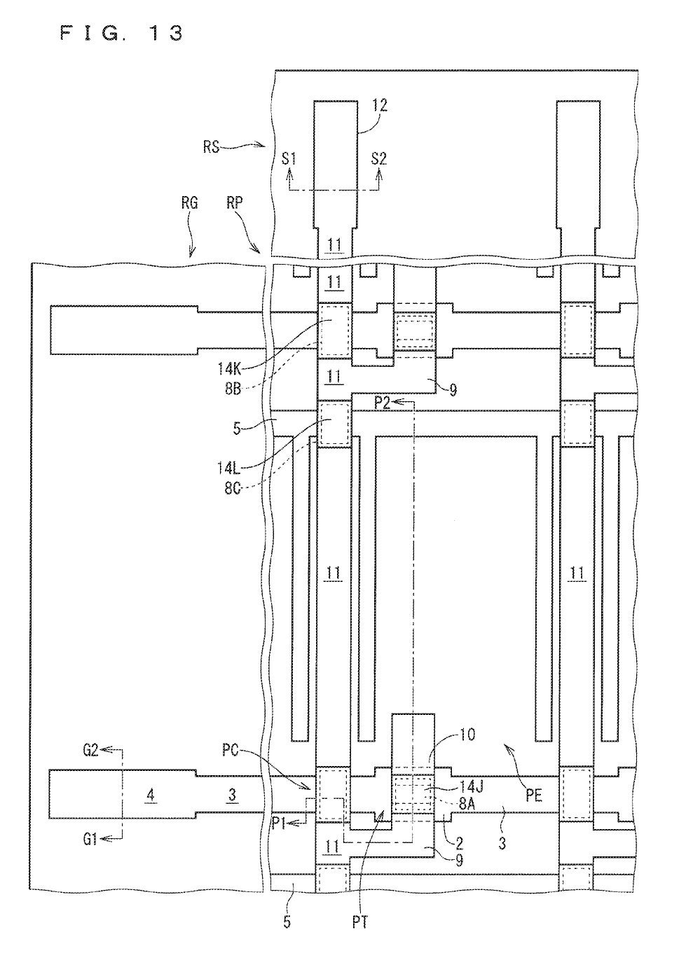

Through the above-described patterning, the local insulating layer 14J is formed on the edge portion of the source electrode 9, on the edge portion of the drain electrode 10, and on a portion of the channel layer 8A that is exposed between the source electrode 9 and the drain electrode 10 in the TFT portion PT as illustrated in FIGS. 12 and 13. In the line-intersecting portion PC, the insulating layer 14K may be formed on the source line 11. Also, the insulating layer 14L (FIG. 13) may be formed at the intersection between the source line 11 and the common electrode 5.

In the first preferred embodiment, the patterning of the third insulation film 114 uses the photoresist pattern used in the aforementioned second photolithographic process. Thus, the pattern of the local insulating layer 14J formed from the third insulation film 114 is approximately the same as the laminated film pattern of the second gate insulating layer 7A and the channel layer 8A in plan view (FIG. 13). Also, the pattern of the insulating layer 14K is approximately the same as the laminated film pattern of the first intersecting layer 7B and the second intersecting layer 8B. Moreover, the pattern of the insulating layer 14L is of approximately the same shape as the laminated film pattern of the first intersecting layer 7C and the second intersecting layer 8C.

By sharing the photoresist pattern between the second and fourth photolithographic processes as described above, the number of photomasks used in the photolithographic processes can be reduced. This reduces the manufacturing cost. Note that when there is no particular need to share the mask, another photomask may be prepared for the fourth photolithographic process. In that case, the insulating layer 14K and the insulating layer 14L can be omitted while the local insulating layer 14J is formed.

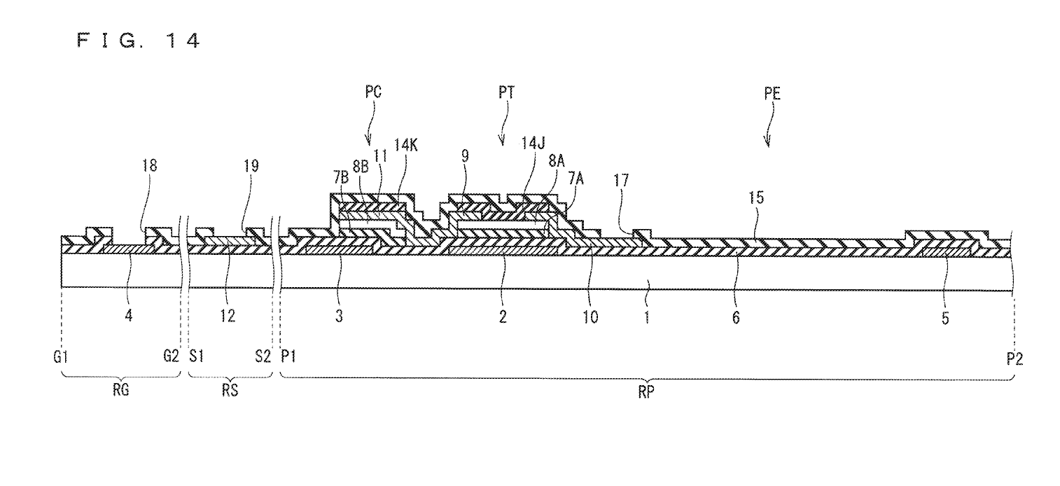

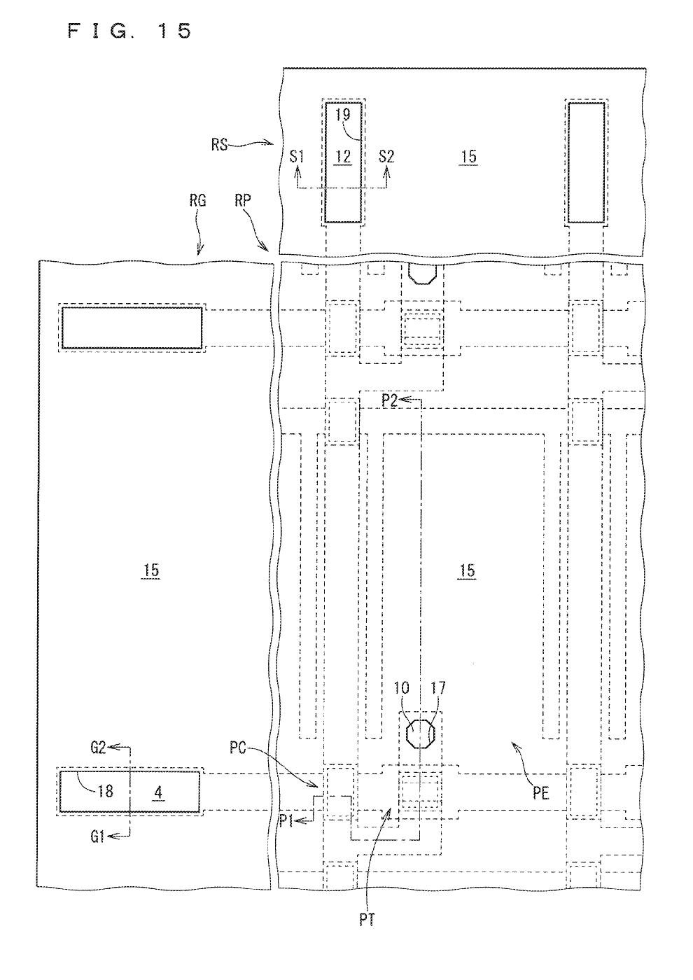

Fifth Photolithographic Process (FIGS. 14 and 15)

Next, the fourth insulation film that serves as the protective insulating layer 15 is deposited. As a preferable example, an SiN film with a thickness of 200 nm is deposited by a similar film deposition method to that used in the case of the first insulation film serving as the first gate insulating layer 6, i.e., by PECVD using a silane (SiH₄) gas, an ammonia (NH₃) gas, and a nitrogen (N₂) gas as source gases. The SiN film deposited by PECVD, which uses the source gases that contain a large volume of hydrogen (H), contain 20 to 25 at % of hydrogen, but, on the other hand, has a high barrier ability (interrupting ability) against impurity elements that adversely affect TFT characteristics, such as moisture (H₂O), sodium (Na), or potassium (K). Thus, it is possible to prevent impurities coming from external environments from being diffused into the channel layer 8A.

Thereafter, the fifth photolithographic process is performed. Specifically, a photoresist pattern is formed, and etching is performed using the photoresist pattern as a mask. As a result, the fourth insulation film and the first insulation film that are made of SiN, i.e., the protective insulating layer 15 and the first gate insulating layer 6, are patterned. This etching may be dry etching using a gas that contains fluorine. As a preferable example, dry etching using a gas made by adding oxygen (O₂) to sulfur hexafluoride (SF₆) is used. Thereafter, the photoresist pattern is removed.

Through this patterning, the pixel drain contact hole 17 that penetrates the protective insulating layer 15, the source contact hole 19 that penetrates the protective insulating layer 15, and the gate contact hole 18 that penetrates the protective insulating layer 15 and the first gate insulating layer 6 are formed simultaneously as illustrated in FIGS. 14 and 15. Accordingly, the pixel drain contact hole 17 exposes part of the surface of the drain electrode 10, the gate contact hole 18 exposes part of the surface of the gate terminal 4, and the source contact hole 19 exposes part of the surface of the source terminal 12.

Sixth Photolithographic Process

Referring back to FIGS. 1 and 2, next, the third conductive film that is to be patterned into the pixel electrodes 21, the gate pads 22, and the source pads 23 is deposited. In the first preferred embodiment, a transparent conductive film (translucent conductive film) is used as the third conductive film. As a preferable example, ITO (mixture of indium oxide (In₂O₃) and tin oxide (SnO₂)) is used as a material for the transparent conductive film, and the mixture ratio thereof is, for example, 90:10 (weight percentage). As a preferable example, an ITO film with a thickness of 100 nm is deposited in an amorphous state by sputtering using an Ar gas mixed with H atoms. To mix H atoms, for example, an H₂ gas or water vapor (H₂O) is used.

Then, the sixth photolithographic process is performed. Specifically, a photoresist pattern is formed, and the third conductive film is patterned by etching using the photoresist pattern as a mask. As a preferable example, an amorphous ITO film is patterned by wet etching using an oxalic acid-based chemical solution that contains 5 wt % of oxalic acid and water. Thereafter, the photoresist pattern is removed.

In the case of using an amorphous ITO film as described above, next, the overall support substrate 1 is heated at 200° C. This heating causes the amorphous ITO film to crystallize into a polycrystalline ITO film. Note that the heating temperature is not limited to 200° C. In the case of using a common amorphous ITO film with a mixture ratio containing 85 to 95 wt % of indium oxide (In₂O₃) and 5 to 15 wt % of tin oxide (SnO₂) (the sum of both is 100 wt %), crystallization can be induced at a heating temperature of 140° C. or higher. On the other hand, the upper limit of the heating temperature may be determined in consideration of the heat resistant temperatures of materials for layers formed on the TFT substrate 701.

Through the above-described patterning, from the transparent conductive film (polycrystalline ITO film), the pixel electrode 21 in the TFT portion PT and the pixel electrode portion PE, the gate pad 22 in the gate terminal portion RG, and the source pad 23 in the source terminal portion RS are formed as illustrated in FIGS. 1 and 2.

Part of the pixel electrode 21 is connected directly to the drain electrode 10 located thereunder through the pixel drain contact hole 17. Also, part of the edge portion of the pixel electrode 21 is disposed so as to overlap with the common electrode 5 located thereunder via the first gate insulating layer 6 and the protective insulating layer 15 in plan view, thereby forming part of a holding capacitor for holding the potential of the pixel. The gate pad 22 is directly connected to the gate terminal 4 through the gate contact hole 18. The source pad 23 is directly connected to the source terminal 12 through the source contact hole 19.

The TFT substrate 701 according to the first preferred embodiment is thereby completed. Note that in the case of assembling a liquid crystal display panel, an alignment film is formed on the surface of the completed TFT substrate 701. The alignment film is a film for aligning a liquid crystal and is made of polyimide, for example. Also, a counter substrate that is separately prepared and includes, for example, a color filter, a counter electrode, and an alignment film is bonded to the TFT substrate 701. At this time, a spacer formed on the surface of either the TFT substrate 701 or the counter substrate forms a space between the TFT substrate 701 and the counter substrate. This space is sealed with a liquid crystal layer. This completes a liquid crystal display panel using the TN mode as a longitudinal electric field mode. Finally, other constituent elements such as a polarizing plate, a phase difference plate, a driving circuit, and a backlight unit are disposed on the outer side of the liquid crystal display panel, and the liquid crystal display is thereby completed.

Summary of Manufacturing Method

The gate lines 3 that includes the gate electrodes 2 disposed respectively in each of the plurality of pixel regions, and the gate terminals 4 connected to the gate lines 3 are formed on the support substrate 1. The first gate insulating layer 6 that covers the gate lines 3 and the gate terminals 4 is made of silicon nitride.

The laminated film 201 is formed on the first gate insulating layer 6. The step of forming the laminated film 201 includes the step of depositing the second insulation film 107 (first oxide insulating layer) on the first gate insulating layer 6 by sputtering and the step of depositing the oxide semiconductor film 108 (oxide semiconductor layer) on the second insulation film 107 by sputtering. The sputtering material used in the step of depositing the second insulation film 107 and the sputtering material used in the step of depositing the oxide semiconductor film 108 are made of oxide and have a common species of elements and a common crystal structure.

Through the patterning of the laminated film 201, the second gate insulating layer 7A provided in each of the plurality of pixel regions on the gate electrode 2 via the first gate insulating layer 6, and the first intersecting layer 7B provided on the gate line 3 via the first gate insulating layer 6 and intersecting with the gate line 3 are formed from the second insulation film 107, and the channel layer 8A provided on the second gate insulating layer 7A and having the same shape as the second gate insulating layer 7A, and the second intersecting layer 8B provided on the first intersecting layer 7B and having the same shape as the first intersecting layer 7B are formed from the oxide semiconductor film 108.

The source electrodes 9 and the drain electrodes 10 that are spaced from and oppose each other on the channel layer 8A, the source lines 11 that are connected to the source electrodes 9 and intersect with the gate lines 3 on the second intersecting layer 8B, and the source terminals 12 that are connected to the source lines 11 are formed. The protective insulating layer 15 that covers the channel layer 8A, the gate lines 3, the gate terminals 4, the source lines 11, and the source terminals 12 is made of silicon nitride. The gate contact holes 18 that reach the gate terminals 4 are formed in the first gate insulating layer 6 and the protective insulating layer 15, and the source contact holes 19 that reach the source terminals 12 are formed in the protective insulating layer 15.

The step of forming the laminated film 201 may include the step of accelerating oxidation of the second insulation film 107 after the step of depositing the second insulation film 107 and before the step of depositing the oxide semiconductor film 108.

Before the formation of the protective insulating layer 15, the third insulation film 114 (second oxide insulating layer) may be deposited directly on the channel layer 8A by sputtering using a sputtering material that is made of oxide and has a common species of elements and a common crystal structure. Also, before the step of forming the protective insulating layer 15, the local insulating layer 14J that directly covers the channel layer 8A may be formed by patterning the third insulation film 114.

Advantageous Effects

According to the present preferred embodiment, the channel layer 8A and the second gate insulating layer 7A in contact with the channel layer 8A are made of oxide and have a common species of elements and a common crystal structure. Thus, structural defects are less likely to occur at the interface between the channel layer 8A and the gate insulating layer, and accordingly the characteristics of the TFT substrate 701 are improved.

Also, the first intersecting layer 7B and the second intersecting layer 8B intersect with the gate lines 3, and the source lines 11 intersect with the gate lines 3 via the first intersecting layer 7B and the second intersecting layer 8B. This reduces the possibility of unintentional disconnection of the source lines 11 due to the influence of step heights caused by the gate lines 3. Accordingly, the reliability and manufacturing yield of the thin-film transistor are improved.

Also, all the layers penetrated by the gate contact holes 18 and the source contact holes 19 are formed not of oxide but of silicon nitride. This configuration is similar to that of TFT substrates using a-Si, and as in the case of TFT substrates using a-Si as their semiconducting materials, contact holes can be easily formed in the TFT substrate 701 using an oxide semiconductor. Accordingly, the TFT substrate 701 can be manufactured with high yield and high productivity.

In addition, the first gate insulating layer 6 and the protective insulating layer 15 in which the gate contact holes 18 are formed are both made of silicon nitride. Thus, the end faces of the contact holes can be formed in a uniform and smooth shape. This improves the coverage of the third conductive film that is formed on the gate contact hole 18 in order to form the gate pad 22. Accordingly, favorable electrical connection can be established between the gate pad 22 and the gate terminal 4 located thereunder.

The channel layer 8A and the local insulating layer 14J that is in contact with the channel layer 8A are made of oxide and have a common species of elements and a common crystal structure. Thus, structural defects are less likely to occur at the interface between the channel layer 8A and the local insulating layer 14J. This improves the characteristics of the TFT substrate 701.

The step of forming the laminated film 201 includes the step of accelerating oxidation of the second insulation film 107 after the step of depositing the second insulation film 107 and before the step of depositing the oxide semiconductor film 108. This stabilizes electrical insulating characteristics of the second insulation film 107 that serves as the first gate insulating layer 6.

The channel layer 8A and the second gate insulating layer 7A are made of oxide and have common species of elements and a common crystal structure, and also have the same shape. Accordingly, these layers can be patterned simultaneously and with ease.

### Second Preferred Embodiment

Overview

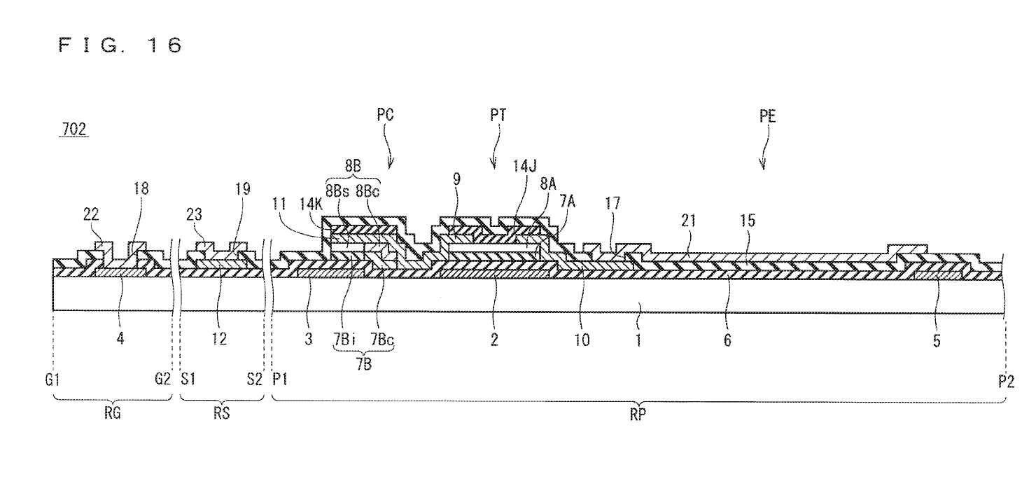

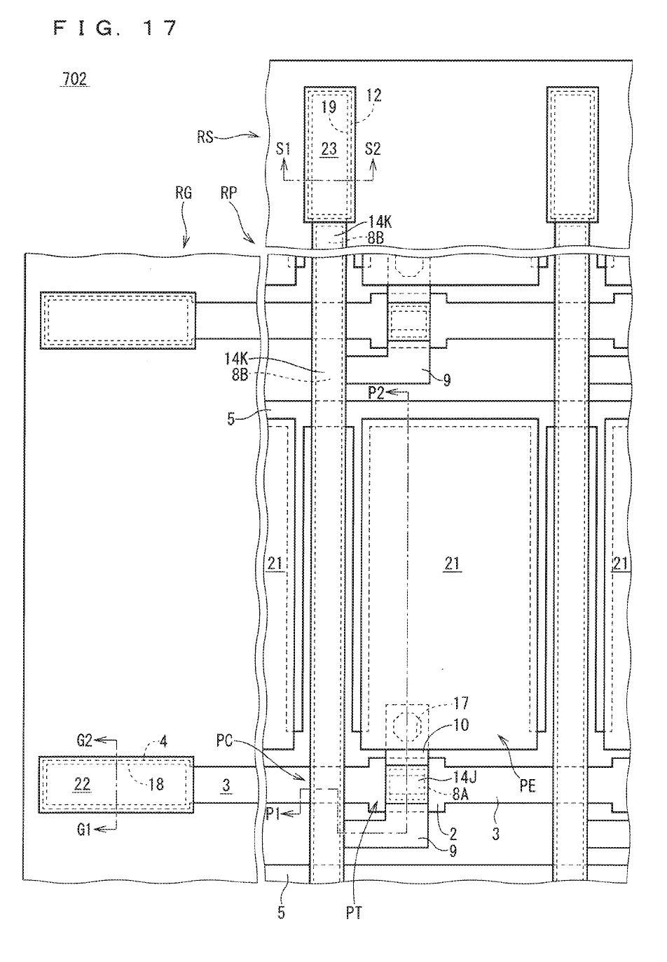

FIGS. 16 and 17 are respectively a partial sectional view and a partial plan view schematically illustrating a configuration of a thin-film transistor substrate (TFT substrate) 702 according to a second preferred embodiment. The section illustrated in FIG. 16 is taken along line G1-G2 in the gate terminal portion RG, line S1-S2 in the source terminal portion RS, and line P1-P2 in the pixel portion RP in FIG. 17. Note that part of the configuration is not shown in FIG. 17 in order to facilitate viewing of the internal configuration of the TFT substrate 702.

In the TFT substrate 702, unlike in the TFT substrate 701 (first preferred embodiment in FIGS. 1 and 2), of the first intersecting layer 7B and the second intersecting layer 8B, portions that extend off the gate lines 3 and the common electrodes 5 in plan view (FIG. 17) have conductivity. This conductivity can be easily obtained by applying ultraviolet light to a region made of oxide while using the gate lines 3 and the common electrode 5 as masks. When conductivity is imparted, the electrical specific resistance value is preferably less than 0.1 Ωcm, and more preferably less than 1×10⁻² Ωcm.

In the second preferred embodiment, the laminated film patterns of the first intersecting layer 7B and the second intersecting layer 8B extend almost all over the source lines 11. Thus, the laminated film patterns of the first intersecting layer 7B and the second intersecting layer 8B intersect with not only the gate lines 3 but also the common electrodes 5 in plan view (FIG. 17). Moreover, each of the laminated film patterns disposed corresponding to each source line 11 may intersect with all of the gate lines 3 on the TFT substrate 701. Portion of the laminated film patterns that have conductivity function as redundant lines of the source lines 11. Thus, even if the source lines 11 are disconnected due to a pattern failure or other factors, a failure in the TFT substrate 702 can be avoided unless the disconnected portions overlap with the gate lines 3 and the common electrodes 5. This improves the reliability of the TFT substrate. In addition, almost the same effects as those described in the first preferred embodiment can also be achieved.

Note that the configuration other than that described above is similar to the configuration of the above-described first preferred embodiment, and therefore identical or corresponding constituent elements are given the same reference numerals, and a detailed description thereof is not repeated.

Details of Structure

As described above, the second preferred embodiment is different from the first preferred embodiment in that the laminated film patterns of the first intersecting layer 7B (not shown in FIG. 17) and the second intersecting layer 8B have approximately the same shape as the patterns of the source lines 11 in plan view (FIG. 17). Thus, these laminated film patterns intersect with not only the gate lines 3 but also the common electrodes 5 in plan view. This laminated bodies may extend to the vicinity of the source contact holes 19, but they are preferably separated from the source contact holes 19.

The first intersecting layer 7B includes an insulator portion 7Bi and a conductor portion 7Bc. Of the first intersecting layer 7B, the insulator portion 7Bi is a portion that overlaps with one of the gate lines 3 and the common electrodes 5 in plan view (FIG. 17). Of the first intersecting layer 7B, the conductor portion 7Bc is a portion that does not overlap with any of the gate lines 3 and the common electrodes 5 in plan view (FIG. 17). The insulator portion 7Bi has insulating properties, and the conductor portion 7Bc has conductivity. Similarly, a second intersecting layer 8B includes a semiconductor portion 8Bs and a conductor portion 8Bc. Of the second intersecting layer 8B, the semiconductor portion 8Bs is a portion that overlaps with one of the gate lines 3 and the common electrodes 5 in plan view (FIG. 17). Of the second intersecting layer 8B, the conductor portion 8Bc is a portion that does not overlap with any of the gate lines 3 and the common electrodes 5 in plan view (FIG. 17). The semiconductor portion 8Bs has semiconducting properties, and the conductor portion 8Bc has conductivity. This conductivity preferably corresponds to electrical specific resistance values of less than 0.1 Ωcm, and more preferably electrical specific resistance values of less than 1×10⁻² Ωcm. When the first intersecting layer 7B and the second intersecting layer 8B are made of InGaZnO, it is easy to adjust the electrical specific resistance value within such a range. As will be described in detail layer, the conductor portion 7Bc and the conductor portion 8Bc are portions to which conductivity is imparted by the application of ultraviolet light.

Manufacturing Method

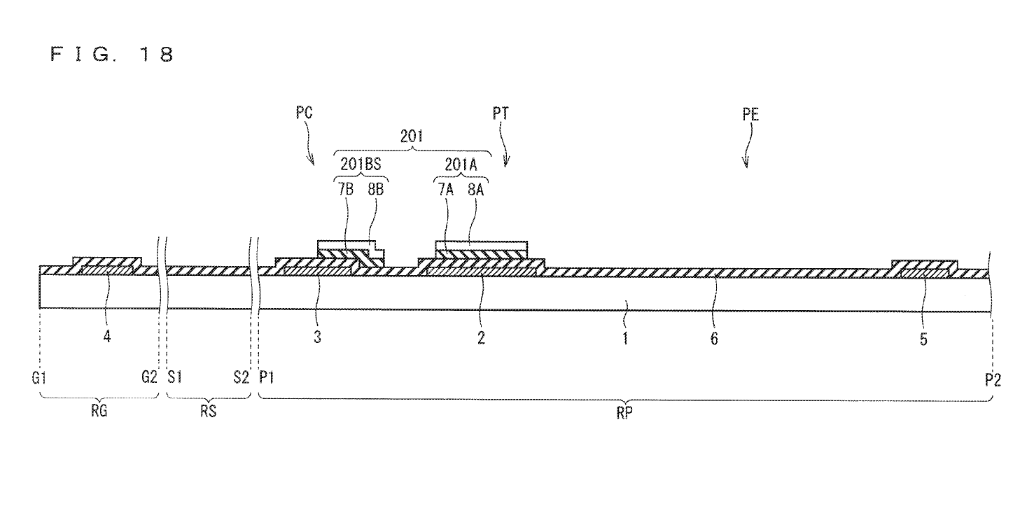

Next, a method of manufacturing the TFT substrate 702 according to the present preferred embodiment is described below with further reference to FIGS. 18 to 27. Among these figures, the fields of view in figures that correspond to partial sectional views are the same as the field of view in FIG. 16, and the fields of view in figures that correspond to partial plan views are the same as the field of view in FIG. 17.

First and Second Photolithographic Process

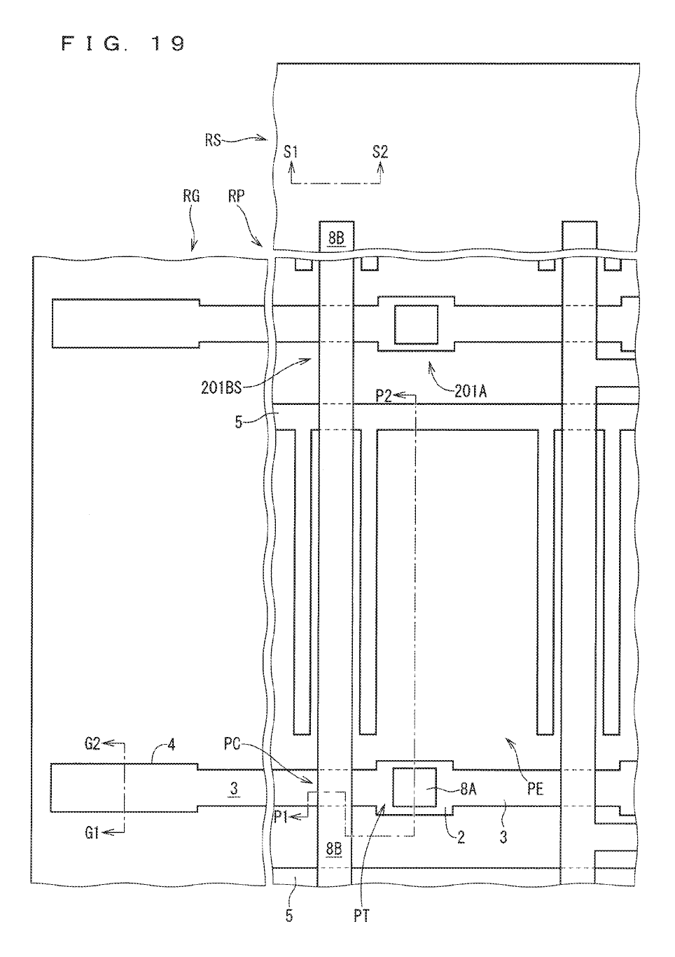

Referring to FIGS. 18 and 19, steps that are almost the same as the steps up to FIGS. 7 and 8 (first preferred embodiment) and that include the first and second photolithographic processes are performed. Note however that, instead of the laminated film patterns 201B and 201C (first preferred embodiment in FIG. 8), a laminated film pattern 201BS is formed as an insular pattern. The laminated film pattern 201BS intersects with a plurality of gate lines 3 in plan view (FIG. 19). The laminated film pattern 201BS also intersects with the common electrodes 5. Note that the first intersecting layer 7B and the second intersecting layer 8B that constitute the laminated film pattern 201BS have approximately the same shape.

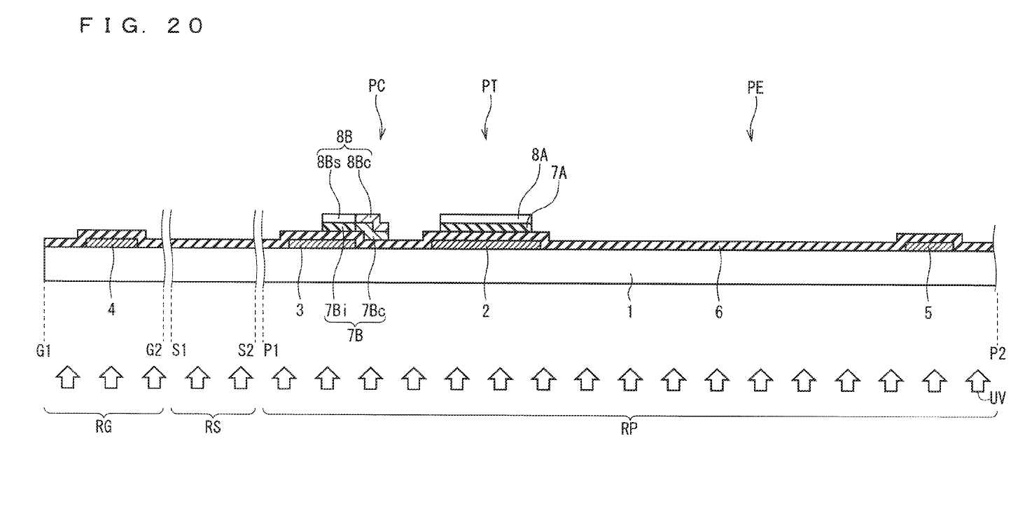

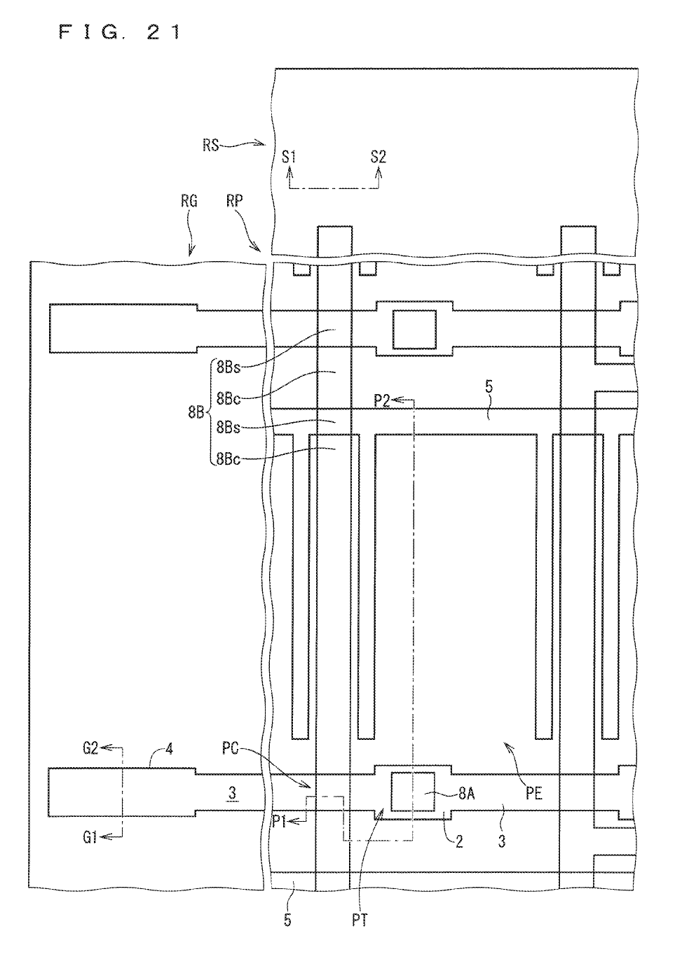

Ultraviolet Light Application Process (FIGS. 20 and 21)

Referring further to FIGS. 20 and 21, next, ultraviolet light UV, which contains ultraviolet rays (light with wavelengths of 10 to 400 nm), is applied to almost the entire surface (back surface of the support substrate 1) opposite to the upper main surface of the support substrate 1. Thus, the ultraviolet light UV is applied via the gate lines 3 and the common electrodes 5 toward to the laminated film pattern 201B S (laminated film 201 in FIG. 18). As a result, conductivity is imparted to the portions of the laminated film 201 that extend off the gate lines 3 and the common electrodes 5 in plan view. That is, of the laminated film pattern 201B S, portions that are irradiated with the ultraviolet light UV and therefore to which conductivity is imparted form conductor portions 7Bc and conductor portions 8Bc. Of the laminated film pattern 201BS, portions that are not irradiated with the ultraviolet light UV undergo no change in specific resistance and remain as insulator portions 7Bi and semiconductor portions 8Bs.

On the other hand, the ultraviolet light UV (FIG. 20) toward the laminated film pattern 201A (FIGS. 18 and 19) is blocked by the gate electrode 2. Thus, the second gate insulating layer 7A and the channel layer 8A included in the laminated film pattern 201A are not affected by the ultraviolet light UV.

Preferably, the ultraviolet light UV has an intensity peak in a wavelength range of less than or equal to 360 nm. Thus, the ultraviolet light UV can efficiently make oxide insulators and oxide semiconductors conductive. As a preferable example, the ultraviolet light UV is generated by a low-pressure mercury lamp. Instead of the ultraviolet light UV, ultraviolet laser may be used. The irradiation conditions (e.g., irradiation power and time) of the ultraviolet light UV may be appropriately determined so as to achieve desired conduction characteristics (low specific resistance value).

In the second preferred embodiment, the first intersecting layer 7B that includes portions to which conductivity is to be imparted is disposed directly on the first gate insulating layer 6. This improves the efficiency of imparting conductivity by the application of the ultraviolet light UV. In particular, when the first gate insulating layer 6 is an SiN film formed by PECVD, the efficiency of imparting conductivity is considered to be improved as a result of a large number of H atoms contained in the SiN film effecting a reducing process during the application of the ultraviolet light UV.

As a preferable example, wet treatment for immersing the support substrate 1 in an alkaline chemical solution is performed after the above-described application of the ultraviolet light UV. This wet treatment can use, for example, an organic alkaline developer (2.38 wt % of TMAH) that is used to develop a photoresist material. This stabilizes and strengthens the conduction characteristics of the portions to which conductivity is imparted by the application of the ultraviolet light UV. Accordingly, it is possible to avoid an increase in specific resistance value caused by heat treatment that is performed after the application of the ultraviolet light UV. This effect is considered to be achieved because the alkaline chemical solution causes a further reducing process to act on the portions to which conductivity has been imparted.

Note that the above-described application of the ultraviolet light UV may be performed on the laminated film 201 prior to patterning.

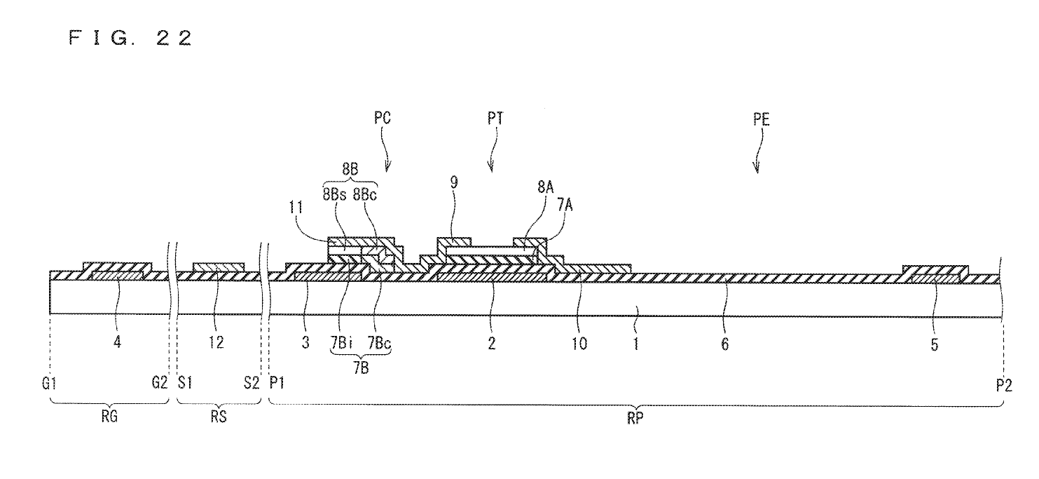

Third Photolithographic Process (FIGS. 22 and 12)

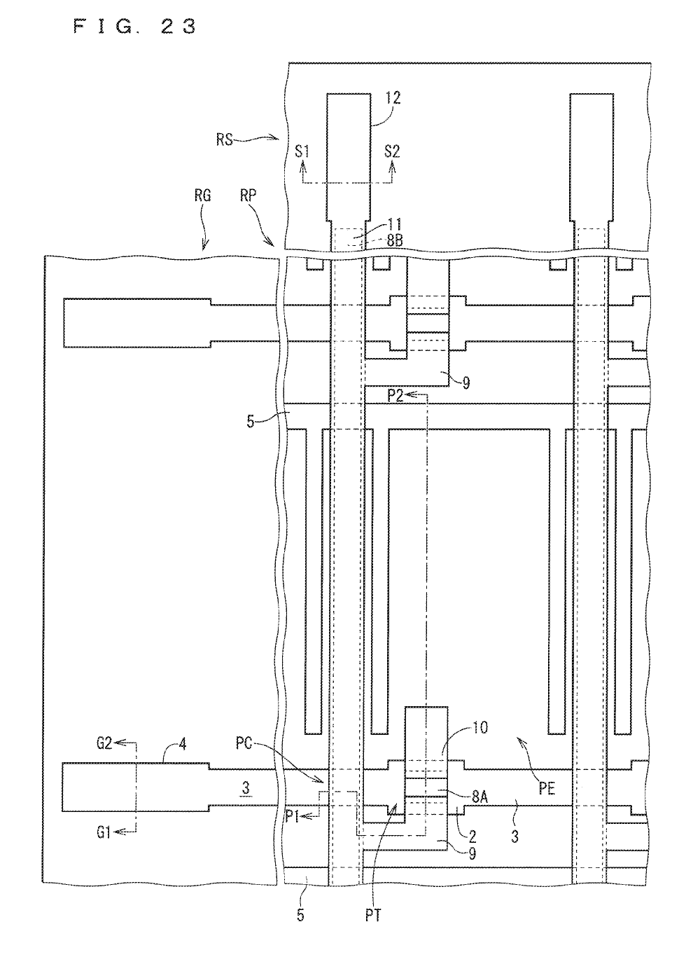

Referring to FIGS. 22 and 23, steps that are almost the same as the steps in FIGS. 9 and 10 of the first preferred embodiment are performed as steps that include the third photolithographic process. That is, the deposition and patterning of the second conductive film are performed. Accordingly, the source electrodes 9, the drain electrodes 10, the source lines 11, and the source terminals 12 are formed.

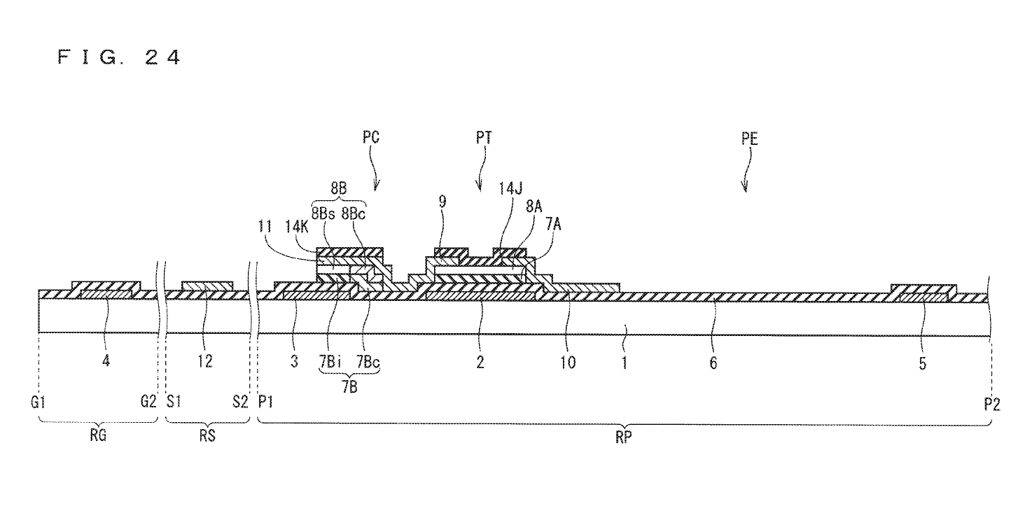

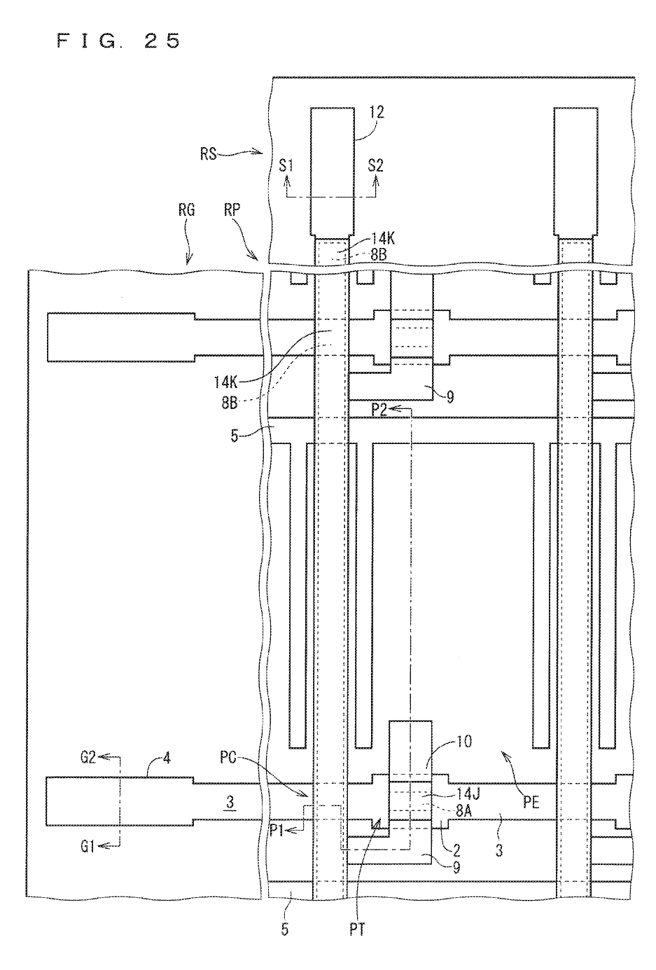

Fourth Photolithographic Process (FIGS. 24 and 25)

Referring to FIGS. 24 and 25, next, steps that are almost the same as the steps in FIGS. 11 to 13 of the first preferred embodiment are performed as steps that include the fourth photolithographic process. Accordingly, the local insulating layer 14J and the insulating layer 14K are formed. In the second preferred embodiment, as in the first preferred embodiment, the photoresist pattern used in the second photolithographic process is also used in the third photolithographic process. Accordingly, in the present preferred embodiment, the pattern of the insulating layer 14K has approximately the same shape as the pattern of the laminated film pattern 201BS (FIG. 19) in plan view (FIG. 25).

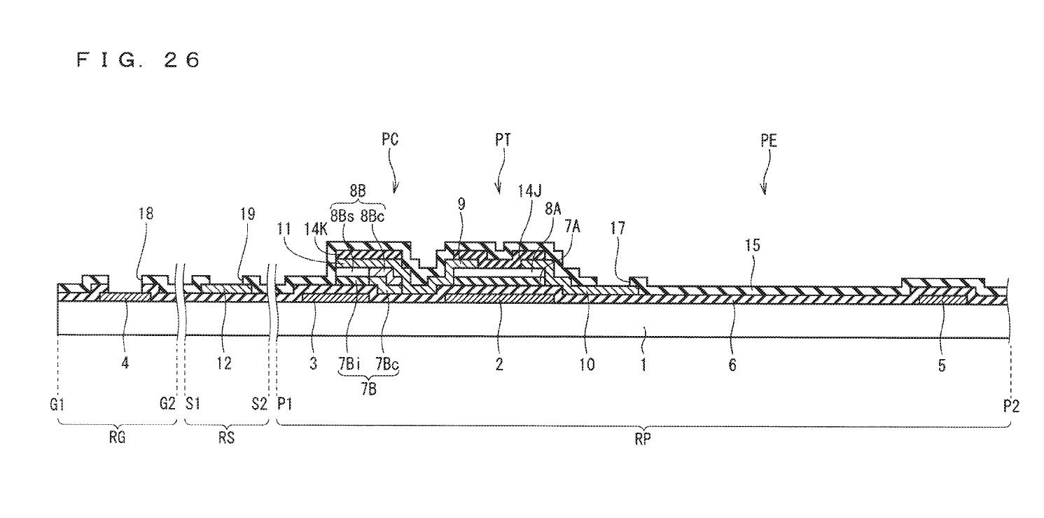

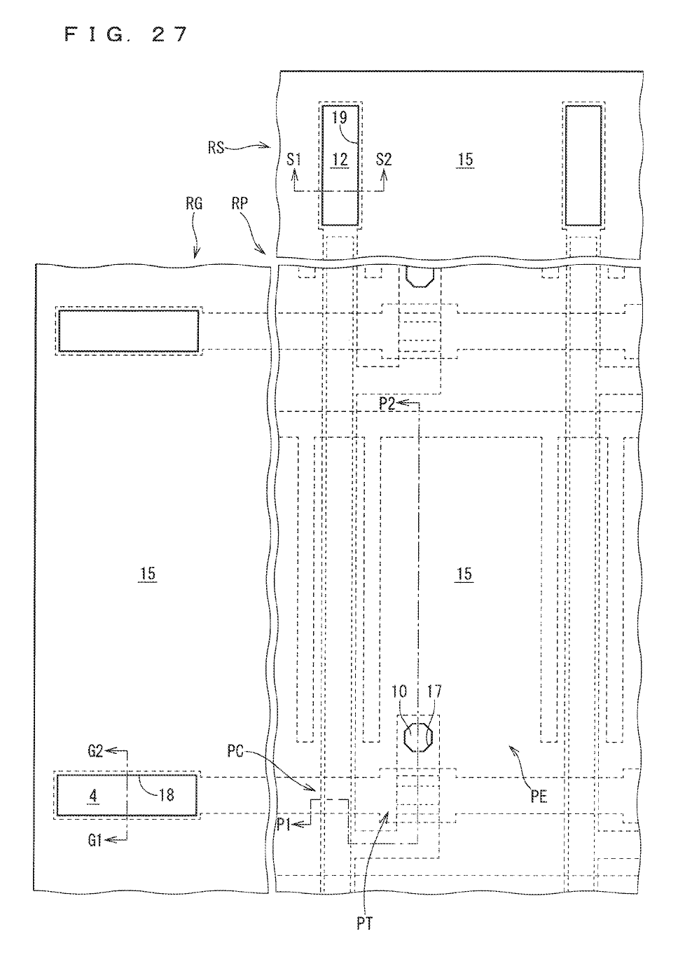

Fifth Photolithographic Process (FIGS. 26 and 27)

Referring to FIGS. 26 and 27, next, steps that are almost the same as the steps in FIGS. 14 and 15 of the first preferred embodiment are performed as steps that include the fifth photolithographic process. Accordingly, the protective insulating layer 15 is formed.

Sixth Photolithographic Process

Referring again to FIGS. 16 and 17, next, the sixth photolithographic process is performed as in the first preferred embodiment. That is, the deposition and patterning of the third conductive film are performed. Accordingly, the pixel electrodes 21, the gate pads 22, and the source pads 23 are formed. As a preferable example, an amorphous ITO film is used as the third conductive film, and the patterned amorphous ITO film is caused to crystallize into a polycrystalline ITO film by heat treatment as described in the first preferred embodiment.

Through the steps described above, the TFT substrate 702 according to the second preferred embodiment is completed. The TFT substrate 702, like the TFT substrate 701 (first preferred embodiment), is applicable to a TN-mode liquid crystal display panel. Also, a liquid crystal display can be manufactured using this liquid crystal display panel.

### Third Preferred Embodiment

Overview

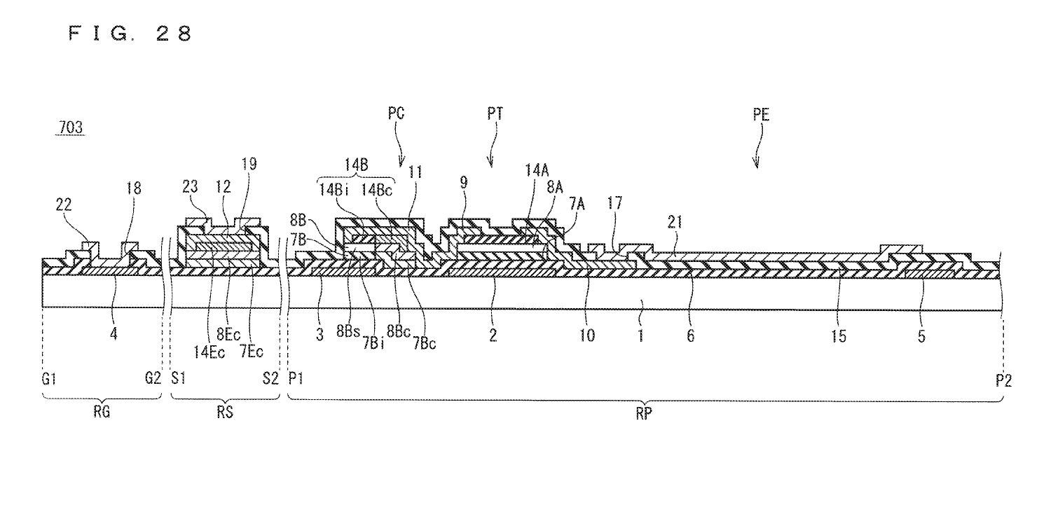

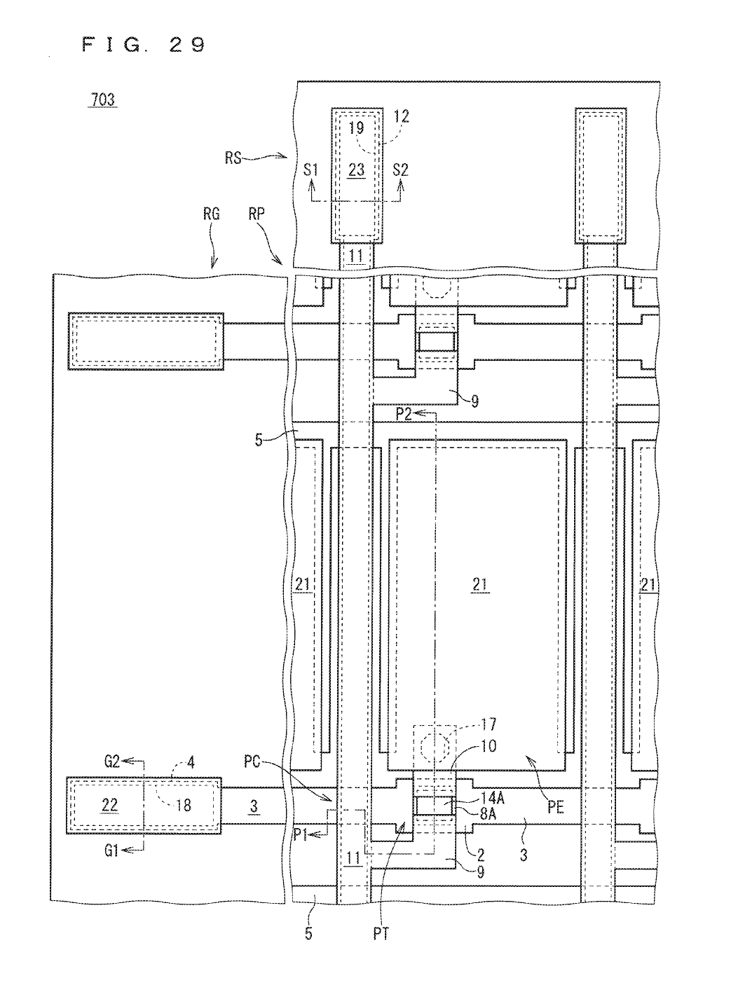

FIGS. 28 and 29 are respectively a partial sectional view and a partial plan view that schematically illustrate a configuration of a thin-film transistor substrate (TFT substrate) 703 according to a third preferred embodiment. The section illustrated in FIG. 28 is taken along line G1-G2 in the gate terminal portion RG, line S1-S2 in the source terminal portion RS, and line P1-P2 in the pixel portion RP in FIG. 29. Note that part of the configuration is not shown in FIG. 29 in order to facilitate viewing of the internal configuration of the TFT substrate 703.

The TFT substrate 703 is applicable to a TN-mode optically transparent LCD. The TFT substrate 703 has a plurality of pixel regions arranged in a matrix and includes a plurality of thin-film transistors that correspond respectively to the plurality of pixel regions. The TFT substrate 703 includes a support substrate 1, gate lines 3, gate terminals 4, a first gate insulating layer 6, a second gate insulating layer 7A, a first intersecting layer 7B, a channel layer 8A, a second intersecting layer 8B, a local insulating layer 14A, a third intersecting layer 14B, source electrodes 9, drain electrodes 10, source lines 11, source terminals 12, and a protective insulating layer 15.

The gate lines 3 are provided on the support substrate 1 and include the gate electrodes 2 that are disposed respectively in the plurality of pixel regions. The gate terminals 4 are provided on the support substrate 1 and connected to the gate lines 3. The first gate insulating layer 6 covers the gate lines 3 and the gate terminals 4 and is made of silicon nitride.

The second gate insulating layer 7A is provided on the gate electrodes 2 via the first gate insulating layer 6 in each of the plurality of pixel regions. The first intersecting layer 7B is provided on the gate lines 3 via the first gate insulating layer 6 and intersects with the gate lines 3.

The channel layer 8A is provided on the second gate insulating layer 7A and has the same shape as the second gate insulating layer 7A. The second intersecting layer 8B is provided on the first intersecting layer 7B and has the same shape as the first intersecting layer 7B.

The local insulating layer 14A is provided on the channel layer 8A and has the same shape as the channel layer 8A. The third intersecting layer 14B is provided on the second intersecting layer 8B and has the same shape as the second intersecting layer 8B.

The source electrodes 9 and the drain electrodes 10 are respectively in contact with one and the other ends (first and second ends) of the channel layer 8A, and are spaced from and oppose each other on the local insulating layer 14A. The source lines 11 are connected to the source electrodes 9 and intersect with the gate lines 3 on the third intersecting layer 14B. The source terminals 12 are connected to the source lines 11.

The protective insulating layer 15 covers the local insulating layer 14A, the gate lines 3, the gate terminals 4, the source lines 11, and the source terminals 12 and is made of silicon nitride. The first gate insulating layer 6 and the protective insulating layer 15 have gate contact holes 18 that reach the gate terminals 4. The protective insulating layer 15 has source contact holes 19 that reach the source terminals 12.

The second gate insulating layer 7A, the channel layer 8A, the local insulating layer 14A, the first intersecting layer 7B, the second intersecting layer 8B, and the third intersecting layer 14B are made of oxide and have a common species of elements and a common crystal structure. Portions of the first intersecting layer 7B, the second intersecting layer 8B, and third intersecting layer 14B that extend off the gate lines 3 in plan view have conductivity.

According to the third preferred embodiment, the local insulating layer 14A having almost the same function as the local insulating layer 14J (FIGS. 16 and 17) can be formed while omitting the fourth photolithographic process of the above-described second preferred embodiment. Thus, it is possible to reduce the number of photolithographic processes by one while achieving almost the same effects as those of the second preferred embodiment. This difference is mainly described in detail hereinafter. The other configuration is similar to the configuration of the aforementioned second preferred embodiment, and therefore identical or corresponding constituent elements are given the same reference numerals, and a detailed description thereof is not repeated.

Details of Structure

According to the present preferred embodiment, the local insulating layer 14A is disposed on the channel layer 8A in the TFT portion PT. The local insulating layer 14A has almost the same shape as the channel layer 8A. Thus, the second gate insulating layer 7A, the channel layer 8A, and the local insulating layer 14A constitute a laminated film pattern. The edge portion of the source electrode 9 and the edge portion of the drain electrode 10 are disposed via the local insulating layer 14A on the channel layer 8A. Specifically, as illustrated in FIG. 28, the source electrode 9 extends to above an insular pattern that serves as the aforementioned laminated film pattern, to above one side face of the insular pattern, and to above the first gate insulating layer 6 in the TFT portion PT. Also, the drain electrode 10 extends to above this insular pattern, to above the other side face of the insular pattern, and to above the first gate insulating layer 6. The outer edge of the local insulating layer 14A is preferably slightly inward of the outer edge of the channel layer 8A in plan view (FIG. 29). This allows not only the side face of the channel layer 8A but also the edge portion of the upper face of the channel layer 8A to come in contact with the source electrode 9 and the drain electrode 10. This stabilizes electrical connection between the channel layer 8A and each of the source electrode 9 and the drain electrode 10. Accordingly, more excellent TFT characteristics can be obtained.

The third intersecting layer 14B is disposed on the second intersecting layer 8B (a semiconductor portion 8Bs and a conductor portion 8Bc in FIG. 28). The third intersecting layer 14B has almost the same shape as the second intersecting layer 8B. Thus, the first intersecting layer 7B, the second intersecting layer 8B, and the third intersecting layer 14B constitute a laminated film pattern. Strictly speaking, the outer edge of the third intersecting layer 14B is slightly inward of the outer edge of the second intersecting layer 8B in plan view (FIG. 29). The third intersecting layer 14B includes an insulator portion 14Bi and a conductor portion 14Bc. The insulator portion 14Bi has insulating properties, and the conductor portion 14Bc has conductivity. Of the third intersecting layer 14B, the insulator portion 14Bi is a portion that overlaps with one of the gate lines 3 and the common electrodes 5 in plan view (FIG. 29). Of the third intersecting layer 14B, the conductor portion 14Bc is a portion that does not overlap with any of the gate lines 3 and the common electrodes 5 in plan view (FIG. 29). The third intersecting layer 14B is disposed between the second intersecting layer 8B (the semiconductor portion 8Bs and the conductor portion 8Bc in FIG. 28) and the source line 11 in the thickness direction (longitudinal direction in FIG. 28). Thus, the source lines 11 intersect with the gate lines 3 via the first intersecting layer 7B, the second intersecting layer 8B, and the third intersecting layer 14B.

Also, a conductor portion 7Ec, a conductor portion 8Ec, and a conductor portion 14Ec may be provided in the source terminal portion RS, and these portions are laminated in order on the first gate insulating layer 6. They have almost the same shape. Thus, the conductor portion 7Ec, the conductor portion 8Ec, and the conductor portion 14Ec constitute a laminated film pattern. Strictly speaking, the outer edge of the conductor portion 14Ec is slightly inward of the outer edge of the conductor portion 8Ec in plan view (FIG. 29). The source terminal 12 is disposed on the first gate insulating layer 6 via these conductor portions. As shown here, the source terminal 12 may be in contact with the edge of the second intersecting layer 8B. The conductor portions 7Ec, 8Ec, and 14Ec are respectively connected to the conductor portions 7Bc, 8Bc, and 14Bc. The conductor portions 7Ec, 8Ec, and 14Ec have conductivity.

Note that the electrical specific resistance value of the layers (or some of the layers) to which conductivity has been imparted is preferably less than 0.1 Ωcm, and more preferably less than 1×10⁻² Ωcm as in the second preferred embodiment.

As a preferable example, the second gate insulating layer 7A, the channel layer 8A, the local insulating layer 14A, the first intersecting layer 7B, the second intersecting layer 8B, and the third intersecting layer 14B are made of InGaZnO having a common crystal structure.

Manufacturing Method

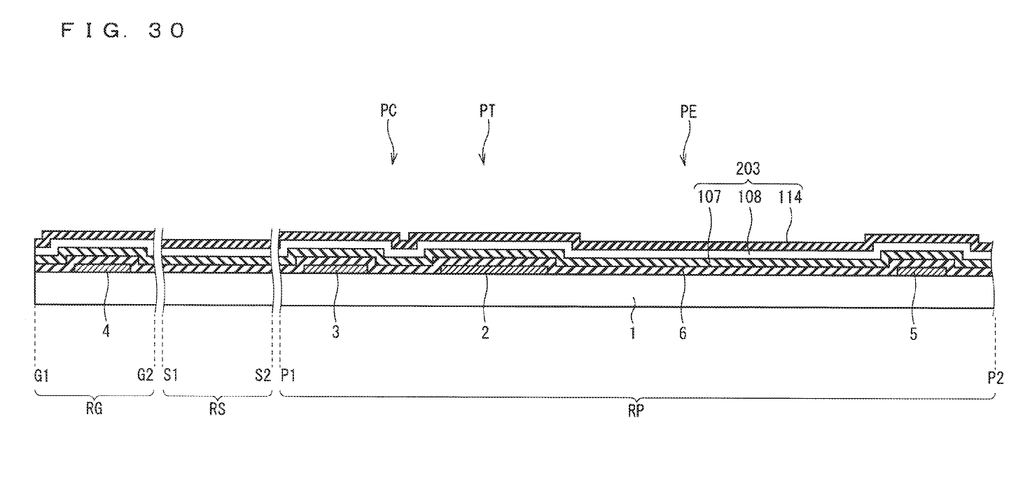

Next, a method of manufacturing the TFT substrate 703 according to the present preferred embodiment is described below with further reference to FIGS. 30 to 42. Among these figures, the fields of view in figures that correspond to partial sectional views are the same as the field of view in FIG. 28, and the fields of view in figures that correspond to partial plan views are the same as the field of view in FIG. 29.

Referring to FIG. 30, first, after the steps up to FIG. 6 of the first preferred embodiment (including the first photolithographic process), the aforementioned third insulation film 114 is deposited on the laminated film 201 that is not patterned. Accordingly, a laminated film 203 configured by the laminated film 201 and the third insulation film 114 is formed.

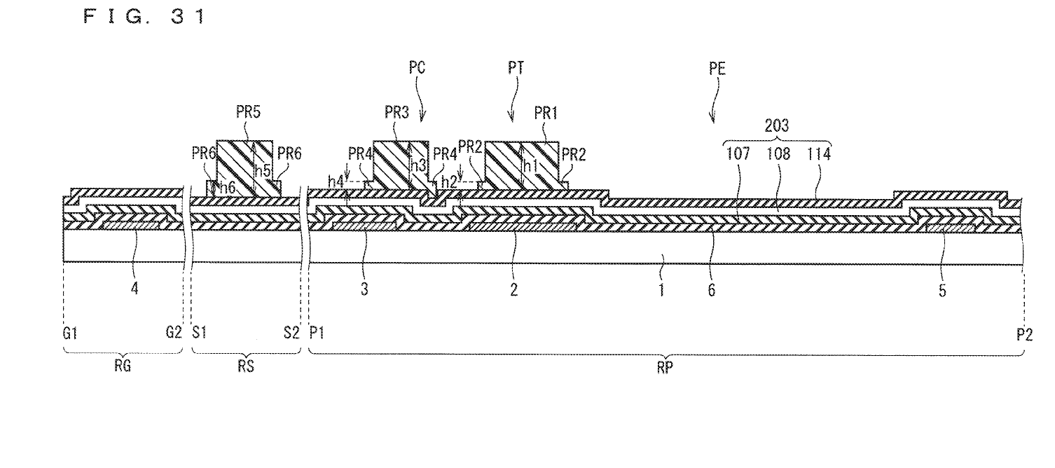

Second Photolithographic Process (FIGS. 31 to 36)

Referring to FIG. 31, a photoresist material is applied to the top of the laminated film 203 in the second photolithographic process. Using the photoresist material, photoresist patterns PR1 to PR6 are formed. The photoresist patterns PR1 and PR2 are integrally formed in the TFT portion PT. The photoresist patterns PR3 and PR4 are integrally formed in the line-intersecting portion PC. The photoresist patterns PR5 and PR6 are integrally formed in the source terminal portion RS. The photoresist patterns PR1 and PR2 are formed in a region where the channel layer 8A (FIG. 28) is to be formed. The photoresist patterns PR3 and PR4 are formed in a region where the source line 11 (FIG. 28) is to be formed. The photoresist patterns PR5 and PR6 are formed in a region where the source terminal 12 is to be formed. Although a set of the photoresist patterns PR3 and PR4 is separated from a set of the photoresist patterns PR5 and PR6 in the section illustrated in FIG. 31, these sets are connected to each other in plan view.

The photoresist patterns PR1 to PR6 have thickness h1 to h6, respectively. The thicknesses h1, h3, and h5 are greater than the thicknesses h2, h4, and h6. As a preferable example, the thicknesses h1, h3, and h5 are set to approximately 2.5 μm, and the thicknesses h2, h4, and h6 are set to approximately 1.0 μm. Note that the thicknesses h1, h3, and h5 may slightly differ from one another, and the thicknesses h2, h4, and h6 may slightly differ from one another. Also, each of the thicknesses h1 to h6 may have slight unevenness. Such differences and unevenness can occur depending on the shape of the surface to which the photoresist material is applied, and dimensions of the differences or unevenness are approximately the thickness of the first conductive film that configures, for example, the gate lines 3.

A method of forming the photoresist patterns PR1 to PR6 is described hereinafter. First, a positive-type photoresist material made of, for example, a novolac resin is applied to the top of the third insulation film 114. The thickness of the photoresist material applied corresponds to the maximum thickness among the thicknesses h1 to h6 (in the above-described example, 2.5 μm). Next, the applied photoresist material is exposed. This exposure is performed with different amounts of exposure on a plurality of regions of the photoresist material. Specifically, regions of the photoresist material that serve as the photoresist patterns PR1, PR3, and PR5 are not irradiated with exposure light, regions thereof that serve as the photoresist patterns PR2, PR4, and PR6 are irradiated with attenuated exposure light, and the other regions thereof are irradiated with direct exposure light. Such a method of controlling the amount of exposure at multiple stages is known as photolithography using a gray-tone or half-tone photomask. Thereafter, the photoresist material is developed. Accordingly, the photoresist material in the regions irradiated with direct exposure light is completely removed, the photoresist mask in the regions that are not irradiated with exposure light (regions shielded from exposure light) fully remains and forms the photoresist patterns PR1, PR3, and PR5, and the photoresist material in the regions irradiated with attenuated exposure light forms the photoresist patterns PR2, PR4, and PR6.

Next, the laminated film 203 is etched using the photoresist patterns PR1 to PR6 as masks. As a preferable example, wet etching using an oxalic acid-based chemical solution that contains 5 wt % of oxalic acid and water is performed.

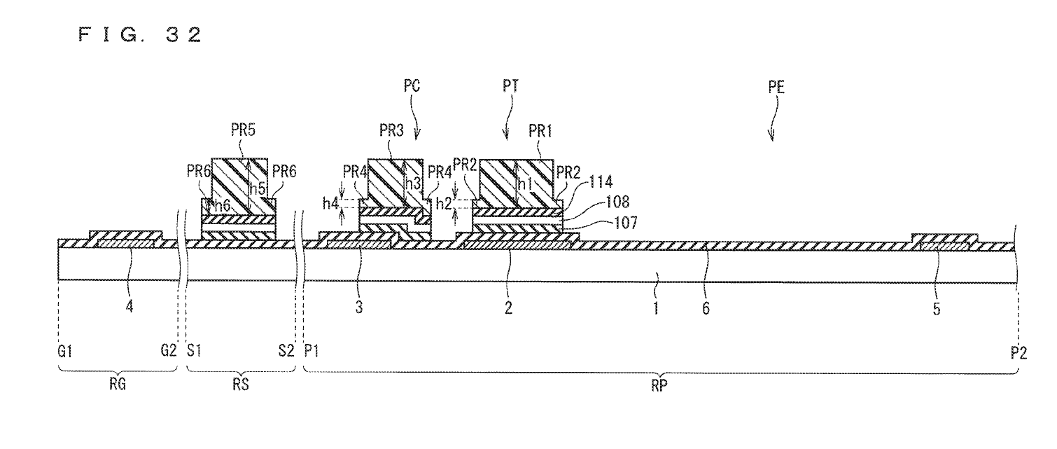

Referring to FIG. 32, the third insulation film 114, the oxide semiconductor film 108, and the second insulation film 107 are etched by the above-described etching. The materials for these films have a common species of elements and a common crystal structure, and as a preferable example, they are all formed from an InGaZnO film. Thus, their susceptibility to etching is almost the same, and accordingly these films are collectively etched and patterned into approximately the same shape.

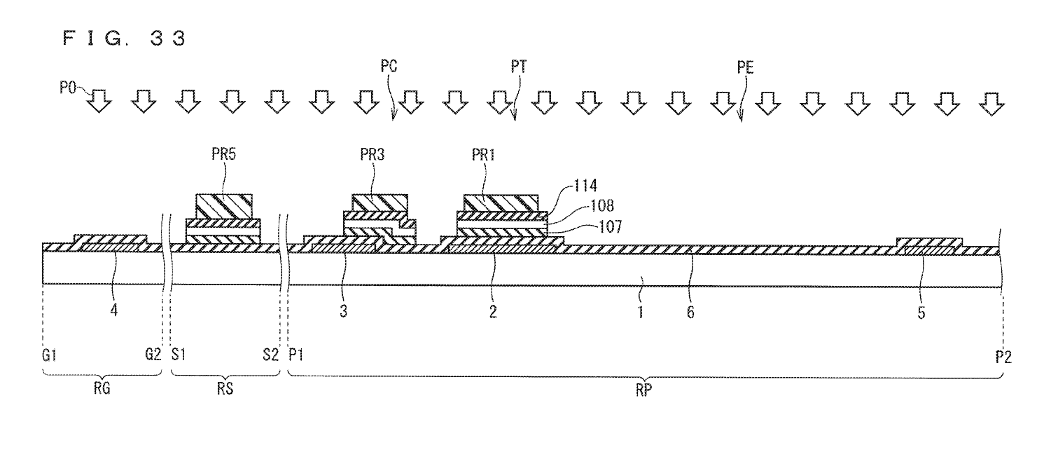

Referring further to FIG. 33, O₂ plasma PO is applied to the entire upper main surface of the support substrate 1 after the above-described patterning. Accordingly, the photoresist patterns PR1 to PR6 as a whole are subjected to ashing. The resultant reduction in the overall film thickness results in a complete removal of the photoresist patterns PR2, PR4, and PR6 (FIG. 32) that have relatively small thicknesses. On the other hand, the photoresist patterns PR1, PR3, and PR5 that have relatively large thicknesses remain, although having reduced thicknesses.

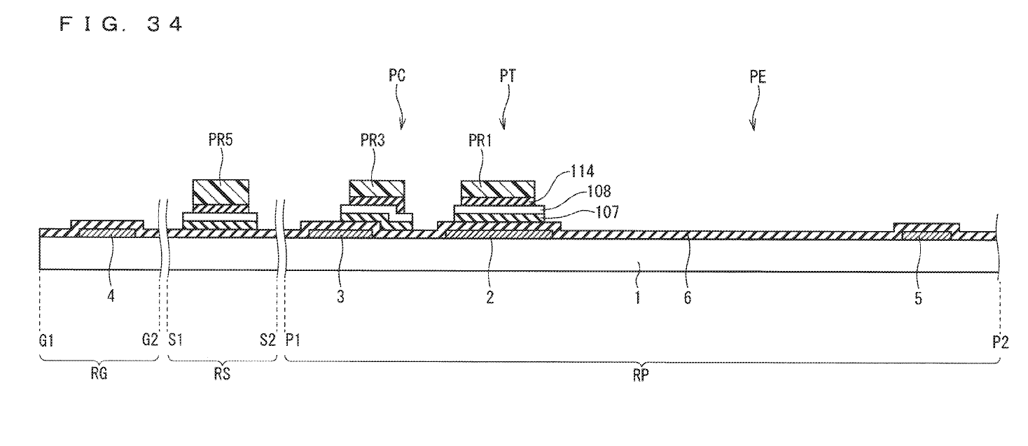

Referring to FIG. 34, only the third insulation film 114 is patterned by etching using, as masks, the photoresist patterns PR1, PR3, and PR5 that have remained after the above-described ashing. As a preferable example, wet etching using an oxalic acid-based chemical solution that contains 5 wt % of oxalic acid and water is performed until the patterning of the third insulation film 114 is completed, by controlling the etching time. At this time, the oxide semiconductor film 108 located thereunder may be slightly overetched.

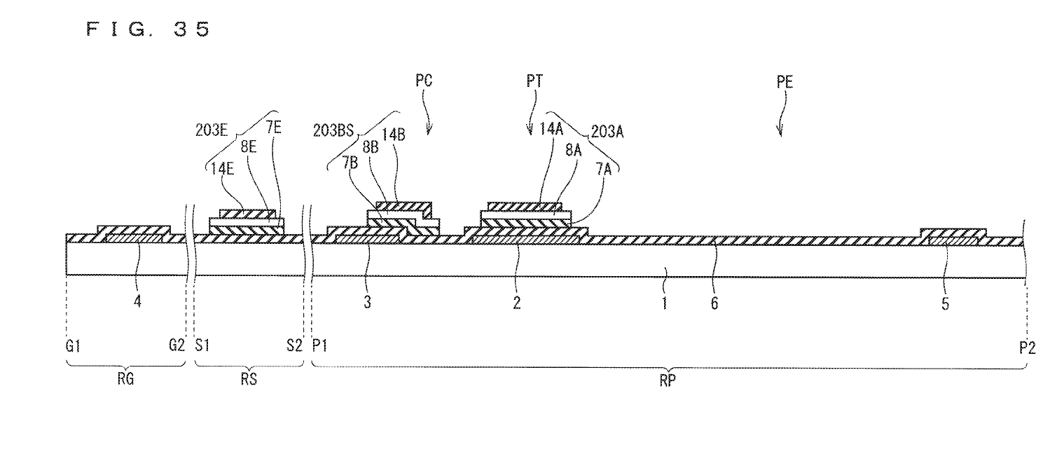

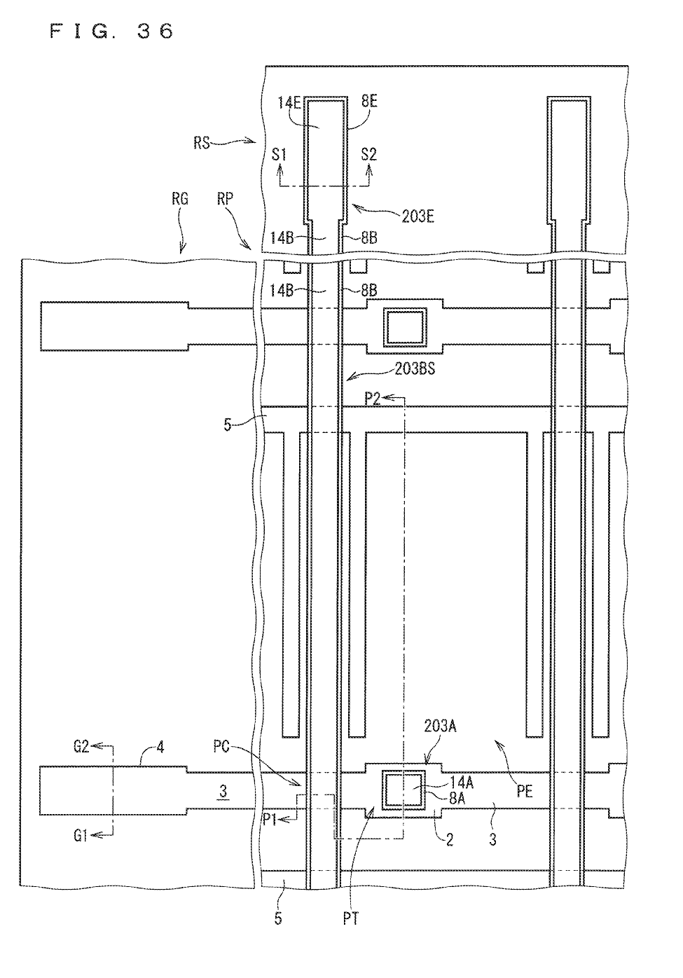

Referring further to FIGS. 35 and 36, the photoresist patterns PR1, PR3, and PR5 (FIG. 34) are removed thereafter. Accordingly, in the TFT portion PT, a laminated film pattern 203A, which includes the second gate insulating layer 7A formed from the second insulation film 107, the channel layer 8A formed from the oxide semiconductor film 108, and the local insulating layer 14A formed from the third insulation film 114, is formed on the gate electrode 2 via the first gate insulating layer 6 formed from the first insulation film. The outer edge of the local insulating layer 14A is inward of the outer edge of the channel layer 8A located thereunder in plan view, and therefore, the outer peripheral portion of the upper surface of the channel layer 8A is exposed. Also, in the line-intersecting portion PC, a laminated film pattern 203BS, which includes the first intersecting layer 7B formed from the second insulation film 107, the second intersecting layer 8B formed from the oxide semiconductor film 108, and the third intersecting layer 14B formed from the third insulation film 114, is formed so as to overlap in part with the gate line 3 via the first gate insulating layer 6 formed from the first insulation film. In the source terminal portion RS, a laminated film pattern 203E, which includes an insulating layer 7E formed from the second insulation film 107, a semiconductor layer 8E formed from the oxide semiconductor film 108, and an insulating layer 14E formed from the third insulation film 114, is formed on the first gate insulating layer 6. In plan view (FIG. 36), the laminated body of the first intersecting layer 7B, the second intersecting layer 8B, and the third intersecting layer 14B intersects with the gate lines 3 and the common electrodes 5 and is disposed so as to reach the source terminal portion RS.

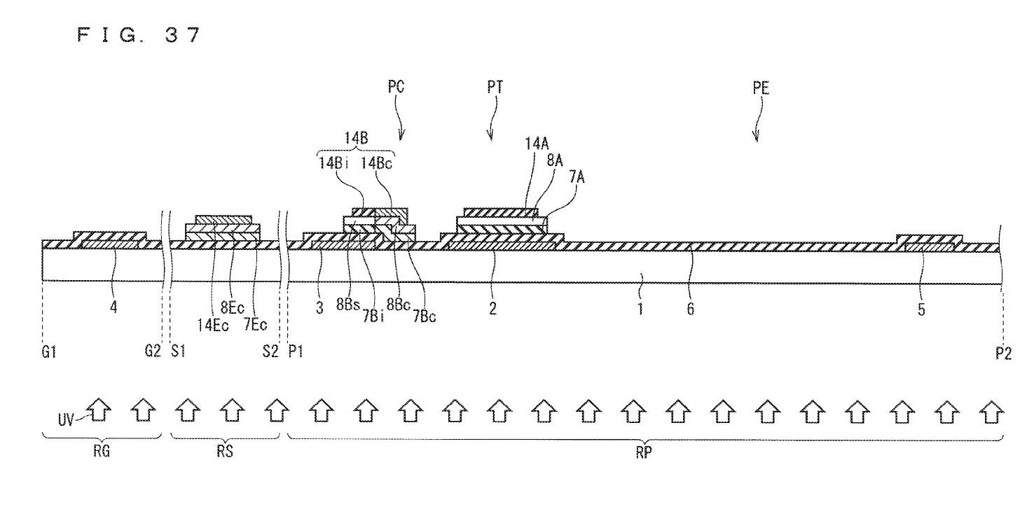

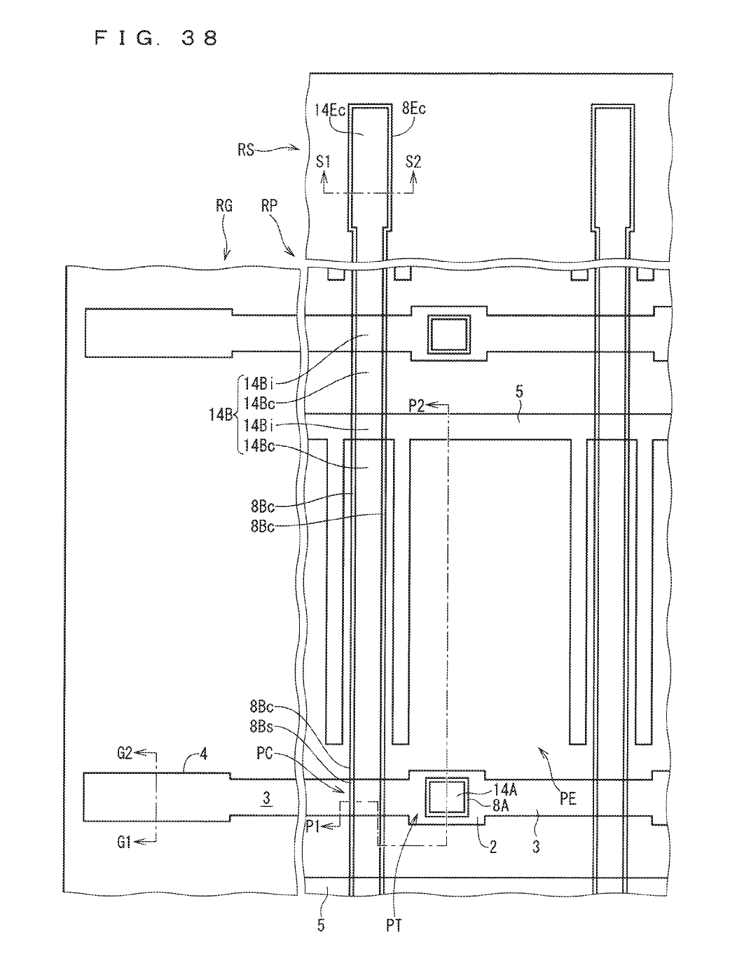

Ultraviolet Light Application Process (FIGS. 37 and 38)

Referring to FIGS. 37 and 38, next, ultraviolet light UV, which contains ultraviolet rays, is applied to almost the entire surface (back surface of the support substrate 1) opposite to the upper main surface of the support substrate 1. Accordingly, conductivity is imparted to portions of the laminated film patterns 203A, 203BS, and 203E formed from the laminated film 203 (FIG. 30); the portions extend off the gate lines 3 and the common electrodes 5 in plan view (FIG. 38). The step of applying the ultraviolet light UV is similar to that (FIG. 20) of the second preferred embodiment, but the steps according to the third preferred embodiment differs in that the ultraviolet light UV is also applied to the third intersecting layer 14B and the laminated film pattern in the source terminal portion RS. Of the third intersecting layer 14B, a portion that is irradiated with the ultraviolet light UV and thereby has conductivity serves as a conductor portion 14Bc, and a portion that is not irradiated with the ultraviolet light UV remains as an insulator portion 14Bi. Also, the insulating layer 7E, the semiconductor layer 8E, and the insulating layer 14E that constitute the laminated film pattern in the source terminal portion RS are respectively transformed into the conductor portion 7Ec, the conductor portion 8Ec, and the conductor portion 14Ec. The local insulating layer 14A remains as an insulating layer because the ultraviolet light UV is blocked by the gate electrode 2. Note that after the application of the ultraviolet light UV, treatment for further enhancing insulation electrical performance may be performed as in the second preferred embodiment.

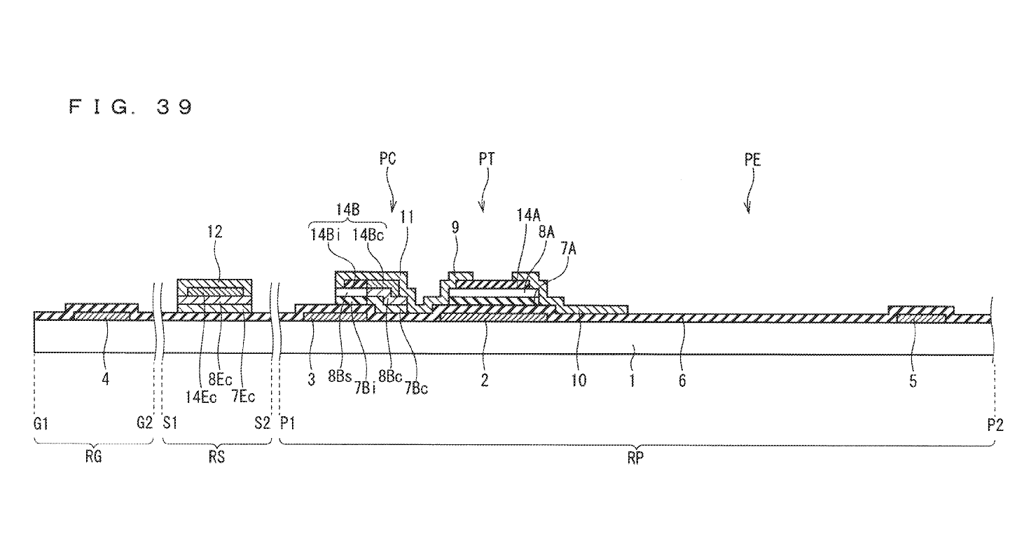

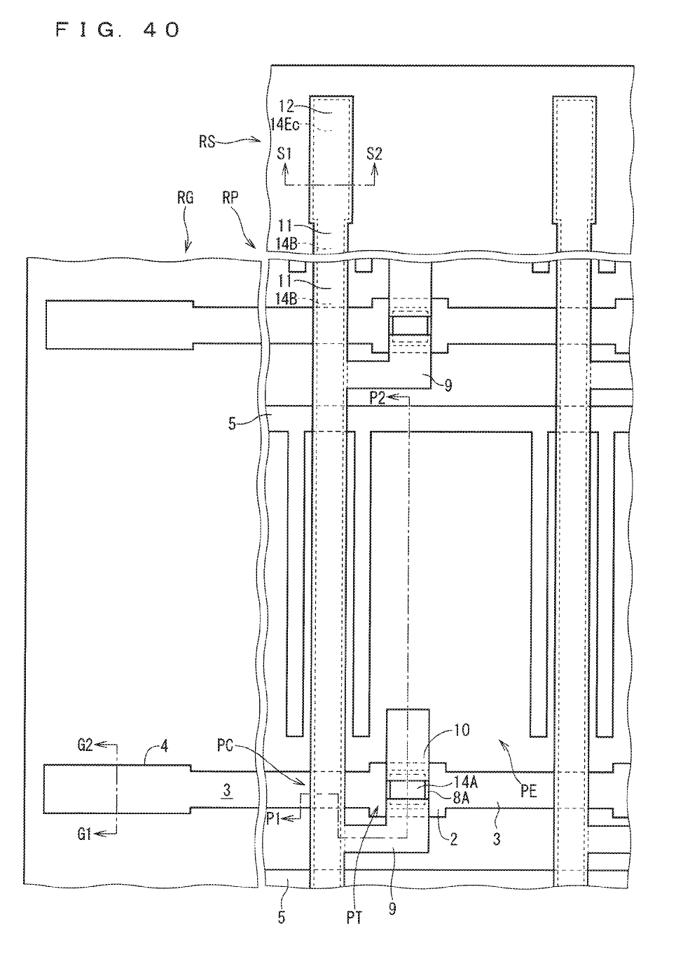

Third Photolithographic Process (FIGS. 39 and 40)

Referring to FIGS. 39 and 40, next, the second conductive film that is to be patterned into, for example, the source electrodes 9, the drain electrodes 10, and the source lines 11 is deposited. The method of depositing the second conductive film is similar to that of the first or second preferred embodiment.

Thereafter, the third photolithographic process is performed. Specifically, a photoresist pattern is formed on the second conductive film. The second conductive film is patterned by etching using the photoresist pattern as a mask. The etching method for the second conductive film is similar to that of the first or second preferred embodiment. Thereafter, the photoresist pattern is removed.

Though the above-described patterning, the source electrodes 9, the drain electrodes 10, the source lines 11, and the source terminals 12 are formed as illustrated in FIGS. 39 and 40. The arrangement of the source electrodes 9 and the drain electrodes 10 are as described above. The source lines 11 are disposed on the third intersecting layer 14B. The source terminals 12 are disposed on the conductor portion 14Ec.

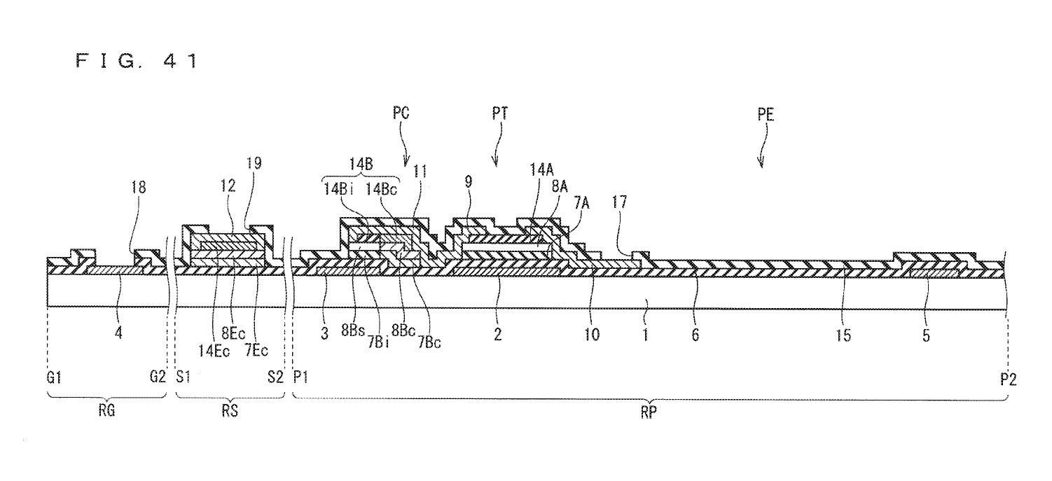

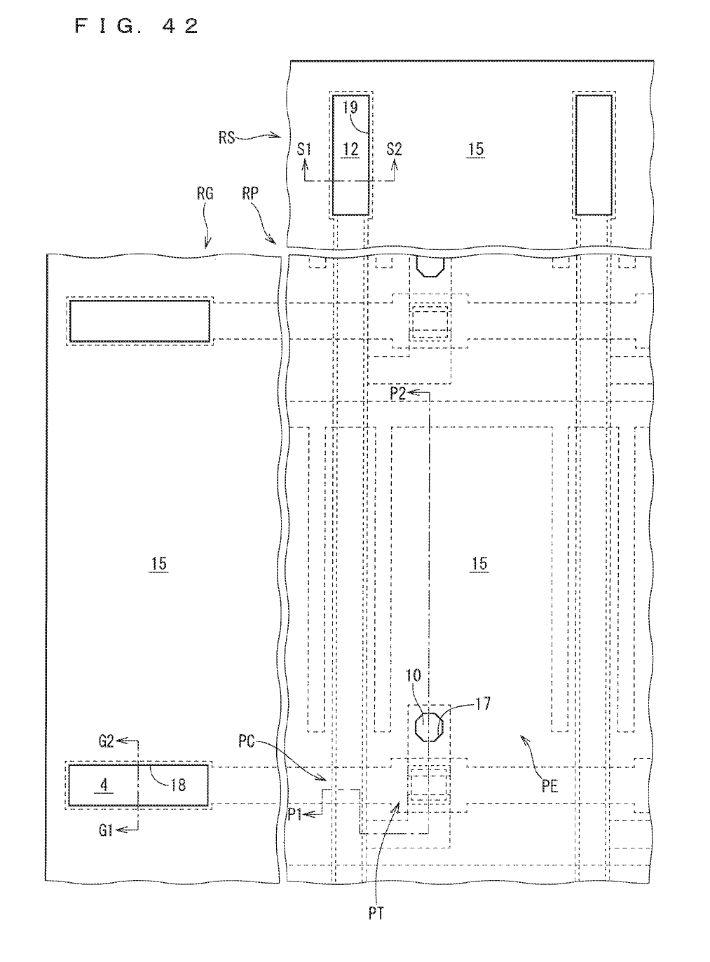

Fourth Photolithographic Process (FIGS. 41 and 42)

Referring to FIGS. 41 and 42, next, the fourth insulation film is deposited by almost the same method as that of the second preferred embodiment. Then, the fourth insulation film and the first insulation film, i.e., the protective insulating layer 15 and the first gate insulating layer 6, are patterned as the fourth photolithographic process. Accordingly, the pixel drain contact holes 17 that penetrate the protective insulating layer 15, the source contact holes 19 that penetrate the protective insulating layer 15, and the gate contact holes 18 that penetrate the protective insulating layer 15 and the first gate insulating layer 6 are formed simultaneously.

Fifth Photolithographic Process

Referring again to FIGS. 28 and 29, next, the sixth photolithographic process is performed in approximately the same manner as the sixth photolithographic process of the second preferred embodiment. That is, the deposition and patterning of the third conductive film are performed. Accordingly, the pixel electrodes 21, the gate pads 22, and the source pads 23 are formed. As a preferable example, as described in the first preferred embodiment, an amorphous ITO film is used as the third conductive film, and the patterned amorphous ITO film is caused to crystallize into a polycrystalline ITO film by heat treatment.

Through the steps described above, the TFT substrate 703 according to the third preferred embodiment is completed. The TFT substrate 703, like the TFT substrate 701 (first preferred embodiment), is applicable to a TN-mode liquid crystal display panel. Also, a liquid crystal display can be manufactured using this liquid crystal display panel.

Summary of Manufacturing Method

The gate lines 3 including the gate electrodes 2 that are disposed respectively in the plurality of pixel regions, and the gate terminals 4 connected to the gate lines 3 are formed on the support substrate 1. The first gate insulating layer 6 that covers the gate lines 3 and the gate terminals 4 is made of silicon nitride.

The laminated film 203 is formed on the first gate insulating layer 6. The step of forming the laminated film 203 includes the step of depositing the second insulation film 107 (first oxide insulating layer) on the first gate insulating layer 6 by sputtering, the step of depositing the oxide semiconductor film 108 (oxide semiconductor layer) on the second insulation film 107 by sputtering, and the step of depositing the second oxide insulating layer on the oxide semiconductor film 108 by sputtering. The sputtering material used in the step of depositing the second insulation film 107, the sputtering material used in the step of depositing the oxide semiconductor film 108, and the sputtering material used in the step of depositing the second oxide insulating layer are made of oxide and have a common species of elements and a common crystal structure.

Through the patterning of the laminated film 203, the second gate insulating layer 7A provided in each of the plurality of pixel regions on the gate electrode 2 via the first gate insulating layer 6 and the first intersecting layer 7B provided on the gate line 3 via the first gate insulating layer 6 and intersecting with the gate line 3 are formed from the second insulation film 107; the channel layer 8A provided on the second gate insulating layer 7A and having the same shape as the second gate insulating layer 7A, and the second intersecting layer 8B provided on the first intersecting layer 7B and having the same shape as the first intersecting layer 7B are formed from the oxide semiconductor film 108; and the local insulating layer 14A provided on the channel layer 8A and having the same shape as the channel layer 8A, and the third intersecting layer 14B provided on the second intersecting layer 8B and having the same shape as the second intersecting layer 8B are formed from the second oxide insulating layer.

Ultraviolet light is applied via the gate line 3 toward the laminated film 203 so as to impart conductivity to the portions of the laminated film 203; the portions extend off the gate line 3 in plan view.

The source electrodes 9 and the drain electrodes 10 that are respectively in contact with one and the other ends (first and second ends) of the channel layer 8A and that are spaced from and oppose each other on the local insulating layer 14A, the source lines 11 that are connected to the source electrodes 9 and intersect with the gate lines 3 on the third intersecting layer 14B, and the source terminals 12 connected to the source lines 11 are formed. The protective insulating layer 15 that covers the local insulating layer 14A, the gate lines 3, the gate terminals 4, the source lines 11, and the source terminals 12 is made of silicon nitride. The gate contact holes 18 that reach the gate terminals 4 are formed in the first gate insulating layer 6 and the protective insulating layer 15. The source contact holes 19 that reach the source terminals 12 are formed in the protective insulating layer 15.

Summary of Advantageous Effects

The third preferred embodiment can also achieve almost the same effects as those of the second preferred embodiment. According to the present preferred embodiment, not only the first intersecting layer 7B and the second intersecting layer 8B but also the third intersecting layer 14B reduce the influence of step heights caused by the gate lines 3. Also, not only the conductor portion 7Bc of the first intersecting layer 7B and the conductor portion 8Bc of the second intersecting layer 8B but also the conductor portion 14Bc of the third intersecting layer 14B serve as redundant lines of the source lines 11.

Moreover, according to the present preferred embodiment, the local insulating layer 14A having the same shape as the channel layer 8A is provided on the channel layer 8A. Thus, the step of patterning the channel layer 8A can be performed as the step of patterning a laminated body that includes the channel layer 8A and the local insulating layer 14A. Accordingly, the channel layer 8A is protected from adverse effects that may occur during patterning by the local insulating layer 14A.

Also, the region where the source electrodes 9 and the drain electrodes 10 oppose each other is provided not directly on the channel layer 8A, but on the local insulation film. This avoids a situation where the channel layer 8A directly suffers process damage when the source electrodes 9 and the drain electrodes 10 are formed by patterning of the conductive film.

From the foregoing, the characteristics and reliability of the TFT substrate 703 can be further improved.

In addition, according to the third preferred embodiment, the number of photolithographic processes included in the manufacturing method is five, which is smaller by one than the number in the second preferred embodiment. This improves productivity.

### Fourth Preferred Embodiment

Structure

The TFT substrates 701 to 703 for TN-mode LCDs are described in the above first to third preferred embodiments. A fourth preferred embodiment describes a TFT substrate for FFS-mode LCDs.

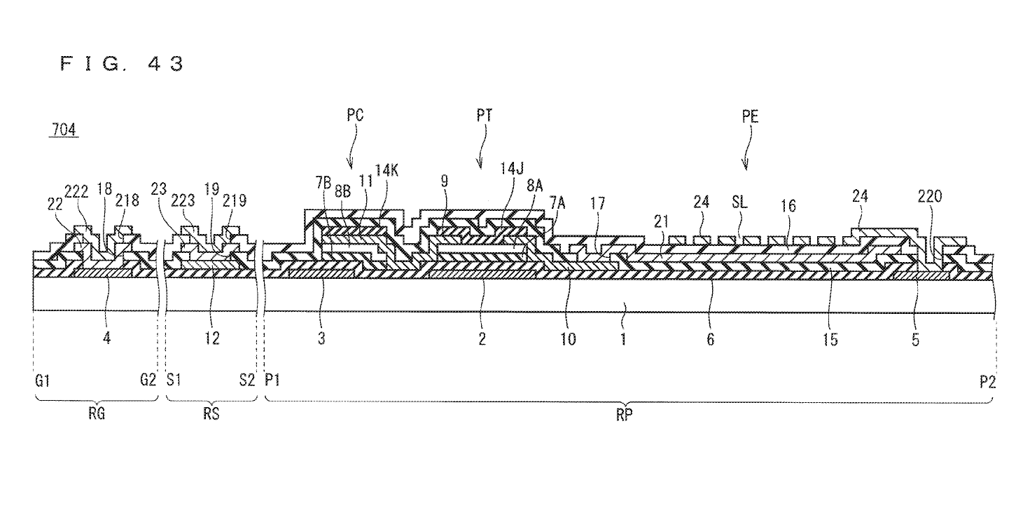

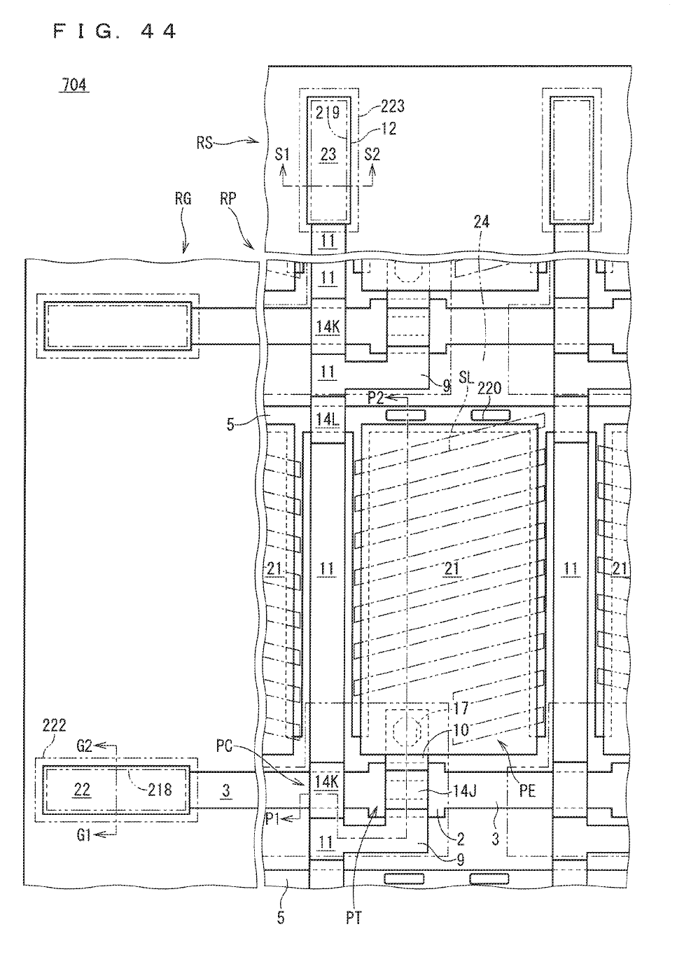

FIGS. 43 and 44 are respectively a partial sectional view and a partial plan view that schematically illustrate a configuration of a thin-film transistor substrate (TFT substrate) 704 according to the fourth preferred embodiment. The section illustrated in FIG. 43 is taken along line G1-G2 in the gate terminal portion RG, line S1-S2 in the source terminal portion RS, and line P1-P2 in the pixel portion RP in FIG. 44. Note that part of the configuration is not shown in FIG. 44 in order to facilitate viewing of the internal configuration of the TFT substrate 704.

First, an overall structure is described. The TFT substrate 704 further includes an interlayer insulation layer 16, a counter electrode 24, and additional pads 222 and 223 in addition to the configuration of the TFT substrate 701 (FIGS. 1 and 2). The interlayer insulation layer 16 covers the channel layer 8A, the gate lines 3, the gate terminals 4, the source lines 11, the source terminals 12, and the pixel electrodes 21. Thus, in the fourth preferred embodiment, the local insulating layer 14J is provided between the channel layer 8A and the interlayer insulation layer 16. The interlayer insulation layer 16 is made of silicon nitride. The counter electrode 24 is provided on the interlayer insulation layer 16 and opposes the pixel electrodes 21 via the interlayer insulation layer 16. In the fourth preferred embodiment, the first gate insulating layer 6, the protective insulating layer 15, and the interlayer insulation layer 16 have common electrode contact holes 220 that reach the common electrodes 5. The counter electrode 24 is connected to the common electrodes 5 via the common electrode contact holes 220. The interlayer insulation layer 16 has openings 218 on the gate pads 22 and openings 219 on the source pads 23. The openings 218 and 219 respectively expose part of the gate pads 22 and the source pads 23. The additional pads 222 are connected to the gate pads 22 via the openings 218. The additional pads 223 are connected to the source pads 23 via the openings 219. The additional pads 222 and 223 have conductivity.

Next, the counter electrode 24 is described in detail below.

As described above, the counter electrode 24 is electrically connected to the common electrodes 5 located thereunder via the common electrode contact holes 220. Thus, a fixed potential (common potential) is supplied from the common electrodes 5 to the counter electrode 24.

The counter electrode 24 is provided so as to overlap most parts of the pixel electrodes 21 in plan view (FIG. 44). According to the fourth preferred embodiment, the counter electrode 24 includes a plurality of portions surrounded by the gate lines 3 and the source lines 11 in correspondence with the plurality of pixel regions, and these plurality of portions are connected to one another. Thus, the counter electrode 24 has one continuous pattern in the TFT substrate 704. Accordingly, for example, even if a failure in electrical connection established by the common electrode contact holes 220 occurs in one pixel region, a common potential is supplied from the common electrode contact holes 220 in adjacent pixel regions to a portion of the counter electrode 24; the portion is included in that pixel region. This prevents a display failure (point defect) in pixel units from occurring due to a failure in electrical connection established by the common electrode contact holes 220.

The counter electrode 24 is provided with a plurality of slit openings SL. With this structure, when a signal voltage is applied between the pixel electrodes 21 and the counter electrode 24, an electric field that is approximately horizontal with respect to the substrate surface is generated above the counter electrode 24. For this reason, the TFT substrate 704 is applicable to transverse electric field-driven FPS-mode LCDs. Note that comb-tooth-shaped openings may be provided, instead of the slit openings SL.

Manufacturing Method

First to Sixth Photolithographic Processes

In a method of manufacturing the TFT substrate 704 according to the fourth preferred embodiment, first, the TFT substrate 701 (FIGS. 1 and 2) described in the first preferred embodiment is prepared as a in-process product. This preparation requires six photolithographic processes as described in the first preferred embodiment.

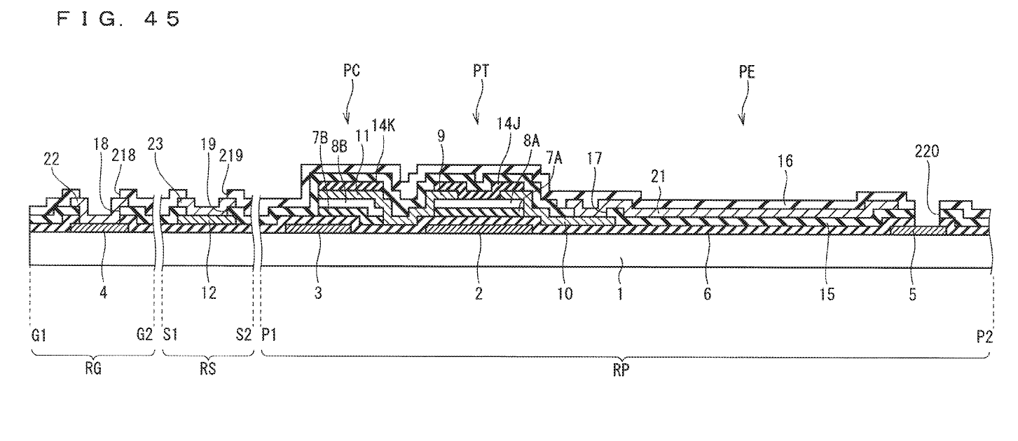

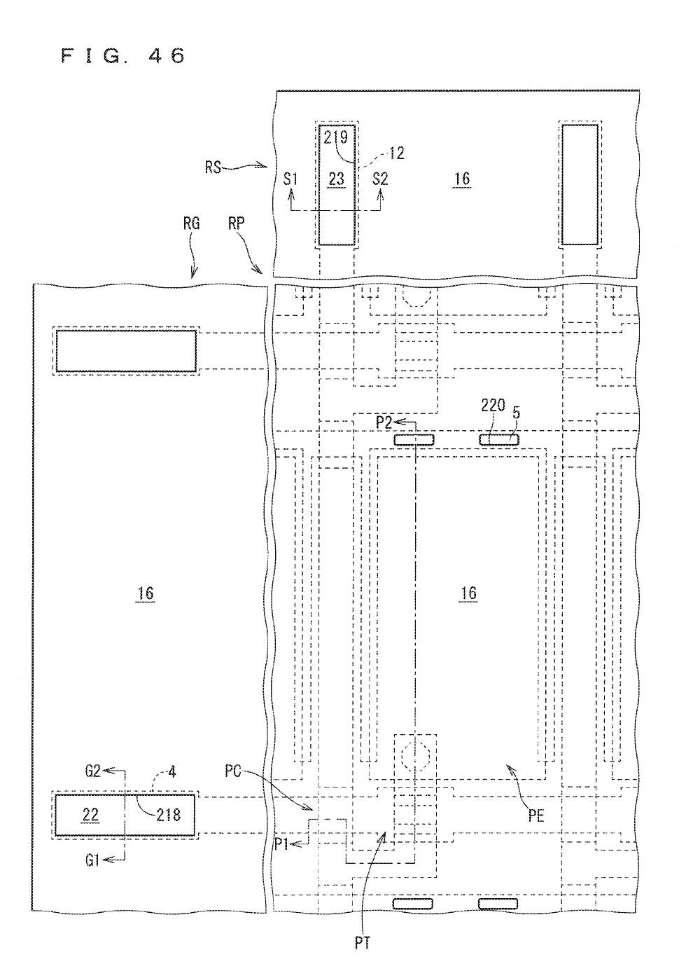

The TFT substrate 704 is manufactured from the above in-process product. This is further specifically described hereinafter with reference to FIGS. 45 and 46. The field of view in FIG. 45 is the same as the field of view in FIG. 43, and the field of view in FIG. 46 is the same as the field of view in FIG. 44.

Seventh Photolithographic Process (FIGS. 45 and 46)

Referring to FIGS. 45 and 46, a fifth insulation film that serves as the interlayer insulation layer 16 is deposited on the upper main surface of the support substrate 1 of the TFT substrate 701 (FIGS. 1 and 2), which is a in-process product. As a preferable example, an SiN film with a thickness of 150 nm is deposited by PECVD in the same manner as the first and third insulation films described in the first preferred embodiment.

Then, the seventh photolithographic process is performed. Specifically, the formation of a photoresist pattern and etching using the photoresist pattern as a mask are performed. By this etching, patterning is performed so as to form the common electrode contact holes 220 in the first gate insulating layer 6, the protective insulating layer 15, and the interlayer insulation layer 16 and to form the openings 218 and 219 in the interlayer insulation layer 16. As a preferable example, dry etching is performed using a gas made by adding O₂ to SF₆. Thereafter, the photoresist pattern is removed.

In plan view (FIG. 46), the common electrode contact holes 220 are formed in regions that overlap with the common electrodes 5 and that do not overlap with the pixel electrodes 21. The number of common electrode contact holes 220 is arbitrarily determined, and in the example illustrated in FIG. 46, two common electrode contact holes 220 are formed in each pixel region. By providing a plurality of common electrode contact holes 220, even if one of the holes has a failure due to a pattern failure or other reasons, the other holes can compensate for the failed one.

The openings 218 and 219 may be formed so as to respectively have approximately the same shapes as the gate contact holes 18 and the source contact holes 19 formed thereunder.

Eighth Photolithographic Process

Referring again to FIGS. 43 and 44, next, the fourth conductive film that is to be patterned into the counter electrode 24 and the additional pads 222 and 223 is deposited. According to the fourth preferred embodiment, a transparent conductive film (translucent conductive film) is used as the fourth conductive film. As a preferable example, an ITO film with a thickness of 100 nm is deposited in an amorphous state in the same manner as the third conductive film described in the first preferred embodiment.

Then, the eighth photolithographic process is performed. Specifically, a photoresist pattern is formed, and the fourth conductive film is patterned by etching using the photoresist mask as a mask. As a preferable example, wet etching using an oxalic acid-based chemical solution that contains 5 wt % of oxalic acid and water is performed. In the case of using an amorphous ITO film as described above, heat treatment for causing the amorphous ITO film to crystallize into a polycrystalline ITO film is performed as described in the first preferred embodiment. Accordingly, the counter electrode 24 and the additional pads 222 and 223 are formed.

Thought the steps described above, the TFT substrate 704 according to the fourth preferred embodiment is completed. In the case of assembling a liquid crystal display panel, an alignment film is formed on the surface of the completed TFT substrate 704. This produces a liquid crystal display panel using the FFS mode as a transverse electric field mode. Also, a counter substrate, which is separately prepared and includes, for example, a color filter and an alignment film, is bonded to the TFT substrate 704. At this time, a spacer formed on the surface of either the TFT substrate 704 or the counter substrate forms a space between the TFT substrate 704 and the counter substrate. In this space, a liquid crystal layer is sealed. Finally, other constituent elements such as a polarizing plate, a phase difference plate, a driving circuit, and a backlight unit are disposed on the outer side of the liquid crystal display panel, and the liquid crystal display is thereby completed.

Advantageous Effects

According to the fourth preferred embodiment, similar effects to those of the first preferred embodiment can be achieved in case of using the FFS mode. In particular, according to the fourth preferred embodiment, all the layers penetrated by not only the gate contact holes 18 and the source contact holes 19 but also the common electrode contact holes 220 are formed not of oxide, but of silicon nitride. Thus, the common electrode contact holes 220 can also be formed with ease. Accordingly, the TFT substrate 704 can be manufactured with high yield and high productivity.

Although the fourth preferred embodiment describes in detail a case in which the TFT substrate for FFS-mode LCDs is configured using the TFT substrate 701 (first preferred embodiment) as a base, the TFT substrate for FFS-mode LCDs may be configured using the TFT substrate 702 or 703 (second or third preferred embodiment) as a base. In this case, the effects of the second or third preferred embodiment can be achieved in the case of using the FFS mode.

### Fifth Preferred Embodiment

Overview

According to a fifth preferred embodiment, a TFT substrate for FFS-mode LCDs can be manufactured with higher productivity by omitting the protective insulating layer 15 (fourth preferred embodiment in FIG. 43).

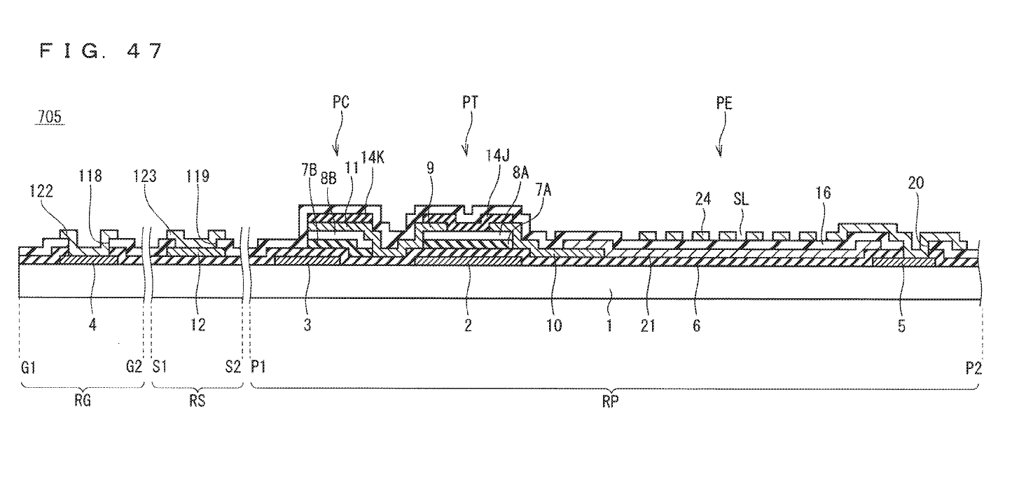

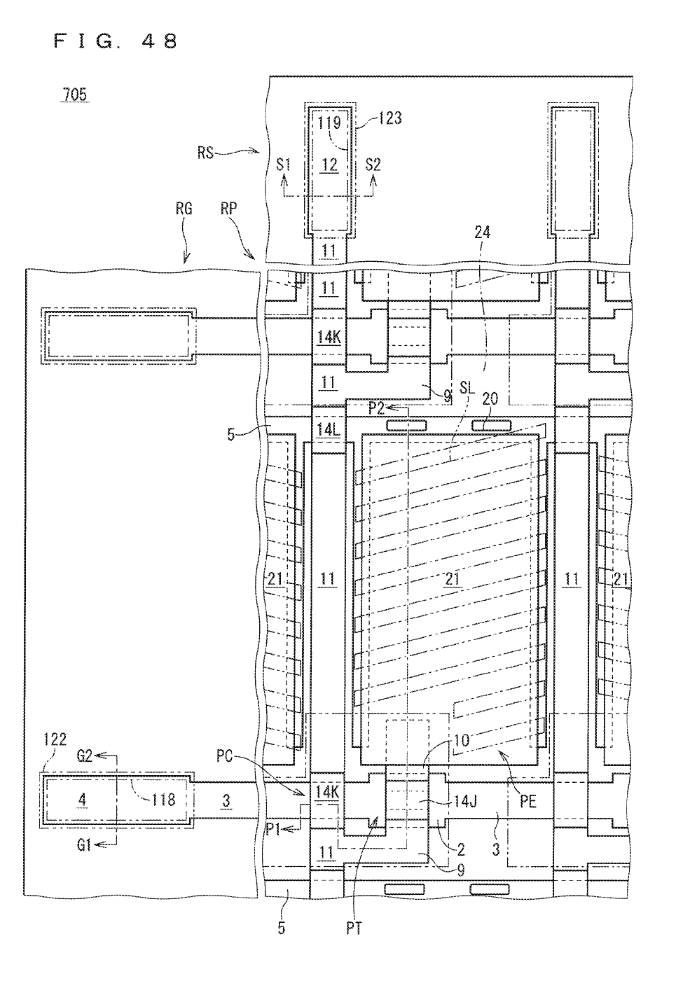

FIGS. 47 and 48 are respectively a partial sectional view and a partial plan view that schematically illustrate a configuration of a thin-film transistor substrate (TFT substrate) 705 according to the fifth preferred embodiment. The section illustrated in FIG. 47 is taken along line G1-G2 in the gate terminal portion RG, line S1-S2 in the source terminal portion RS, and line P1-P2 in the pixel portion RP in FIG. 48. Note that part of the configuration is not shown in FIG. 48 in order to facilitate viewing of the internal configuration of the TFT substrate 705.

The TFT substrate 705 has a plurality of pixel regions arranged in a matrix and includes a plurality of thin-film transistors that correspond respectively to the plurality of pixel regions. The TFT substrate 705 includes a support substrate 1, gate lines 3, gate terminals 4, common electrodes 5, a first gate insulating layer 6, a second gate insulating layer 7A, a first intersecting layer 7B, a channel layer 8A, a second intersecting layer 8B, source electrodes 9, drain electrodes 10, source lines 11, source terminals 12, pixel electrodes 21, an interlayer insulation layer 16, a counter electrode 24, and a local insulating layer 14J.

The gate lines 3 are provided on the support substrate 1 and include gate electrodes 2 disposed respectively in the plurality of pixel regions. The gate terminals 4 are provided on the support substrate 1 and connected to the gate lines 3. The common electrodes 5 are provided apart from the gate lines 3 on the support substrate 1. The first gate insulating layer 6 covers the gate lines 3 and the gate terminals 4 and is made of silicon nitride.

The second gate insulating layer 7A is provided on the gate electrodes 2 via the first gate insulating layer 6 in each of the plurality of pixel regions. The first intersecting layer 7B is provided on the gate lines 3 via the first gate insulating layer 6 and intersects with the gate lines 3. The channel layer 8A is provided on the second gate insulating layer 7A and has the same shape as the second gate insulating layer 7A. The second intersecting layer 8B is provided on the first intersecting layer 7B and has the same shape as the first intersecting layer 7B. Of the first intersecting layer 7B and the second intersecting layer 8B, portions that extend off the gate lines 3 in plan view may have conductivity.

The source electrodes 9 and the drain electrodes 10 are spaced from and oppose each other on the channel layer 8A. The source lines 11 are connected to the source electrodes 9 and intersect with the gate lines 3 on the second intersecting layer 8B. The source terminals 12 are connected to the source lines 11. The pixel electrodes 21 are respectively provided on the first gate insulating layer 6 in the plurality of pixel regions, and are in contact with the drain electrodes 10. The interlayer insulation layer 16 covers the channel layer 8A, the gate lines 3, the gate terminals 4, the source lines 11, the source terminals 12, and the pixel electrodes 21 and is made of silicon nitride. The counter electrode 24 is provided on the interlayer insulation layer 16 and opposes the pixel electrodes 21 via the interlayer insulation layer 16. The local insulating layer 14J is provided between the channel layer 8A and the interlayer insulation layer 16 and directly covers the channel layer 8A.

The interlayer insulation layer 16 has source contact holes 119 that reach the source terminals 12. The first gate insulating layer 6 and the interlayer insulation layer 16 have gate contact holes 118 that reach the gate terminals 4 and common electrode contact holes 20 that reach the common electrodes 5. The counter electrode 24 is connected to the common electrodes 5 through the common electrode contact holes 20. The second gate insulating layer 7A, the channel layer 8A, the first intersecting layer 7B, the second intersecting layer 8B, and the local insulating layer 14J are made of oxide and have a common species of elements and a common crystal structure.

The fifth preferred embodiment can achieve approximately the same effects as those of the fourth preferred embodiment.

Moreover, all the layers penetrated by the gate contact holes 118, the source contact holes 119, and the common electrode contact holes 20 are formed not of oxide but of silicon nitride. Thus, in the fifth preferred embodiment, the contact holes can also be formed with ease as in the first preferred embodiment. Accordingly, the TFT substrate 705 can be manufactured with high yield and high productivity. Moreover, according to the present preferred embodiment, the number of photolithographic processes can be reduced by one, as compared with the number in the fourth preferred embodiment, by omitting the protective insulating layer 15 (fourth preferred embodiment in FIG. 43). This further improves productivity.

Of the first intersecting layer 7B and the second intersecting layer 8B, portions that extend off the gate lines 3 in plan view may have conductivity. In this case, it is possible to suppress the occurrence of operational failures in thin-film transistors caused by disconnection of the source lines 11 as in the second preferred embodiment.

Details of Structure

Hereinafter, differences from the fourth preferred embodiment are mainly described in detail. The other configuration is almost the same as the configuration of the above-described fourth preferred embodiment, and therefore identical or corresponding constituent elements are given the same reference numerals, and a detailed description thereof is not repeated.

As described above, the TFT substrate 705 (FIG. 47) according to the fifth preferred embodiment omits the protective insulating layer 15 (fourth preferred embodiment in FIG. 43). Thus, the pixel electrodes 21 and the drain electrodes 10 are directly connected to each other without passing through the pixel drain contact holes 17 of the protective insulating layer 15. Following this, the interlayer insulation layer 16 disposed on the upper main surface of the support substrate 1 so as to cover the pixel electrodes 21 directly covers the local insulating layer 14J in the TFT portion PT.

In the pixel electrode portion PE, common electrode contact holes 20 are provided, instead of the common electrode contact holes 220 (fourth preferred embodiment in FIGS. 43 and 44). In plan view, the positions of the common electrode contact holes 20 are the same as the positions of the common electrode contact holes 220. The counter electrode 24 reaches the common electrodes 5 in the common electrode contact holes 20 through only two layers, namely, the interlayer insulation layer 16 and the first gate insulating layer 6. Accordingly, the counter electrode 24 is connected to the common electrodes 5 through the common electrode contact holes 20.

Also, as illustrated in FIG. 47, the gate contact holes 118 and the source contact holes 119 are provided, instead of the gate contact holes 18 and the source contact holes 19 (fourth preferred embodiment in FIG. 43). The gate contact holes 118 and the source contact holes 119 respectively reach the gate terminals 4 and the source terminals 12 through only two layers, namely, the interlayer insulation layer 16 and the first gate insulating layer 6. Also, gate pads 122 and source pads 123 are provided, instead of the gate pads 22 and the source pads 23 (fourth preferred embodiment in FIG. 43). The gate pads 122 and the source pads 123 are disposed respectively in the gate contact holes 118 and the source contact holes 119. Thus, the gate pads 122 and the source pads 123 are respectively connected to the gate terminals 4 and the source terminals 12. The materials for the gate pads 122 and the source pads 123 may be the same as the material for the counter electrode 24. Note that the additional pads 222 and 223 (fourth preferred embodiment in FIG. 43) are not provided in the present preferred embodiment.

Manufacturing Method

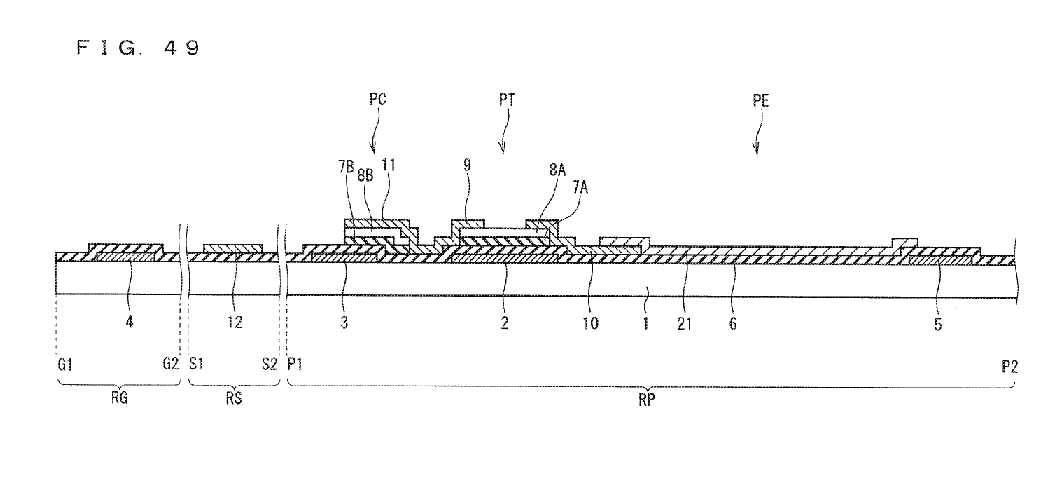

Next, a method of manufacturing the TFT substrate 705 according to the present preferred embodiment is described below with further reference to FIGS. 49 to 54. Among these figures, the fields of view in figures that correspond to partial sectional views are the same as the field of view in FIG. 47, and the fields of view in figures that correspond to partial plan views are the same as the field of view in FIG. 48.

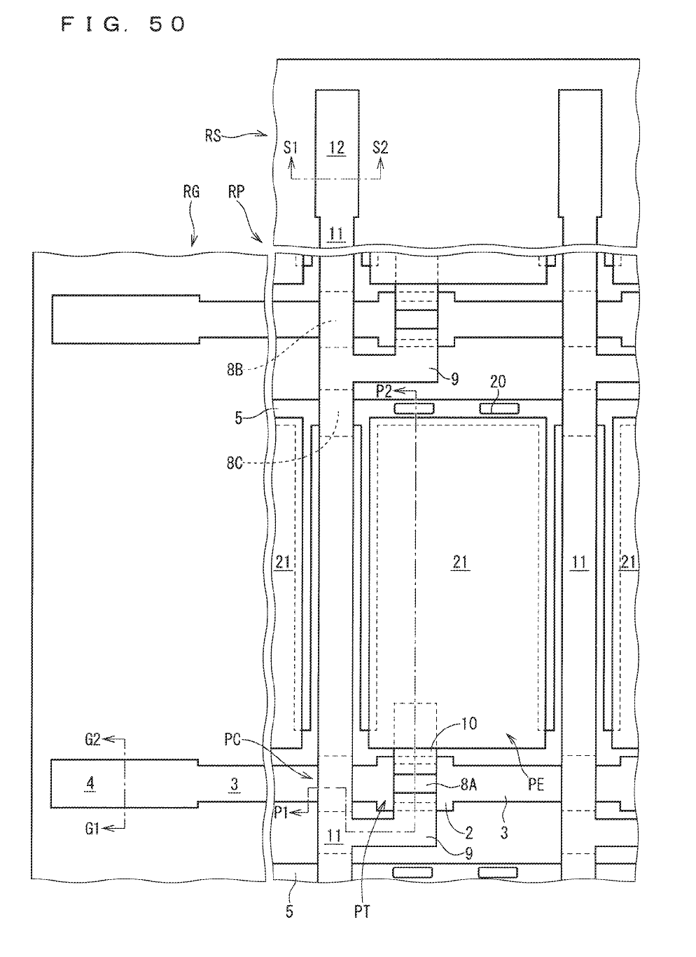

Fourth Photolithographic Process (FIGS. 49 and 50)

Referring to FIGS. 49 and 50, after execution of steps that are almost the same as the steps up to FIGS. 9 and 10 (first preferred embodiment) and that include the first to third photolithographic processes, the third conductive film that is to be patterned into the pixel electrodes 21 is deposited. The method of depositing the third conductive film may be the same as that of the first preferred embodiment. As a preferable example, an ITO film that is a transparent conductive film is deposited to a thickness of 100 nm in an amorphous state as in the first preferred embodiment.

Then, the fourth photolithographic process is performed. Specifically, a photoresist pattern is formed, and the third conductive film is patterned by etching using the photoresist pattern as a mask. As a preferable example, wet etching using an oxalic acid-based chemical solution is used as in the first preferred embodiment. Thereafter, the photoresist pattern is removed. In the case of using an amorphous ITO film as described above, heat treatment for crystallization into a polycrystalline film is performed as in the first preferred embodiment.

Accordingly, the pixel electrodes 21 are formed from the third conductive film. Part of the edge portions of the pixel electrodes 21 overlap with the common electrodes 5 located thereunder via the first gate insulating layer 6, thereby forming part of a holding capacitor for holding the potential of the pixel.

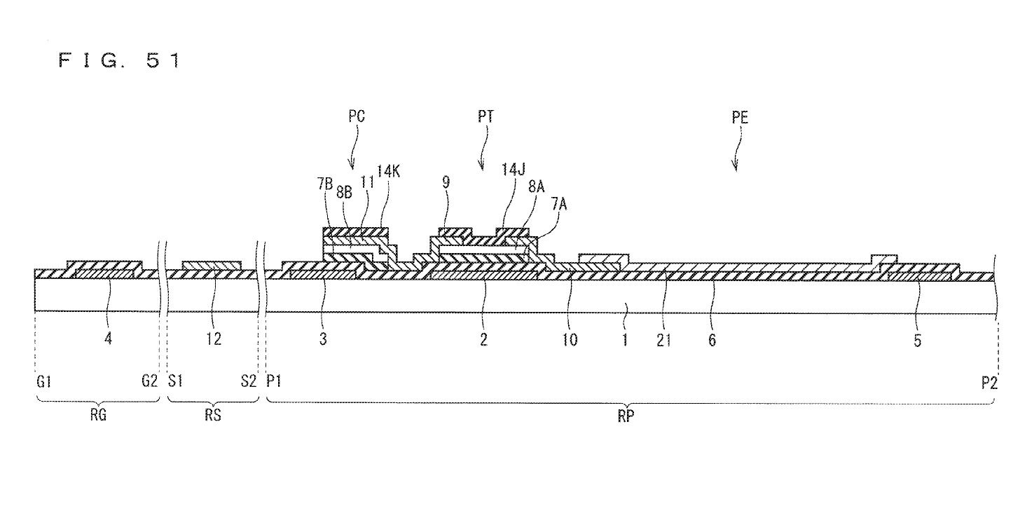

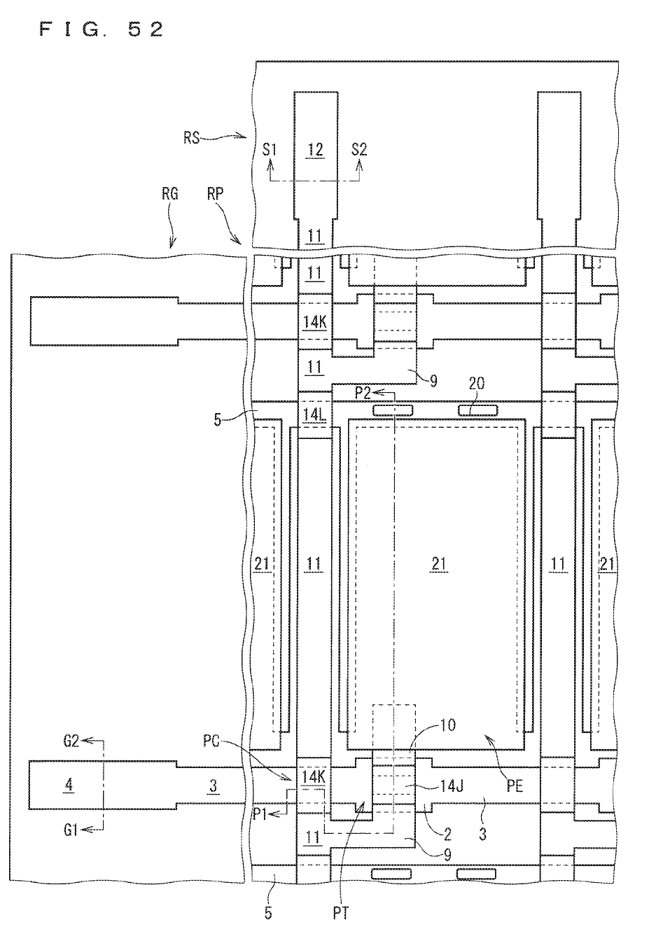

Fifth Photolithographic Process (FIGS. 51 and 52)

Referring to FIGS. 51 and 52, next, the third insulation film that is to be patterned into, for example, the local insulating layer 14J is deposited. As a preferable example, an InGaZnO film having insulating properties is deposited to a thickness of 100 nm by sputtering as in the first preferred embodiment.

Thereafter, the fourth photolithographic process is performed. Specifically, a photoresist material is applied to the top of the third insulation film and used to form a photoresist pattern. As a preferable example, the same photoresist pattern as the photoresist pattern used in the aforementioned fourth photolithographic process is used. Thereafter, the third insulation film is patterned by etching using that photoresist pattern as a mask. As a preferable example, wet etching using an oxalic acid-based chemical solution is performed as in the first preferred embodiment. Thereafter, the photoresist pattern is removed. Accordingly, the local insulating layer 14J is formed from the third insulation film. Simultaneously, the insulating layer 14K may be formed.

In plan view (FIG. 52), the local insulating layer 14J may be formed in approximately the same shape as the second gate insulating layer 7A and the channel layer 8A. Also, the insulating layer 14K may be formed in approximately the same shape as the first intersecting layer 7B and the second intersecting layer 8B.

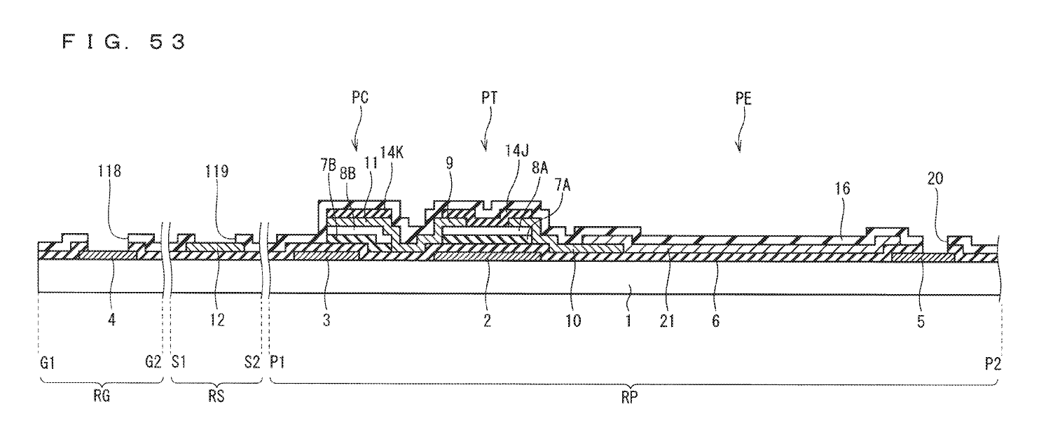

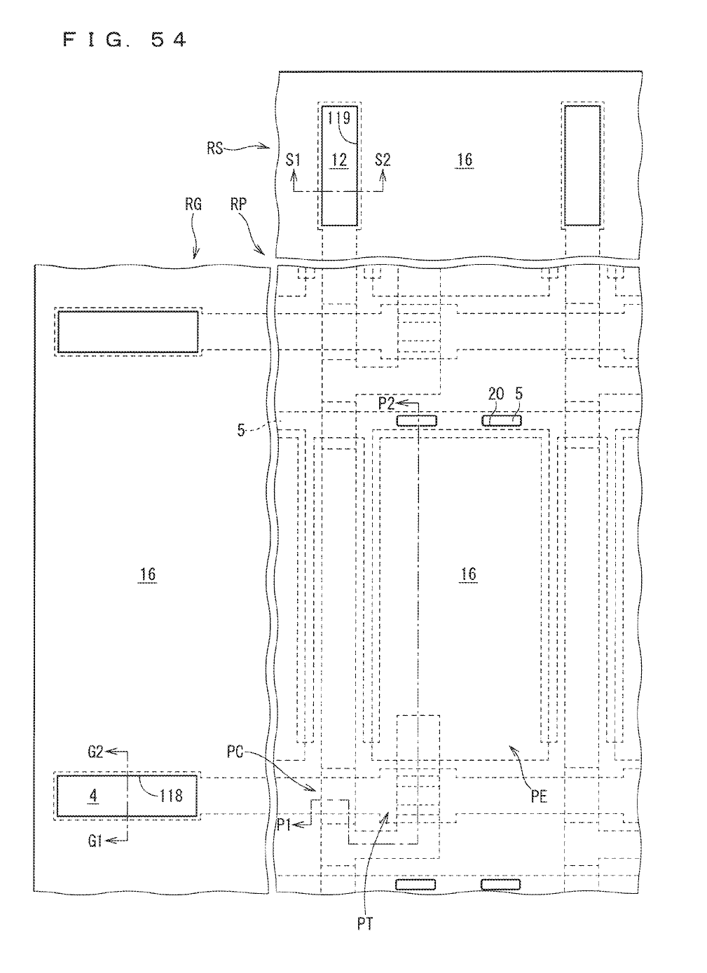

Sixth Photolithographic Process (FIGS. 53 and 54)

Next, the fifth insulation film that serves as the interlayer insulation layer 16 is deposited. Note that in the present preferred embodiment, the fourth insulation film corresponding to the protective insulating layer 15 (first to third preferred embodiments) is omitted. As a preferable example, an SiN film with a thickness of 150 nm is deposited as the fifth insulation film by PECVD. Note that the method of depositing the fifth insulation film may be the same as the method of depositing the fourth insulation film.

Thereafter, the sixth photolithographic process is performed. Specifically, a photoresist pattern is formed, and etching is performed using the photoresist pattern as a mask. Accordingly, the fifth insulation film and the first insulation film that are made of SiN, i.e., the interlayer insulation layer 16 and the first gate insulating layer 6, are patterned. This etching can use dry etching using a gas that contains fluorine. As a preferable example, dry etching is performed using a gas made by adding O₂ to SF₆. Thereafter, the photoresist pattern is removed.

Through this patterning, the common electrode contact holes 20 that penetrate the interlayer insulation layer 16 and the first gate insulating layer 6, the source contact holes 119 that penetrate the interlayer insulation layer 16, and the gate contact holes 118 that penetrate the interlayer insulation layer 16 and the first gate insulating layer 6 are formed simultaneously as illustrated in FIGS. 53 and 54. Accordingly, the common electrode contact holes 20 expose part of the surfaces of the common electrodes 5, the gate contact holes 118 expose part of the surfaces of the gate terminals 4, and the source contact holes 119 expose part of the surfaces of the source terminals 12.

In plan view (FIG. 54), the common electrode contact holes 20 are formed in regions that overlap with the common electrodes 5 and that do not overlap with the pixel electrodes 21. The number of common electrode contact holes 20 can be arbitrarily determined, and in the example illustrated in FIG. 54, two common electrode contact holes 20 are formed in each pixel region. By providing a plurality of common electrode contact holes 20, even if one of the holes has a failure due to a pattern failure or other reasons, the other holes can compensate for the failed one.

Seventh Photolithographic Process

Referring again to FIGS. 47 and 48, next, the fourth conductive film that is to be patterned into the counter electrode 24, the gate pads 122, and the source pads 123 is deposited. The fifth preferred embodiment, like the fourth preferred embodiment, uses a transparent conductive film (translucent conductive film) as the fourth conductive film. As a preferable example, an ITO film with a thickness of 100 nm is deposited in an amorphous state as in the fourth preferred embodiment.

Then, the seventh photolithographic process is performed. Specifically, a photoresist pattern is formed, and the fourth conductive film is patterned by etching using the photoresist pattern as a mask. As a preferable example, wet etching using an oxalic acid-based chemical solution is performed as in the fourth preferred embodiment. In the case of using an amorphous ITO film as described above, heat treatment for causing the amorphous ITO film to crystallize into a polycrystalline ITO film is performed as in the fourth preferred embodiment. Accordingly, the counter electrode 24, the gate pads 122, and the source pads 123 are formed.

Through the steps described above, the TFT substrate 705 according to the fifth preferred embodiment is completed. The TFT substrate 705, like the TFT substrate 704 (fourth preferred embodiment), is applicable to an FFS-mode liquid crystal display panel. Also, a liquid crystal display can be manufactured using this liquid crystal display panel.

### Sixth Preferred Embodiment

Overview

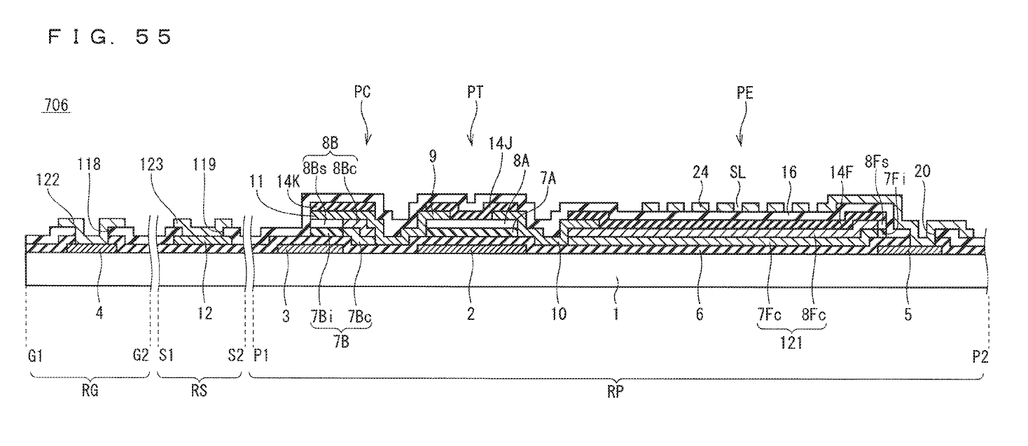

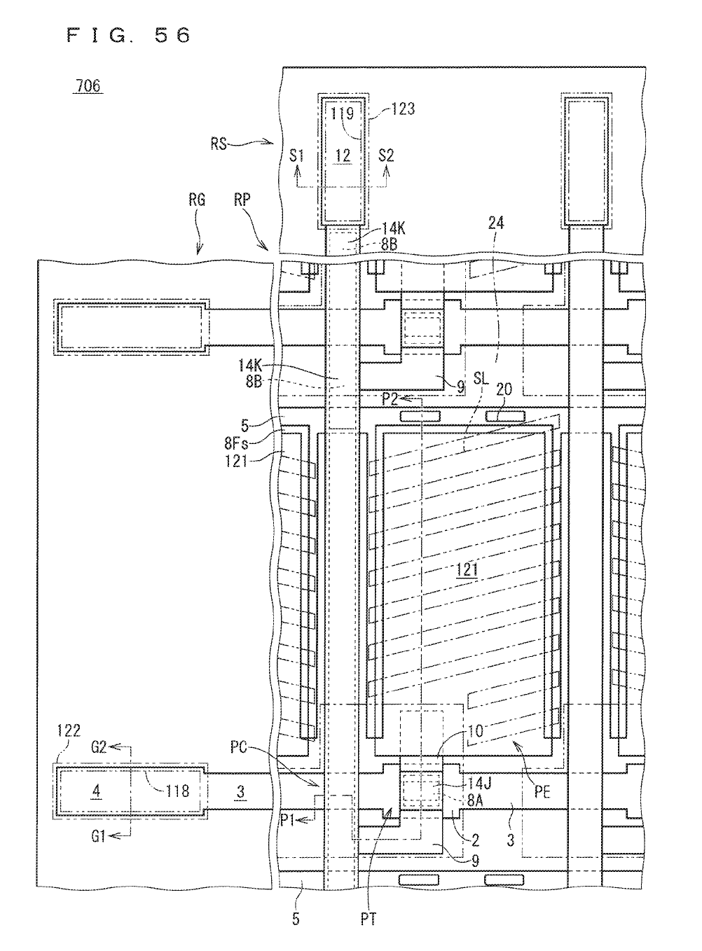

FIGS. 55 and 56 are respectively a partial sectional view and a partial plan view that schematically illustrate a configuration of a thin-film transistor substrate (TFT substrate) 706 according to a sixth preferred embodiment. The section illustrated in FIG. 55 is taken along line G1-G2 in the gate terminal portion RG, line S1-S2 in the source terminal portion RS, and line P1-P2 in the pixel portion RP in FIG. 56. Note that part of the configuration is not shown in FIG. 56 in order to facilitate viewing of the internal configuration of the TFT substrate 706.

The TFT substrate 706 according to the present preferred embodiment includes a pixel electrodes 121, instead of the pixel electrodes 21 (FIGS. 47 and 48) of the TFT substrate 705. The pixel electrodes 121 include a first pixel electrode layer 7Fc provided on the first gate insulating layer 6, and a second pixel electrode layer 8Fc provided on the first pixel electrode layer 7Fc and having the same shape as the first pixel electrode layer 7Fc. The first pixel electrode layer 7Fc and the second pixel electrode layer 8Fc are made of oxide. Also, the first pixel electrode layer 7Fc and the second pixel electrode layer 8Fc have a common species of elements and a common crystal structure with the second gate insulating layer 7A, the channel layer 8A, the first intersecting layer 7B, the second intersecting layer 8B, and the local insulating layer 14J.

The sixth preferred embodiment can achieve almost the same effects as those of the fifth preferred embodiment. Moreover, according to the sixth preferred embodiment, the first pixel electrode layer 7Fc and the second pixel electrode layer 8Fc that constitute the pixel electrodes 121, the second gate insulating layer 7A, and the channel layer 8A have a common species of elements and a common crystal structure. Thus, the number of photolithographic processes can be reduced by performing the deposition and patterning of these configurations simultaneously. This further improves the productivity of the TFT substrate 706.

Specifically, according to the sixth preferred embodiment, the number of photolithographic processes can be reduced to a total of six, which is smaller by one than the number in the above-described fifth preferred embodiment. To achieve this, laminated film patterns that are formed simultaneously with the laminated film patterns of the second gate insulating layer 7A and the channel layer 8A are used as pixel electrodes, instead of the pixel electrodes 21 (fourth preferred embodiment in FIG. 43). Accordingly, a TFT substrate for FFS-mode LCDs can be manufactured with higher productivity. Hereinafter, these differences are mainly described in detail. The other configuration is similar to the configuration of the above-described second or fifth preferred embodiment, and therefore identical or corresponding constituent elements are given the same reference numerals, and a detailed description thereof is not repeated.

Details of Structure

Referring to FIG. 55, as described above, laminated film patterns of the first pixel electrode layer 7Fc and the second pixel electrode layer 8Fc, which are made of oxide and to which conductivity are imparted, constitute the pixel electrodes 121 on the first gate insulating layer 6 from the TFT portion PT to the pixel electrode portion PE. The pixel electrodes 121 has translucency. The first pixel electrode layer 7Fc and the second pixel electrode layer 8Fc, like the other oxide conductive layers described above, preferably have electrical specific resistance values of less than 0.1 Ωcm, and more preferably electrical specific resistance values of less than 1×10⁻² Ωcm. As a preferable example, the material for the first pixel electrode layer 7Fc and the second pixel electrode layer 8Fc is InGaZnO. InGaZnO has a transmittance of greater than or equal to 70% with respect to visible light from 400 to 800 nm, irrespective of whether it is a conductor, a semiconductor, or an insulator. Accordingly, InGaZnO to which conductivity has been imparted is favorably used as the material for pixel electrodes.

The arrangement of the pixel electrodes 121 is approximately the same arrangement as that of the pixel electrodes 21 (fifth preferred embodiment in FIG. 47). Specifically, in plan view (FIG. 56), each pixel electrode 121 is disposed in a region surrounded by a gate electrode 2, a common electrode 5, and two source lines 11. As illustrated in FIG. 55, the drain electrode 10 is disposed so as to extend off the gate electrode 2 toward the pixel electrode portion PE, and part of the drain electrode 10 is in contact with the upper surface of the second pixel electrode layer 8Fc of the pixel electrode 121.

As illustrated in FIGS. 55 and 56, the first intersecting layer 7B and the second intersecting layer 8B are provided on the first gate insulating layer 6. This improves coverage at the intersections as in the second preferred embodiment. Accordingly, it is possible to prevent the disconnection of the source lines 11 due to step height discontinuity (discontinuity or rupture of films at step heights).

The configuration of the first intersecting layer 7B and the second intersecting layer 8B according to the sixth preferred embodiment is similar to that of the second preferred embodiment (FIGS. 16 and 17), and conductivity is imparted to part of the first intersecting layer 7B and the second intersecting layer 8B. Specifically, the first intersecting layer 7B includes the insulator portion 7Bi and the conductor portion 7Bc, and the second intersecting layer 8B includes the semiconductor portion 8Bs and the conductor portion 8Bc. The conductor portion 7Bc of the first intersecting layer 7B and the conductor portion 8Bc of the second intersecting layer 8B serve as redundant lines of the source lines 11. Thus, even if the source lines 11 are disconnected due to a pattern failure or other reasons, a failure in the TFT substrate 706 can be avoided unless the disconnected portion overlaps with the gate lines 3 and the common electrodes 5.

Manufacturing Method

Next, a method of manufacturing the TFT substrate 706 according to the present preferred embodiment is described below.

First Photolithographic Process

First, the laminated film 201 is formed by performing the same steps as those up to FIG. 6 in the first preferred embodiment. These steps include the first photolithographic process.

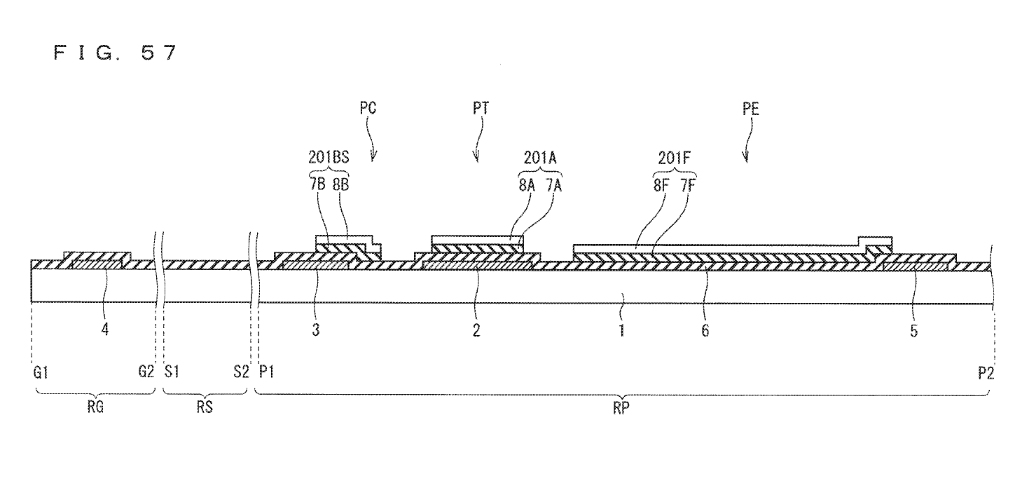

Subsequent steps are described with further reference to FIGS. 57 to 66. Among these figures, the fields of view in figures that correspond to partial sectional views are the same as the field of view in FIG. 55, and the fields of view in figures that correspond to partial plan views are the same as the field of view in FIG. 56.

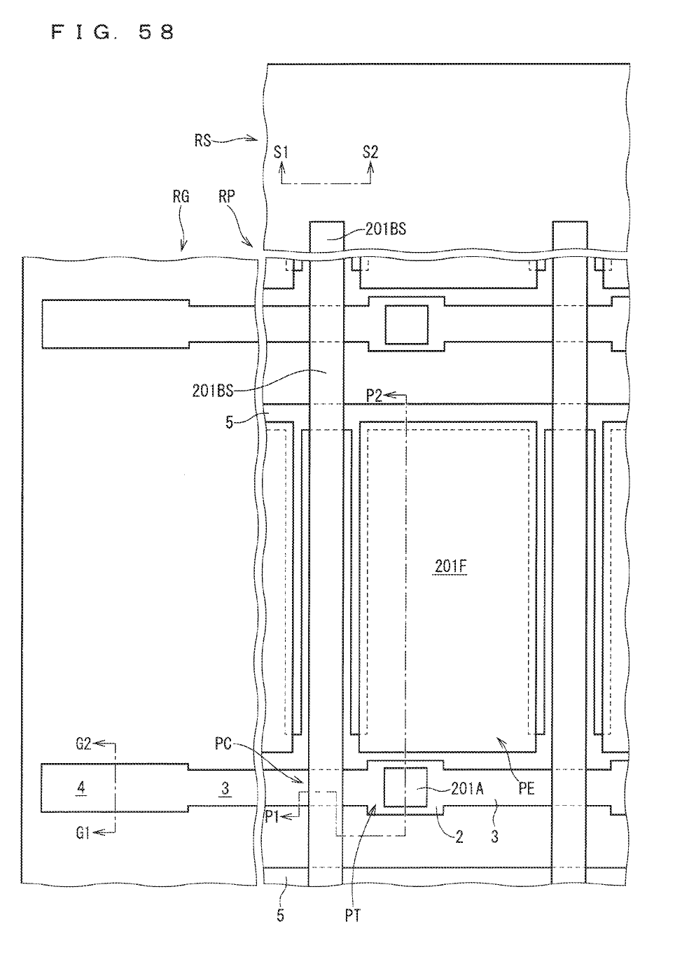

Second Photolithographic Process (FIGS. 57 and 58)

Referring to FIGS. 57 and 58, next, the laminated film 201 is patterned by the second photolithographic process. Accordingly, the laminated film patterns 201A and 201BS are formed as in the second preferred embodiment (FIG. 18), and simultaneously a laminated film pattern 201F is formed. The laminated film pattern 201F includes an insulating layer 7F formed from the second insulation film and a semiconductor layer 8F formed from the oxide semiconductor film. The semiconductor layer 8F is disposed on the insulating layer 7F, and these layers have approximately the same shape. Of the laminated film pattern 201F, portions that do not overlap with the common electrodes 5 in plan view forms the pixel electrodes 121 in a subsequent step. The laminated film pattern 201F may overlap in part with the common electrodes 5 in plan view. Note that the patterning method for the laminated film 201 is the same as that of the second preferred embodiment.

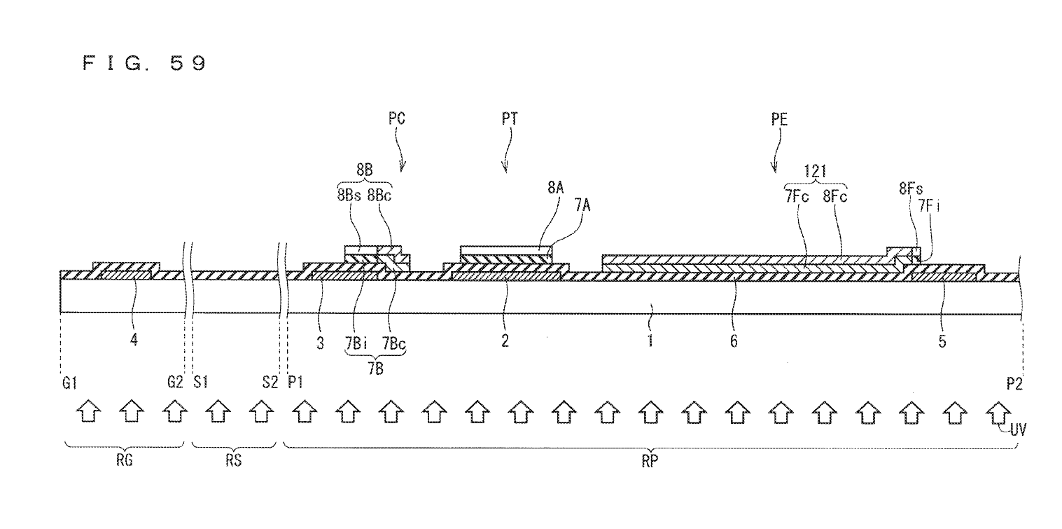

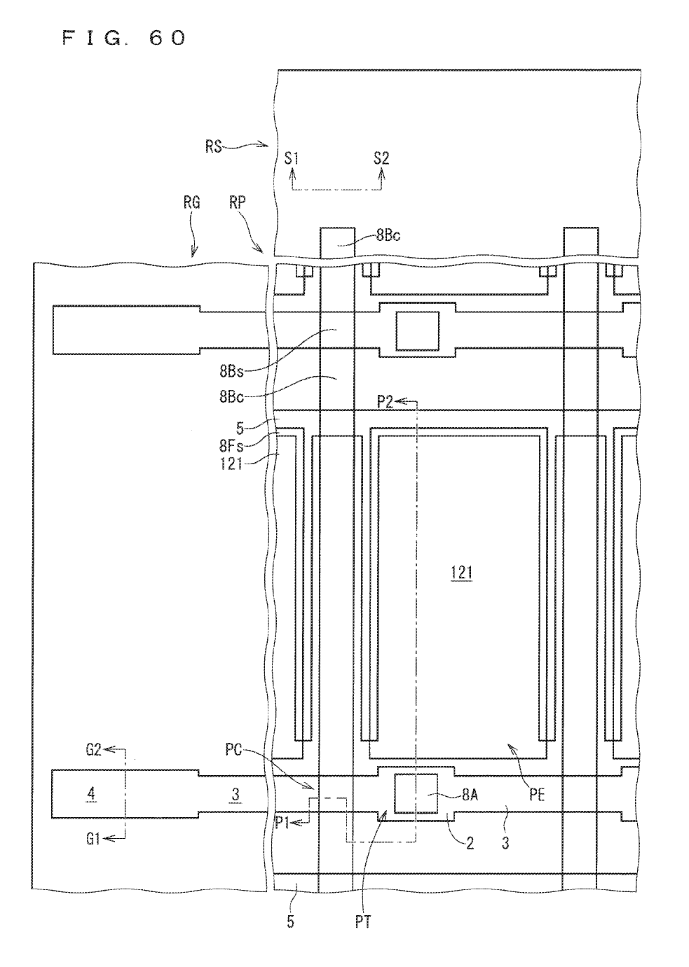

Ultraviolet Light Application Process (FIGS. 59 and 60)

Referring to FIGS. 59 and 60, next, ultraviolet light UV is applied by the same method as that illustrated in FIGS. 20 and 21 (second preferred embodiment). Accordingly, the conductor portions 7Bc and 8Bc are formed as in the second preferred embodiment. At the same time, conductivity is imparted to portions of the laminated film pattern 201F (FIG. 57); the portions extend off the gate lines 3 and the common electrodes 5 in plan view. That is, conductivity is imparted to, of the laminated film pattern 201F, portions that are irradiated with the ultraviolet light UV, so that they serve as the first pixel electrode layer 7Fc and the second pixel electrode layer 8Fc that constitute the pixel electrodes 121. Of the laminated film pattern 201F, portions that are not irradiated with the ultraviolet light UV undergo no change in specific resistance and remain as the insulator portion 7Fi and the semiconductor portion 8Fs.

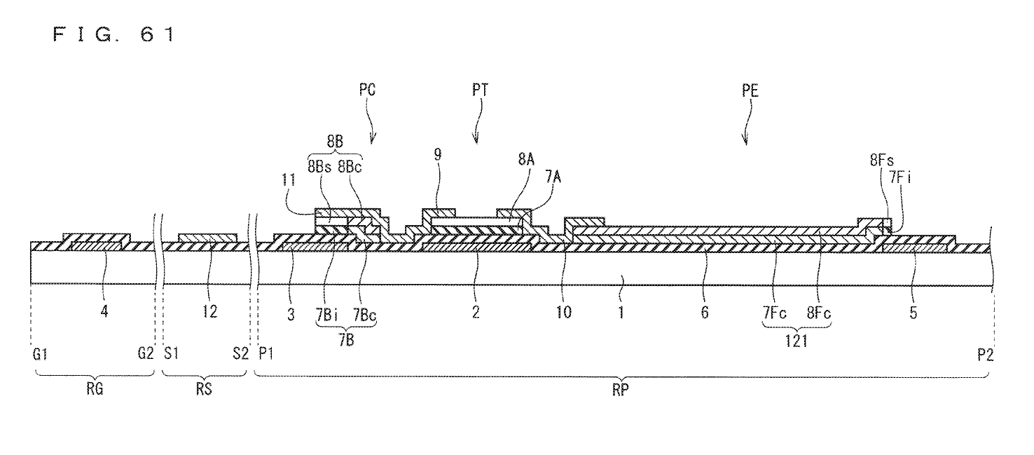

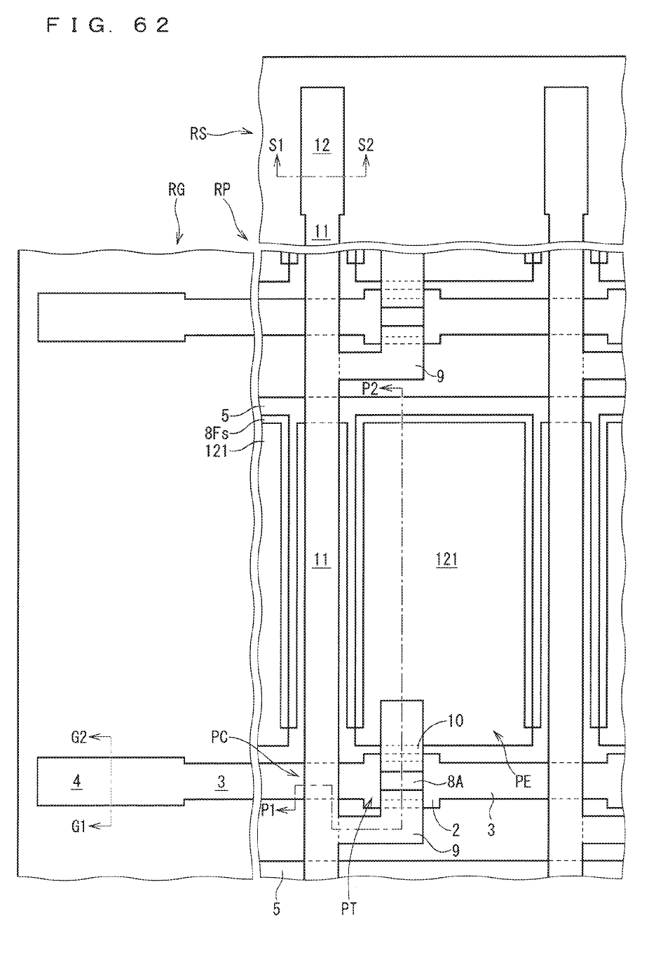

Third Photolithographic Process (FIGS. 61 and 62)

Referring to FIGS. 61 and 62, next, the source electrodes 9, the drain electrodes 10, the source lines 11, and the source terminals 12 are formed by the step using the third photolithographic process as in FIGS. 22 and 23 (second preferred embodiment). Parts of the drain electrodes 10 are formed on the second pixel electrode layer 8Fc of the pixel electrodes 121.

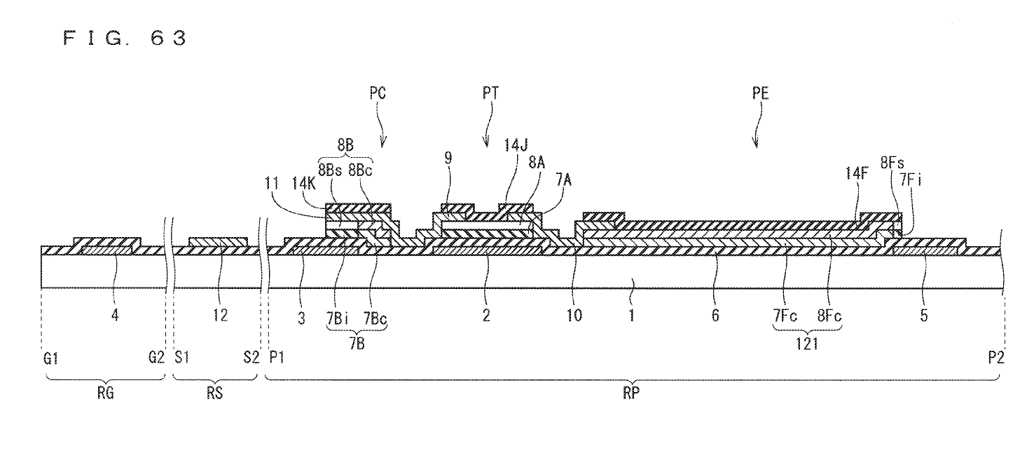

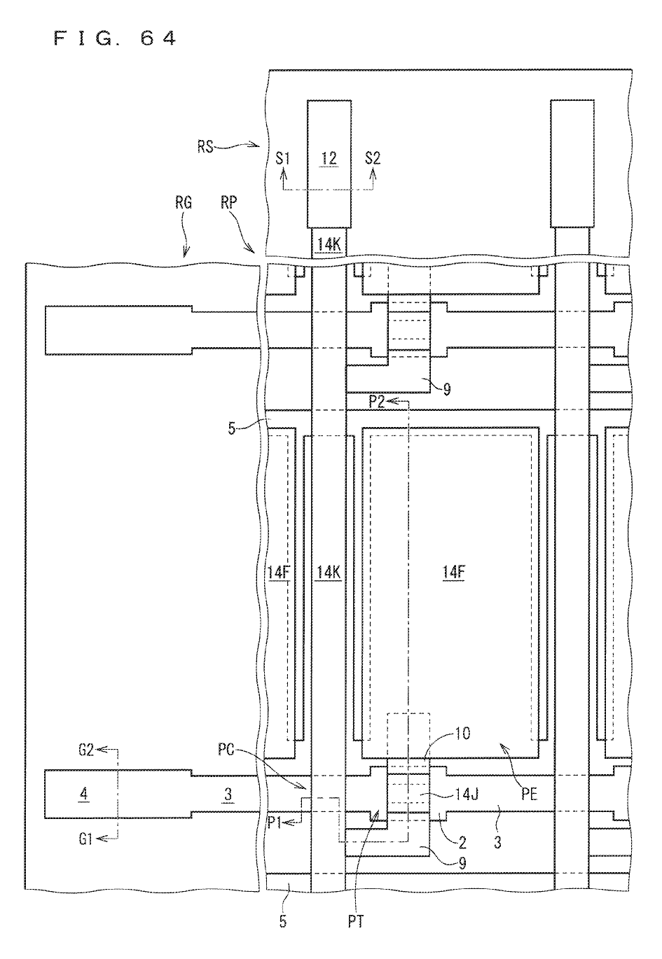

Fourth Photolithographic Process (FIGS. 63 and 64)

Referring to FIGS. 63 and 64, next, the local insulating layer 14J, the insulating layer 14K, and the insulating layer 14F are formed by the step using the fourth photolithographic process. This step is performed by the same method as the step in FIGS. 24 and 25 (second preferred embodiment), but in the sixth preferred embodiment, the insulating layer 14F is included as a pattern to be formed. In the sixth preferred embodiment, the photoresist pattern used in the second photolithographic process is also used in the third photolithographic process as in the second preferred embodiment. Thus, in plan view (FIG. 64), the insulating layer 14F and the laminated film pattern 201F (FIGS. 12 and 58) have approximately the same shape.

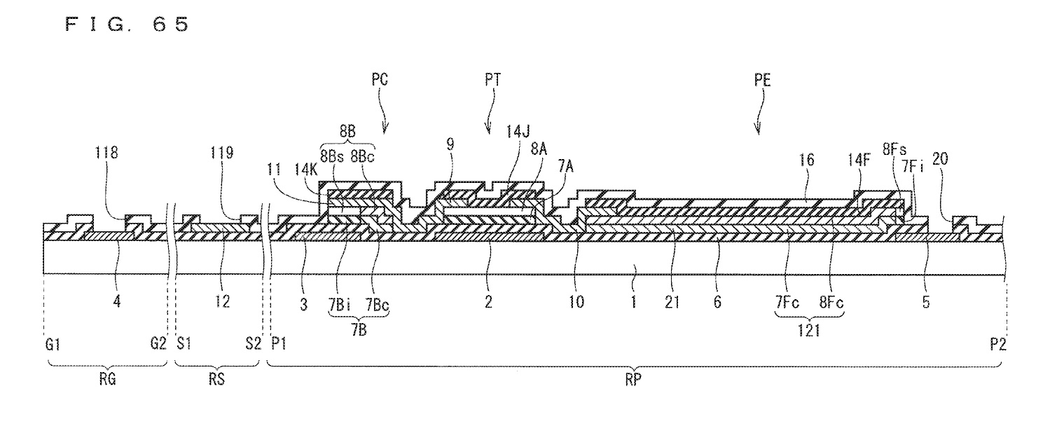

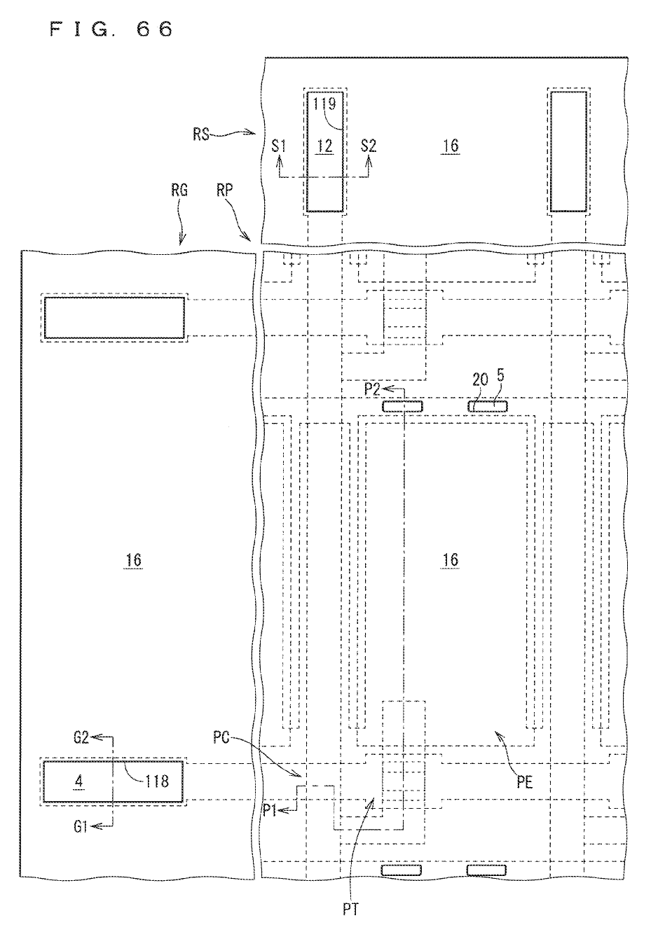

Fifth Photolithographic Process (FIGS. 65 and 66)

Referring to FIGS. 65 and 66, next, the interlayer insulation layer 16 having the common electrode contact holes 20, the gate contact holes 118, and the source contact holes 119 is formed by the steps using the fifth photolithographic process. This step is performed by the same method as that used in the step in FIGS. 53 and 54 (second preferred embodiment).

Sixth Photolithographic Process

Referring again to FIGS. 55 and 56, the counter electrode 24, the gate pads 122, and the source pads 123 are formed by the step using the sixth photolithographic process. This step is the same as that of the fifth preferred embodiment. The sixth preferred embodiment differs from the fifth preferred embodiment in that the deposition and patterning of the fourth conductive film are performed by the above-described step without forming the third conductive film that forms the pixel electrodes 21 (fifth preferred embodiment in FIG. 51).

Through the steps described above, the TFT substrate 706 according to the sixth preferred embodiment is completed. The TFT substrate 706, like the TFT substrate 704 (fourth preferred embodiment), is applicable to an FFS-mode liquid crystal display panel. Also, a liquid crystal display can be manufactured using this liquid crystal display panel.

### Seventh Preferred Embodiment

Overview

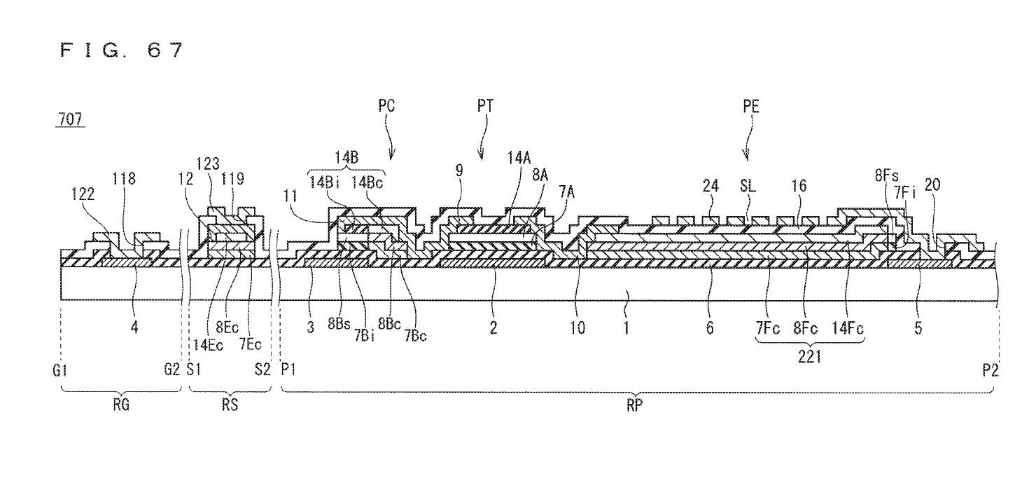

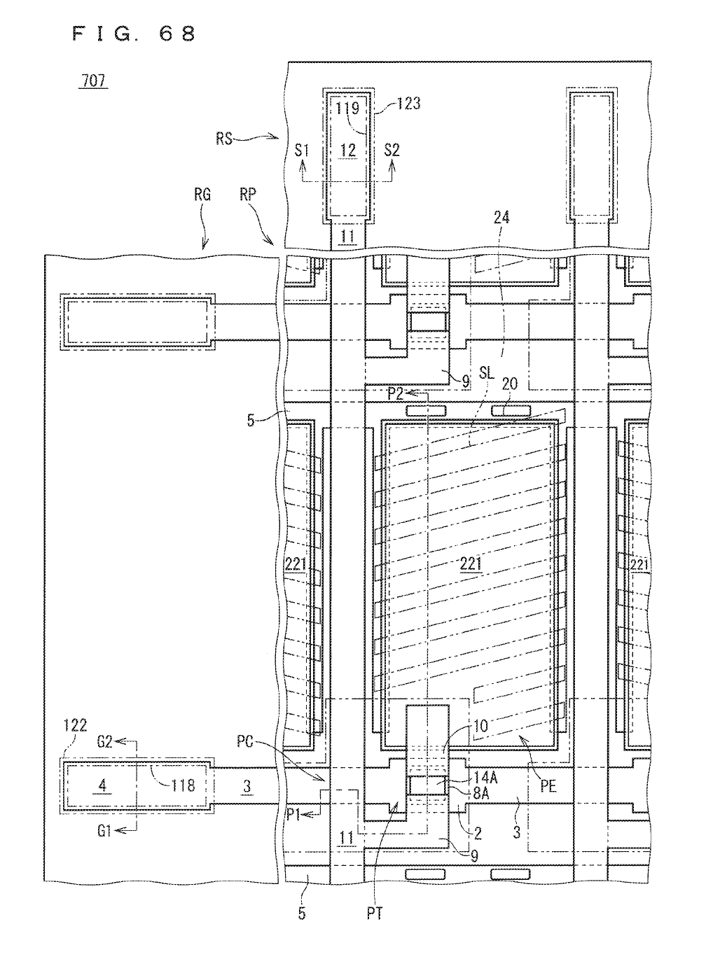

FIGS. 67 and 68 are respectively a partial sectional view and a partial plan view that schematically illustrate a configuration of a thin-film transistor substrate (TFT substrate) 707 according to a seventh preferred embodiment. The section illustrated in FIG. 67 is taken along line G1-G2 in the gate terminal portion RG, line S1-S2 in the source terminal portion RS, and line P1-P2 in the pixel portion RP in FIG. 68. Note that part of the configuration is not shown in FIG. 68 in order to facilitate viewing of the internal configuration of the TFT substrate 707.

The seventh preferred embodiment is different from the sixth preferred embodiment in that the local insulating layer 14A (FIG. 28) described in detail in the third preferred embodiment is provided, instead of the local insulating layer 14J (sixth preferred embodiment in FIG. 55). Also, a third pixel electrode layer 14Fc is provided that is formed by imparting conductivity to the member corresponding to the insulating layer 14F (sixth preferred embodiment in FIG. 55). The third pixel electrode layer 14Fc constitutes laminated film patterns that serve as the pixel electrodes 221, together with the first pixel electrode layer 7Fc and the second pixel electrode layer 8Fc. The arrangement of the pixel electrodes 221 in plan view (FIG. 68) is the same as that of the pixel electrodes 121 (sixth preferred embodiment in FIG. 56). One ends of the drain electrodes 10 are disposed on the local insulating layer 14A, and the other ends of the drain electrodes 10 are disposed on the pixel electrode 221, i.e., on the third pixel electrode layer 14Fc. Also, the conductor portion 7Ec, the conductor portion 8Ec, and the conductor portion 14Ec may be provided in the source terminal portion RS as in the third preferred embodiment.

The seventh preferred embodiment can achieve almost the same effects as those of the sixth preferred embodiment. Moreover, since the local insulating layer 14A and the channel layer 8A have the same shape, the photolithographic process for the local insulating layer 14A and the photolithographic process for the channel layer 8A can be integrated into a common photolithographic process. This reduces the number of photolithographic processes. Accordingly, the productivity of the TFT substrate 707 can be further improved. Specifically, according to the seventh preferred embodiment, the number of photolithographic processes can be reduced to a total of five, which is smaller by one than the number in the above-described sixth preferred embodiment. Thus, the local insulating layer 14A that constitute a common laminated film pattern together with the second gate insulating layer 7A and the channel layer 8A is provided, instead of the local insulating layer 14J (sixth preferred embodiment in FIG. 55). Accordingly, the TFT substrate for FFS-mode LCDs can be manufactured with higher productivity. This difference is mainly described in detail below. The other configuration is similar to the configuration of the above-described sixth preferred embodiment, and therefore identical or corresponding constituent elements are given the same reference numerals, and a detailed description thereof is not repeated.

Manufacturing Method

Next, a method of manufacturing the TFT substrate 707 according to the present preferred embodiment is described.

First Photolithographic Process

First, the laminated film 203 is formed by performing the same steps as those up to FIG. 30 in the third preferred embodiment. These steps include the first photolithographic process.

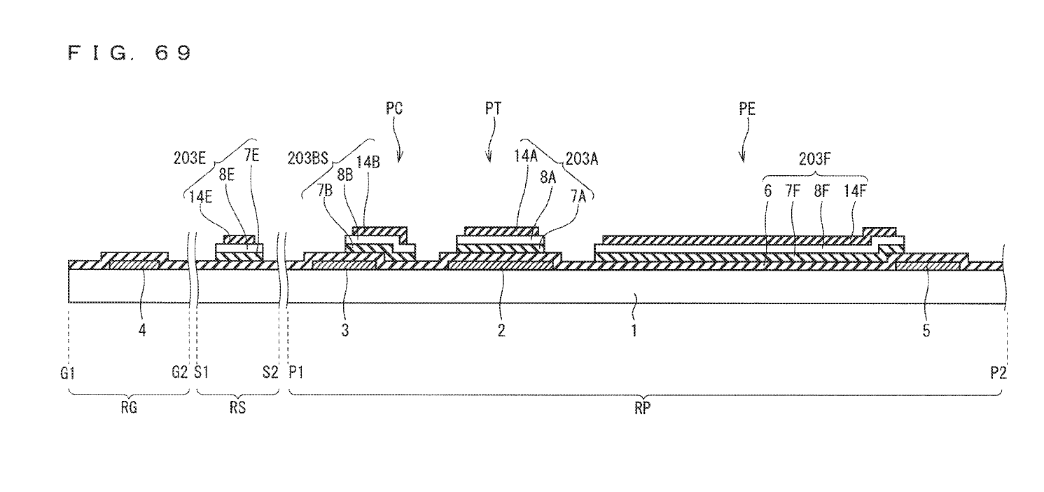

Subsequent steps are described with further reference to FIGS. 69 to 76. Among these figures, the fields of view in figures that correspond to partial sectional views are the same as the field of view in FIG. 67, and the fields of view in figures that correspond to partial plan views are the same as the field of view in FIG. 68.

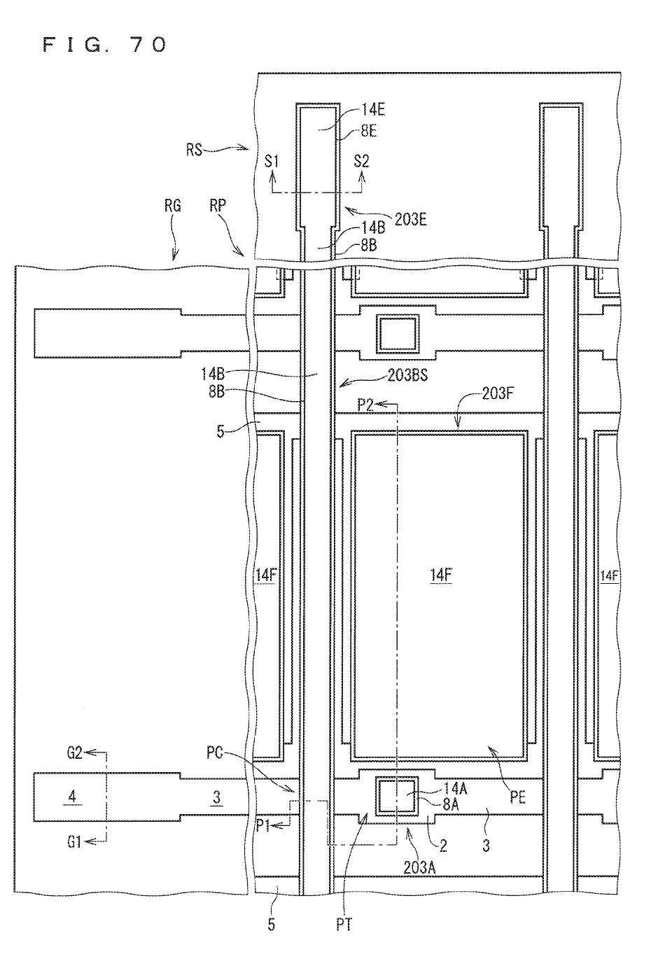

Second Photolithographic Process (FIGS. 69 and 70)

Referring to FIGS. 69 and 70, next, the laminated film 203 is patterned by the second photolithographic process. Accordingly, the laminated film patterns 203A, 203BS, and 203E are formed as in the third preferred embodiment (FIG. 35), and simultaneously a laminated film pattern 203F is formed. The laminated film pattern 203F includes the insulating layer 7F formed from the second insulation film, the semiconductor layer 8F formed from the oxide semiconductor film, and the insulating layer 14F formed from the third insulation film. The insulating layer 14F is disposed on the semiconductor layer 8F, and these layers have approximately the same shape. Strictly speaking, the outer edge of the insulating layer 14F is slightly inward of the outer edge of the semiconductor layer 8F in plan view (FIG. 70). Of the laminated film pattern 203F, portions that do not overlap with the common electrodes 5 in plan view form the pixel electrodes 221 in a subsequent step. The laminated film pattern 203F may overlap in part with the common electrodes 5 in plan view. Note that the patterning method for the laminated film 203 is the same as that of the third preferred embodiment.

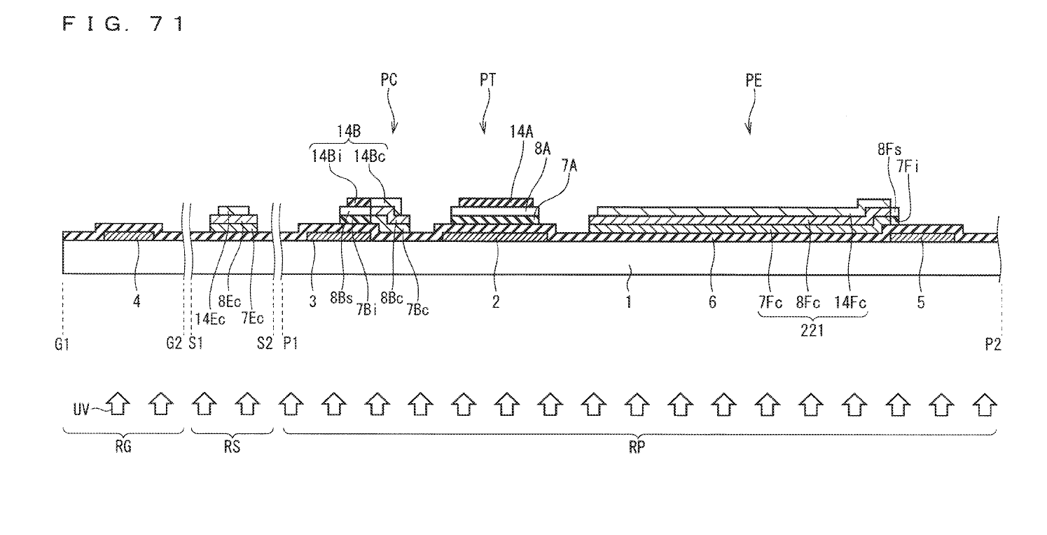

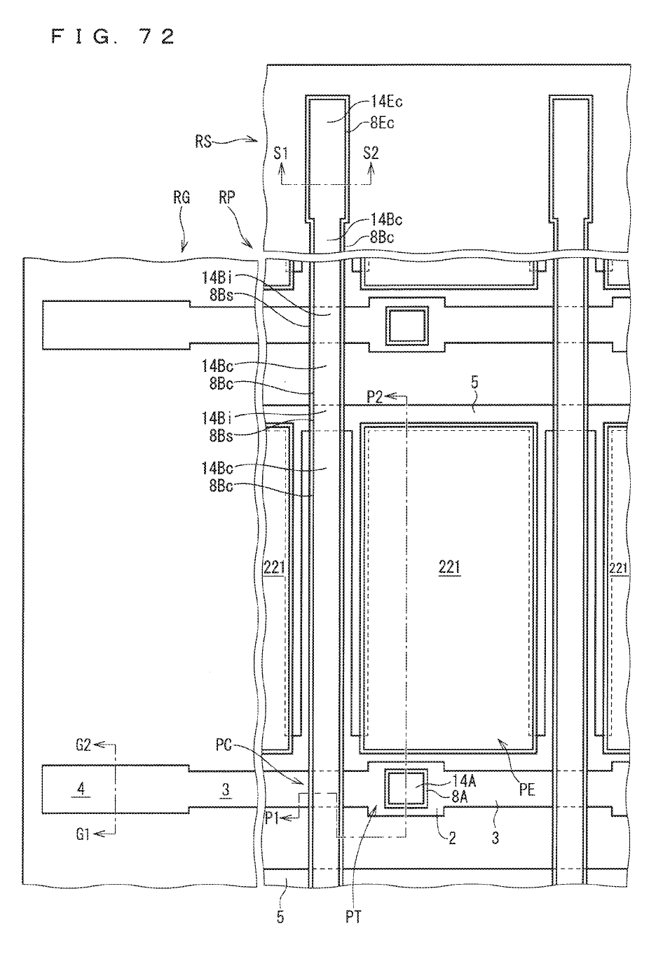

Ultraviolet Light Application Process (FIGS. 71 and 72)

Referring to FIGS. 71 and 72, next, ultraviolet light UV is applied by the same method as that illustrated in FIGS. 37 and 38 (third preferred embodiment). Accordingly, the conductor portions 7Bc, 8Bc, 7Ec, 8Ec, and 14Ec are formed as in the third preferred embodiment. Simultaneously, of the laminated film pattern 203F (FIG. 69), conductivity is imparted to portions that extend off the gate lines 3 and the common electrodes 5 in plan view. That is, conductivity is imparted to, of the laminated film pattern 203F, portions that are irradiated with the ultraviolet light UV, so that they serve as the first pixel electrode layer 7Fc, the second pixel electrode layer 8Fc, and the third pixel electrode layer 14Fc that constitute the pixel electrodes 121. Portions of the laminated film pattern 203F that are not irradiated with the ultraviolet light UV undergone no change in specific resistance and remain as the insulator portion 7Fi and the semiconductor portion 8Fs. The specific resistance value of the portions to which conductivity has been imparted is preferably less than 0.1 Ωcm, and more preferably less than 1×10⁻² Ω·cm.

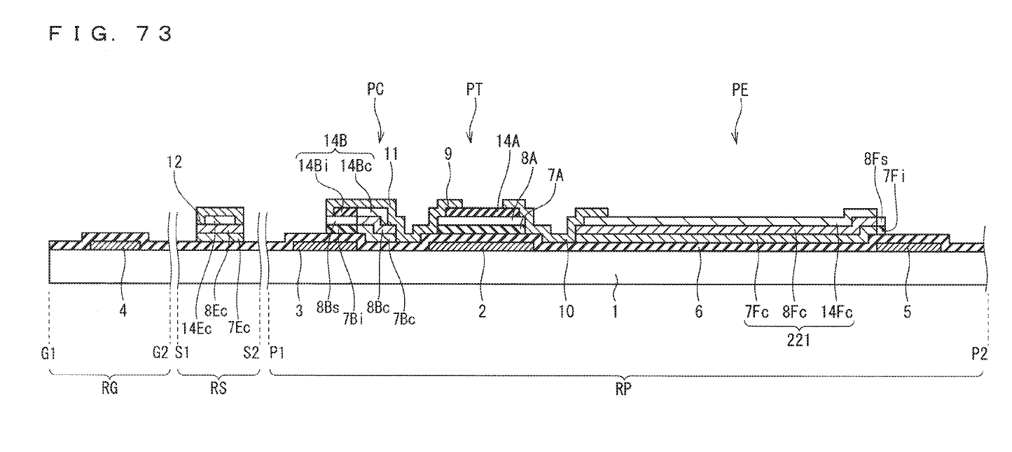

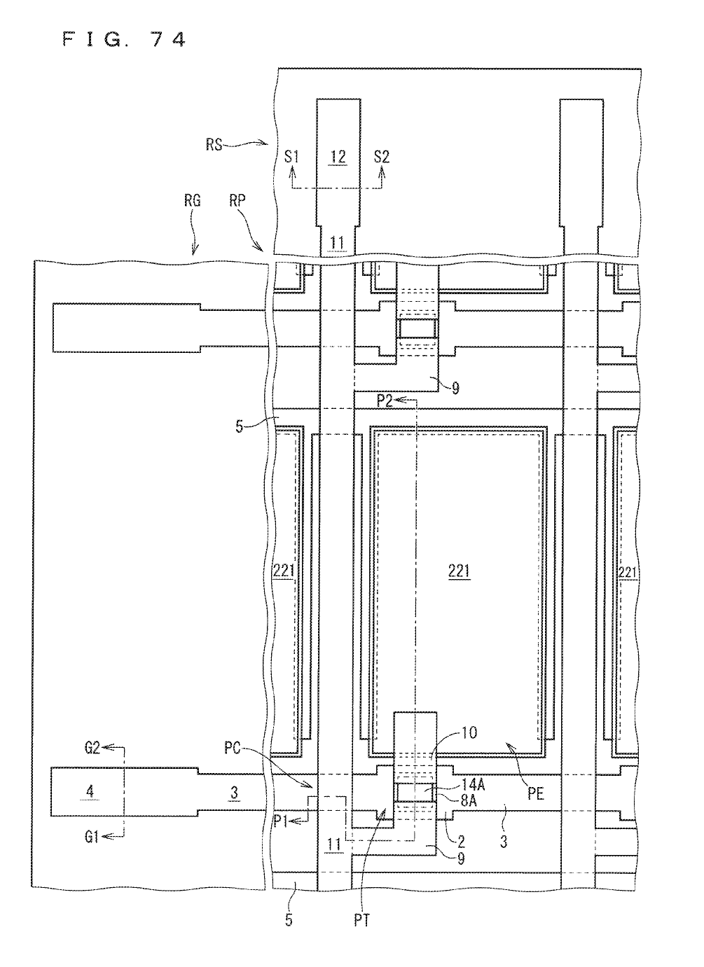

Third Photolithographic Process (FIGS. 73 and 74)

Referring to FIGS. 71 and 72, next, the source electrodes 9, the drain electrodes 10, the source lines 11, and the source terminals 12 are formed by the step using the third photolithographic process in approximately the same manner as in FIGS. 39 and 40 (second preferred embodiment). In the present preferred embodiment, parts of the drain electrodes 10 are formed on the third pixel electrode layer 14Fc of the pixel electrodes 221.

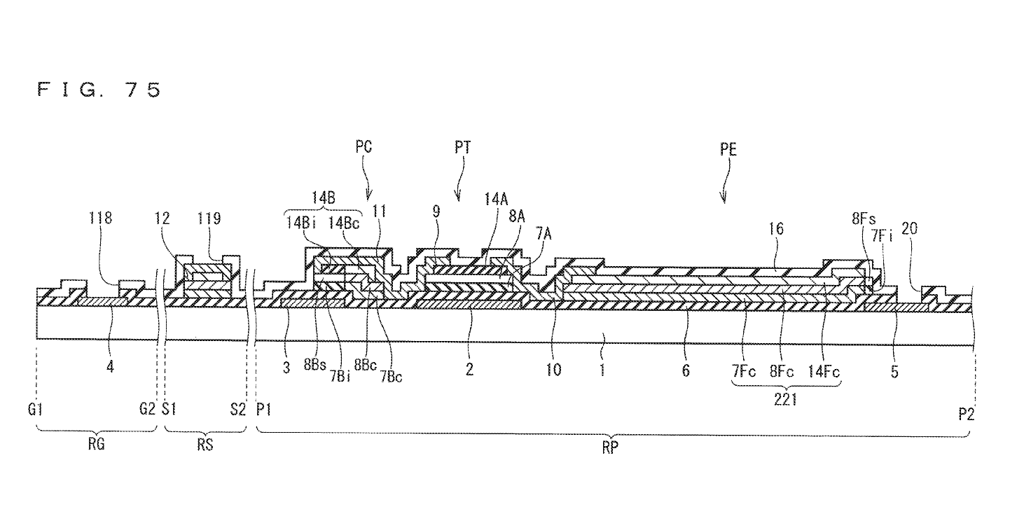

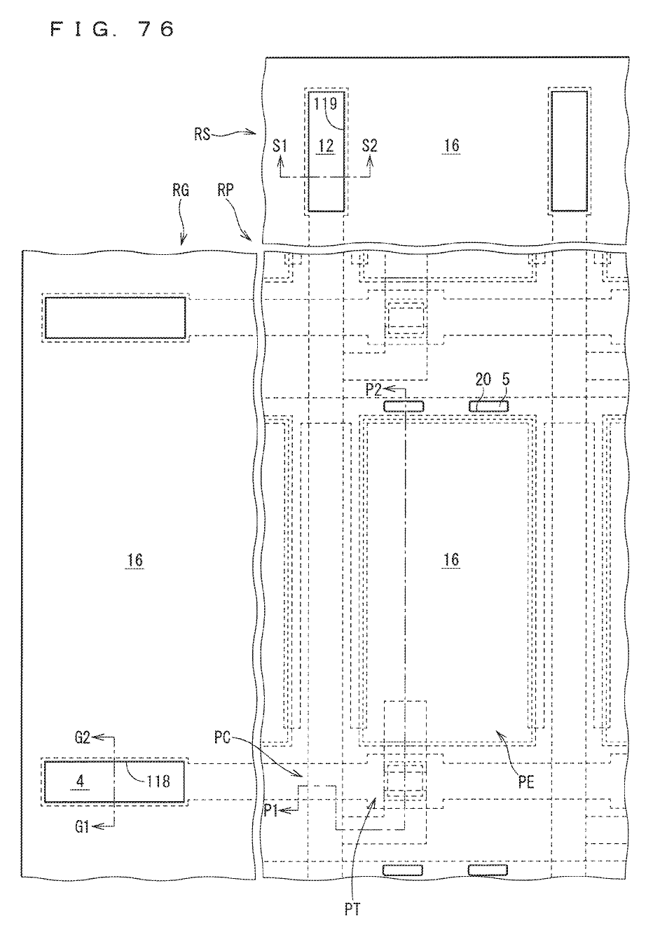

Fourth Photolithographic Process (FIGS. 75 and 76)

Referring to FIGS. 75 and 76, next, the interlayer insulation layer 16 that has the common electrode contact holes 20, the gate contact holes 118, and the source contact holes 119 is formed by the step using the fourth photolithographic process. This step is performed by the same method as that illustrated in FIGS. 65 and 66 (sixth preferred embodiment).

Fifth Photolithographic Process (FIGS. 67 and 68)

Referring again to FIGS. 67 and 68, the counter electrode 24, the gate pads 122, and the source pads 123 are formed by the step using the fifth photolithographic process. This step is the same as that of the sixth preferred embodiment.

Through the steps described above, the TFT substrate 707 according to the seventh preferred embodiment is completed. The TFT substrate 707, like the TFT substrate 704 (fourth preferred embodiment), is applicable to an FFS-mode liquid crystal display panel. Also, a liquid crystal display can be manufactured using this liquid crystal display panel.

Summary of Structure

The TFT substrate 707 according to the seventh preferred embodiment has a plurality of pixel regions arranged in a matrix and includes a plurality of thin-film transistors that correspond respectively to the plurality of pixel regions. The TFT substrate 707 includes the support substrate 1, the gate lines 3, the gate terminals 4, the common electrodes 5, the first gate insulating layer 6, the second gate insulating layer 7A, the first intersecting layer 7B, the channel layer 8A, the second intersecting layer 8B, the local insulating layer 14A, the third intersecting layer 14B, the source electrodes 9, the drain electrodes 10, the source lines 11, the source terminals 12, the pixel electrodes 21, the interlayer insulation layer 16, and the counter electrode 24.

The gate lines 3 are provided on the support substrate 1 and include the gate electrodes 2 deposed respectively in the plurality of pixel regions. The gate terminals 4 are provided on the support substrate 1 and connected to the gate lines 3. The common electrodes 5 are provided apart from the gate lines 3 on the support substrate 1. The first gate insulating layer 6 covers the gate lines 3 and the gate terminals 4 and is made of silicon nitride.

The second gate insulating layer 7A is provided on the gate electrodes 2 via the first gate insulating layer 6 in each of the plurality of pixel regions. The first intersecting layer 7B is provided on the gate lines 3 via the first gate insulating layer 6 and intersects with the gate lines 3. The channel layer 8A is provided on the second gate insulating layer 7A and has the same shape as the second gate insulating layer 7A. The second intersecting layer 8B is provided on the first intersecting layer 7B and has the same shape as the first intersecting layer 7B. The local insulating layer 14A is provided on the channel layer 8A and has the same shape as the channel layer 8A. The third intersecting layer 14B is provided on the second intersecting layer 8B and has the same shape as the second intersecting layer 8B.

The source electrodes 9 and the drain electrodes 10 are respectively in contact with one and the other ends (first and second ends) of the channel layer 8A, and they are spaced from and oppose each other on the local insulating layer 14. The source lines 11 are connected to the source electrodes 9 and intersect with the gate lines 3 on the third intersecting layer 14B. The source terminals 12 are connected to the source lines 11. The pixel electrodes 21 are respectively provided on the first gate insulating layer 6 in the plurality of pixel regions and are in contact with the drain electrodes 10. The interlayer insulation layer 16 covers the channel layer 8A, the gate lines 3, the gate terminals 4, the source lines 11, the source terminals 12, and the pixel electrodes 21 and is made of silicon nitride. The counter electrode 24 is provided on the interlayer insulation layer 16 and opposes the pixel electrodes 21 via the interlayer insulation layer 16. The pixel electrodes 21 include the first pixel electrode layer 7Fc provided on the first gate insulating layer 6, the second pixel electrode layer 8Fc provided on the first pixel electrode layer 7Fc and having the same shape as the first pixel electrode layer 7Fc, and the third pixel electrode layer 14Fc provided on the second pixel electrode layer 8Fc and having the same shape as the second pixel electrode layer 8Fc.

The interlayer insulation layer 16 has the source contact holes 19 that reach the source terminals 12. The first gate insulating layer 6 and the interlayer insulation layer 16 have the gate contact holes 18 that reach the gate terminals 4 and the common electrode contact holes 20 that reach the common electrodes 5. The counter electrode 24 is connected to the common electrodes 5 through the common electrode contact holes 20. The second gate insulating layer 7A, the channel layer 8A, the local insulating layer 14A, the first intersecting layer 7B, the second intersecting layer 8B, the third intersecting layer 14B, the first pixel electrode layer 7Fc, the second pixel electrode layer 8Fc, and the third pixel electrode layer 14Fc are made of oxide and have a common species of elements and a common crystal structure.

Additional Remarks

Although the above-described first to seventh preferred embodiments mainly describe oxide materials (In—Ga—Zn—O) that contain In, Ga, and Zn as the materials for the second insulation film, the oxide semiconductor film, and the third insulation film that are respectively used to form the second gate insulating layer 7A, the channel layer 8A, and the local insulating layer 14A or 14J, an oxide material that contains at least one of In, Ga, and Zn can be used. For example, In—O, Ga—O, Zn—O, In—Zn—O, In—Ga—O, or Ga—Zn—O can be used. In addition to these metal oxides, for example, oxide materials made by appropriately combining oxides such as hafnium (Hf), tin (Sn), yttrium (Y), and aluminum (Al) can be used. Even in the case of using these other oxide materials, electrical properties can be controlled among insulating properties, semiconducting properties and conductivity, by appropriately selecting the film deposition conditions, the plasma irradiation conditions, and wet treatment conditions. Accordingly, these materials can be favorably applied to each preferred embodiment of the present invention.

Also, the present invention is not limited to these examples, and the present invention can be implemented by combining constituent elements of each preferred embodiment or by modifying or omitting constituent elements of each preferred embodiment as appropriate without departing from the scope of the present invention. For example, an organic EL display device (organic light emitting diode: OLED), which is a selfluminous display, may be configured by using the TFT configurations according to the first to third preferred embodiments and disposing a selfluminous display structure such as an organic EL material in the pixel regions. Even in that case, the effects of the present invention can be achieved.

What is claimed is:

1. A thin-film transistor substrate having a plurality of pixel regions arranged in a matrix, and including a plurality of thin-film transistors that correspond respectively to the plurality of pixel regions, the thin-film transistor substrate comprising:
a support substrate;
a gate line provided on the support substrate and including a gate electrode disposed in each of the plurality of pixel regions;
a gate terminal provided on the support substrate and connected to the gate line;
a first gate insulating layer made of silicon nitride and covering the gate line and the gate terminal;
a second gate insulating layer provided on the gate electrode via the first gate insulating layer in each of the plurality of pixel regions;
a first intersecting layer provided on the gate line via the first gate insulating layer and intersecting with the gate line;
a channel layer provided on the second gate insulating layer and having the same shape as the second gate insulating layer;
a second intersecting layer provided on the first intersecting layer and having the same shape as the first intersecting layer;
a source electrode and a drain electrode that are spaced from and oppose each other on the channel layer;
a source line connected to the source electrode and intersecting with the gate line via the second intersecting layer;
a source terminal connected to the source line; and
a protective insulating layer made of silicon nitride and covering the channel layer, the gate line, the gate terminal, the source line, and the source terminal,
wherein the first gate insulating layer and the protective insulating layer has a gate contact hole that reaches the gate terminal, and the protective insulating layer has a source contact hole that reaches the source terminal, and
the second gate insulating layer, the channel layer, the first intersecting layer, and the second intersecting layer are made of oxide and have a common species of elements and a common crystal structure.

2. The thin-film transistor substrate according to claim 1, further comprising:
a local insulating layer made of oxide, provided between the channel layer and the protective insulating layer, and directly covering the channel layer.

3. The thin-film transistor substrate according to claim 1, wherein
the first intersecting layer and the second intersecting layer have portions that extend off the gate line in plan view, the portions having conductivity.

4. The thin-film transistor substrate according to claim 1, further comprising:
a local insulating layer covered by the protective insulating layer and provided on the channel layer and having the same shape as the channel layer; and
a third intersecting layer provided on the second intersecting layer and having the same shape as the second intersecting layer,
wherein the source electrode and a drain electrode are respectively in contact with first and second ends of the channel layer and are spaced from and oppose each other on the local insulating layer,
the source line intersects with the gate line via the second intersecting layer and the third intersecting layer,
the second gate insulating layer, the channel layer, the local insulating layer, the first intersecting layer, the second intersecting layer, and the third intersecting layer are made of oxide and have a common species of elements and a common crystal structure, and
the first intersecting layer, the second intersecting layer, and the third intersecting layer have portions that extend off the gate line in plan view, the portions having conductivity.

5. A thin-film transistor substrate having a plurality of pixel regions arranged in a matrix, and including a plurality of thin-film transistors that correspond respectively to the plurality of pixel regions, the thin-film transistor substrate comprising:
a support substrate;
a gate line provided on the support substrate and including a gate electrode disposed in each of the plurality of pixel regions;
a gate terminal provided on the support substrate and connected to the gate line;
a common electrode provided apart from the gate line on the support substrate;
a first gate insulating layer made of silicon nitride and covering the gate line and the gate terminal;
a second gate insulating layer provided on the gate electrode via the first gate insulating layer in each of the plurality of pixel regions;
a first intersecting layer provided on the gate line via the first gate insulating layer and intersecting with the gate line;
a channel layer provided on the second gate insulating layer and having the same shape as the second gate insulating layer;
a second intersecting layer provided on the first intersecting layer and having the same shape as the first intersecting layer;
a source electrode and a drain electrode that are spaced from and oppose each other on the channel layer;
a source line connected to the source electrode and intersecting with the gate line on the second intersecting layer;
a source terminal connected to the source line;
a pixel electrode provided in contact with the drain electrode on the first gate insulating layer in each of the plurality of pixel regions;
an interlayer insulation layer made of silicon nitride and covering the channel layer, the gate line, the gate terminal, the source line, the source terminal, and the pixel electrode;
a counter electrode provided on the interlayer insulation layer and opposing the pixel electrode via the interlayer insulation layer; and
a local insulating layer provided between the channel layer and the interlayer insulation layer and directly covering the channel layer,
wherein the interlayer insulation layer has a source contact hole that reaches the source terminal, the first gate insulating layer and the interlayer insulation layer have a gate contact hole that reaches the gate terminal and a common electrode contact hole that reaches the common electrode, and the counter electrode is connected to the common electrode through the common electrode contact hole, and
the second gate insulating layer, the channel layer, the first intersecting layer, the second intersecting layer, and the local insulating layer are made of oxide and have a common species of elements and a common crystal structure.

6. The thin-film transistor substrate according to claim 5, wherein
the first intersecting layer and the second intersecting layer have portions that extend off the gate line in plan view, the portions having conductivity.

7. The thin-film transistor substrate according to claim 5, wherein
the pixel electrode includes a first pixel electrode layer provided on the first gate insulating layer, and a second pixel electrode layer provided on the first pixel electrode layer and having the same shape as the first pixel electrode layer, and
the first pixel electrode layer and the second pixel electrode layer are made of oxide and have the common species of elements and the common crystal structure.

8. A thin-film transistor substrate having a plurality of pixel regions arranged in a matrix, and including a plurality of thin-film transistors that correspond respectively to the plurality of pixel regions, the thin-film transistor substrate comprising:
a support substrate;
a gate line provided on the support substrate and including a gate electrode disposed in each of the plurality of pixel regions;
a gate terminal provided on the support substrate and connected to the gate line;
a common electrode provided apart from the gate line on the support substrate;
a first gate insulating layer made of silicon nitride and covering the gate line and the gate terminal;
a second gate insulating layer provided on the gate electrode via the first gate insulating layer in each of the plurality of pixel regions;
a first intersecting layer provided on the gate line via the first gate insulating layer and intersecting with the gate line;
a channel layer provided on the second gate insulating layer and having the same shape as the second gate insulating layer;
a second intersecting layer provided on the first intersecting layer and having the same shape as the first intersecting layer;
a local insulating layer provided on the channel layer and having the same shape as the channel layer;
a third intersecting layer provided on the second intersecting layer and having the same shape as the second intersecting layer;
a source electrode and a drain electrode that are respectively in contact with first and second ends of the channel layer and are spaced from and oppose each other on the local insulating layer;
a source line connected to the source electrode and intersecting with the gate line on the third intersecting layer;
a source terminal connected to the source line;
a pixel electrode provided in contact with the drain electrode on the first gate insulating layer in each of the plurality of pixel regions;
an interlayer insulation layer made of silicon nitride and covering the channel layer, the gate line, the gate terminal, the source line, the source terminal, and the pixel electrode; and
a counter electrode provided on the interlayer insulation layer and opposing the pixel electrode via the interlayer insulation layer,
wherein the pixel electrode includes a first pixel electrode layer provided on the first gate insulating layer, a second pixel electrode layer provided on the first pixel electrode layer and having the same shape as the first pixel electrode layer, and a third pixel electrode layer provided on the second pixel electrode layer and having the same shape as the second pixel electrode layer,
the interlayer insulation layer has a source contact hole that reaches the source terminal, the first gate insulating layer and the interlayer insulation layer have a gate contact hole that reaches the gate terminal and a common electrode contact hole that reaches the common electrode, and the counter electrode is connected to the common electrode through the common electrode contact hole, and
the second gate insulating layer, the channel layer, the local insulating layer, the first intersecting layer, the second intersecting layer, the third intersecting layer, the first pixel electrode layer, the second pixel electrode layer, and the third pixel electrode layer are made of oxide and have a common species of elements and a common crystal structure.
